(19) United States
(12) Patent Application Publication
(10) Pub. No.: US 2017/0351179 A1
(43) Pub. Date: Dec. 7, 2017

(54) COMPOSITION FOR FORMING UPPER LAYER FILM, PATTERN FORMING METHOD USING THE SAME, AND METHOD FOR MANUFACTURING ELECTRONIC DEVICE

(71) Applicant: FUJIFILM Corporation, Tokyo (JP)

(72) Inventors: Akiyoshi GOTO, Haibara-gun (JP); Naoki INOUE, Haibara-gun (JP); Naohiro TANGO, Haibara-gun (JP); Kei YAMAMOTO, Haibara-gun (JP); Michihiro SHIRAKAWA, Haibara-gun (JP)

(73) Assignee: FUJIFILM Corporation, Tokyo (JP)

(21) Appl. No.: 15/685,630

(22) Filed: Aug. 24, 2017

Related U.S. Application Data
(63) Continuation of application No. PCT/JP2016/054751, filed on Feb. 18, 2016.

(30) Foreign Application Priority Data
Feb. 26, 2015 (JP) 2015-037290

(51) Int. Cl. G03F 7/11; G03F 7/16; C09D 133/10; C09D 133/14; G03F 7/32; G03F 7/20

(52) U.S. Cl. CPC G03F 7/11; G03F 7/32; G03F 7/20; C09D 133/10; C09D 133/14; G03F 7/168

(57) ABSTRACT

Provided are a composition for forming an upper layer film for a photoresist, including a polymer having a molecular weight distribution in which a peak area of a high-molecular-weight component having a weight-average molecular weight of 40,000 or more accounts for 0.1% or less with respect to the entire peak area in the molecular weight distribution, measured by the gel permeation chromatography.

### CROSS REFERENCE TO RELATED APPLICATION(S)

This is a continuation of International Application No. PCT/JP2016/054751 filed on Feb. 18, 2016, and claims a priority from Japanese Patent Application No. 2015-037290 filed on Feb. 26, 2015.

### BACKGROUND OF THE INVENTION

### 1. Field of the Invention

The present invention relates to a composition for forming an upper layer film which is used for a process for manufacturing a semiconductor such as an IC, for the manufacture of a circuit board for a liquid crystal, a thermal head, or the like, and for a lithography process of photofabrication in addition to these, a pattern forming method using the same, and a method for manufacturing an electronic device.

### 2. Description of the Related Art

After resists for a KrF excimer laser (248 nm) were developed, an image forming method called chemical amplification has been used as an image forming method for a resist in order to compensate for the decrease in sensitivity due to light absorption. By way of an example of an image forming method for positive-type chemical amplification, the method is an image forming method in which an acid generator in the exposed areas formed by exposure decomposes to generate an acid, the generated acid is used as a reaction catalyst through baking (PEB: Post Exposure Bake) after the exposure to change an alkali-insoluble group into an alkali-soluble group, and the exposed areas are removed by alkali development.

It is known that in a case where a chemical amplification resist is applied to a liquid immersion exposure, the resist layer is brought into contact with an immersion liquid during the exposure, and therefore, the resist layer is modified or the components adversely affecting the immersion liquid exudes from the resist layer.

As a solution to avoid such problems, a method in which a resist and water are prevented from coming into direct contact with each other by providing a protective film (hereinafter also referred to as a “topcoat” or an “overcoat”) between a resist and a lens is known (for example, JP2008-309878A and JP2013-61647A).

### SUMMARY OF THE INVENTION

However, more recently, finer trench patterns and contact holes have further been demanded, and accordingly, it has been required to obtain a pattern having more excellent performance, in particular in a case where a trench pattern or hole pattern having an ultrafine width or pore diameter (for example, 60 nm or less) is to be formed on a resist film.

The present invention has been made in consideration of such problems, and has an object to provide a composition for forming an upper layer film capable of forming a trench pattern or hole pattern having an ultrafine width or pore diameter (for example, 60 nm or less) with a high focus latitude (DOF: Depth of Focus) performance, a pattern forming method using the same, and a method for manufacturing an electronic device.

The present invention has the following configuration, whereby the objects of the present invention are achieved.

[1] A composition for forming an upper layer film for a photoresist, comprising a polymer having a molecular weight distribution in which a peak area of a high-molecular-weight component having a weight-average molecular weight of 40,000 or more accounts for 0.1% or less with respect to the entire peak area in the molecular weight distribution, measured by the gel permeation chromatography.

[2] The composition for forming an upper layer film as described in [1], which is for use in a photoresist to be subjected to development using a developer containing an organic solvent.

[3] The composition for forming an upper layer film as described in [1] or [2], in which the polymer is produced by a method including a step of radically polymerizing monomers having ethylenic double bonds in the coexistence of 30 ppm or more of a polymerization inhibitor with respect to the total amount of the monomers.

[4] The composition for forming an upper layer film as described in [3], in which the polymerization inhibitor is one or more compounds selected from the group consisting of hydroquinone, catechol, benzoquinone, a 2,2,6,6-tetramethylpiperidin-1-oxyl free radical, an aromatic nitro compound, an N-nitroso compound, benzothiazole, dimethylaniline, phenothiazine, vinylpyrene, and derivatives thereof.

[5] The composition for forming an upper layer film as described in any one of [1] to [4], further comprising:

at least one compound selected from the group consisting of the following (A1) and (A2):

(A1) a basic compound or base generator; and

(A2) a compound containing a bond or group selected from the group consisting of an ether bond, a thioether bond, a hydroxyl group, a thiol group, a carbonyl bond, and an ester bond.

[6] A pattern forming method comprising: a step of forming an upper layer film on a resist film using the composition for forming an upper layer film as described in any one of [1] to [5]; a step of exposing the resist film; and a step of developing the exposed resist film.

[7] The pattern forming method as described in [6], in which the step of forming an upper layer film includes a step of applying the composition for forming an upper layer film on the resist film, and a step of heating the composition applied on the resist film to 100° C. or higher.

[8] The pattern forming method as described in [6] or [7], in which the step of developing the exposed resist film is a step of carrying out development using a developer containing an organic solvent.

[9] A method for manufacturing an electronic device, using the pattern forming method as described in any one of [6] to [8].

According to the present invention, it is possible to provide a composition for forming an upper layer film capable of forming a trench pattern or hole pattern having an ultrafine width or pore diameter (for example, 60 nm or less) with a high focus latitude (DOF: Depth of Focus) performance, a pattern forming method using the same, and a method for manufacturing an electronic device.

### DESCRIPTION OF THE PREFERRED EMBODIMENTS

Hereinafter, aspects for carrying out the present invention will be described.

In citations for a group (atomic group) in the present specification, a description not referring to substitution or non-substitution includes both a group having no substituent and a group having a substituent. For example, an “alkyl group” includes not only an alkyl group having no substituent (an unsubstituted alkyl group) but also an alkyl group having a substituent (a substituted alkyl group).

“Actinic ray” or “radiation” in the present specification means, for example, a bright line spectrum of a mercury lamp, far ultraviolet rays represented by an excimer laser, extreme ultraviolet rays (EUV light), X-rays, electron beams (EB), or the like. In addition, in the present invention, light means actinic ray or radiation. Furthermore, unless otherwise specified, “exposure” in the present specification includes not only exposure by a mercury lamp, far ultraviolet rays represented by an excimer laser, extreme ultraviolet rays, X-rays, EUV light, or the like, but also writing by particle rays such as electron beams and ion beams.

In the present specification, the weight-average molecular weight (Mw), the number-average molecular weight (Mn), and the dispersity (Mw/Mn) of the polymer in the composition for forming an upper layer film and the resin in the resist composition are each defined as a value in terms of polystyrene by GPC measurement (solvent: tetrahydrofuran, flow rate (amount of a sample to be injected): 10 μl, column: TSK gel Multipore HXL-M (×4) manufactured by TOSOH Corporation, column temperature: 40° C., flow rate: 1.0 mL/min, detector: refractive index (RI) detector), using a GPC device (HLC-8120GPC manufactured by TOSOH Corporation).

The composition for forming an upper layer film according to the present invention is a composition for forming an upper layer film for a photoresist, including a polymer, in which the peak area of a high-molecular-weight component having a weight-average molecular weight of 40,000 or more accounts for 0.1% or less with respect to the entire peak area in the molecular weight distribution of the polymer, measured by the gel permeation chromatography (GPC).

The reason why the DOF performance is improved by the composition for forming an upper layer film of the present invention is not clear, but is presumed as follows.

The present inventors have initially presumed that even when a low-molecular-weight compound (for example, a deprotected substance generated by a polarity inversion reaction with an acid in an acid-decomposable resin as a catalyst) generated by a reaction in the exposed area of the resist film volatilizes from the film, the compound partially remains in the resist film, and thus, this deprotected substance acts as a plasticizer that accelerates the mixing of the interface between the resist film and the upper layer film. Under the presumption, the present inventors have found that if a large amount of the high-molecular-weight component (specifically, a high-molecular-weight component having a weight-average molecular weight of 40,000 or more) that lowers the solubility of the resist is present in the upper layer film in the mixed state, the developability in the upper part of the resist film is reduced.

In particular, the present inventors have found that if the developability in the upper part of the resist film is low in the formation of a trench pattern or a hole pattern, the pattern is easily blocked, the DOF performance thus tends to be reduced, and further, this tendency is significant in a case where the width of the trench pattern or the hole diameter of the hole pattern is ultrafine (for example, 60 nm or less).

It is thought that by the composition for forming an upper layer film of the present invention, the amount of the high-molecular-weight component (high-molecular-weight component having a weight-average molecular weight of 40,000 or more) to be present, which causes the reduction in the developability in the upper part of the resist film, is small and sufficient developability is secured in the upper part of the resist film, and as a result, the DOF is enhanced.

The peak area of the high-molecular-weight component having a weight-average molecular weight of 40,000 or more accounts for preferably 0.08% or less, and more preferably 0.05% or less, with respect to the entire peak area, in the molecular weight distribution of the polymer measured by the gel permeation chromatography (GPC).

It is the most preferable that the peak area of the high-molecular-weight component having a weight-average molecular weight of 40,000 or more with respect to the entire peak area is the smallest (that is, zero), but in a case where a high-molecular-weight component having a weight-average molecular weight of 40,000 or more is present, the peak area thereof accounts for, for example, 0.001% or more with respect to the entire peak area.

[1] Polymer in Composition for Forming Upper Layer Film, and Method for Synthesizing the Same

Regarding a polymer included in the composition for forming an upper layer film, in which as a ratio (%) of the peak area of the high-molecular-weight component having a weight-average molecular weight of 40,000 or more with respect to the entire peak area in the molecular weight distribution measured by the gel permeation chromatography, a value calculated using the following method is adopted. A 2%-by-mass solution (A) of the polymer included in the composition for forming an upper layer film is prepared, and the molecular weight distribution is measured by GPC to determine the peak area Ap of the polymer component. Next, a 20%-by-mass solution (B) of the polymer included in the composition for forming an upper layer film, having a concentration of ten times the concentration of the solution (A), is prepared, and the molecular weight distribution is measured by GPC to determine the peak area Ah of the polymer component corresponding to the high-molecular-weight component having a weight-average molecular weight of 40,000 or more.

Using Ap and Ah obtained from such results, the ratio (%) of the peak area of the high-molecular-weight component having a molecular weight of 40,000 or more of the polymer to be added to the composition for forming an upper layer film with respect to the entire peak area is calculated according to the following calculation formula. Further, since the area Ap is an area obtained with a concentration of 1/10 times that of the area Ah, it becomes 10 times in comparison with the area Ah.

$$\frac{A h}{( Ap \times 10 ) + A h} \times 100 ( \% )$$

By the above-mentioned method, it is possible to calculate the ratio (%) of the peak area of the high-molecular-weight component having a weight-average molecular weight of 40,000 or more with respect to the entire peak area with high accuracy even in a case where the amount of the high-molecular-weight component having a weight-average molecular weight of 40,000 or more in the polymer is a trace amount.

The molecular weight distribution measured by GPC is calculated based on a calibration curve prepared with a commercially available polystyrene standard sample, using a refractive index detector (RI) as a detector.

In a case where the composition for forming an upper layer film contains two or more kinds of the polymer, both the solution (A) and the solution (B) each contain the two or more kinds of the polymer, and the weight ratio among the 2 or more kinds of the polymer in the solution (A) and the solution (B) were set to be the same as that in the composition for forming an upper layer film.

<Method for Synthesizing Polymer>

Suitable examples of the method for synthesizing the polymer include a method including supplying continuously or intermittently a monomer solution (hereinafter also described as a “monomer solution”) containing a polymerizable monomer and a solution (hereinafter also described as an “initiator solution”) containing a polymerization initiator stored separately in a reservoir to a polymerization system to undergo radical polymerization, whereby production of the high-molecular-weight component having a weight-average molecular weight of 40,000 or more can be appropriately inhibited to appropriately control the content of the high-molecular-weight component to 0.1% or less.

Examples of the component other than the monomer, which may be contained in the monomer solution, include a solvent, a polymerization inhibitor, oxygen, and a chain transfer agent. Examples of the initiator solution include a solvent.

<Polymerization Concentration>

The polymerization concentration varies depending on a combination of the solute and the solvent in each solution, but typically, the final concentration of the solutes (the monomer and the polymerization initiator) after the completion of the supply of the monomer solution and the initiator solution is preferably 5% to 60%, by mass, and more preferably 30% to 50% by mass.

The concentration of the monomer in the monomer solution is preferably 5% to 60% by mass, and more preferably 30% to 50% by mass.

As the monomer, a monomer having a low metal content, for example, a monomer having a metal content of 100 ppb by mass or less, is preferably used.

The concentration of the initiator in the initiator solution is preferably 5% to 60% by mass, and more preferably 30% to 50% by mass.

<Polymerization Inhibiting Component>

It is preferable that the polymerization inhibitor in an amount of 30 ppm or more with respect to the monomer or oxygen in an amount of 400 ppm or more with respect to the monomer exists as a polymerization inhibiting component in the solution including the monomers which becomes a raw material.

By the coexistence of the polymerization inhibiting component in the solution including the monomer, the high-molecular-weight component can be inhibited from being produced during the radical polymerization.

In the present invention, examples of the polymerization inhibiting component that coexists in the solution including the monomers include compounds which are generally used as a polymerization inhibitor and oxygen.

As the polymerization inhibitor, any known polymerization inhibitors can be used. Specific examples of the polymerization inhibitor include hydroquinone and a hydroquinone derivative such as 4-methoxyphenol, tert-butylhydroquinone, and 2,5-di-ten-butylhydroquinone; catechol and a catechol derivative such as 4-tert-butylcatecol; benzoquinone and a benzoquinone derivative such as methylbenzoquinone and tert-butylbenzoquinone; a 2,2,6,6-tetramethylpiperidin-1-oxyl free radical and a derivative thereof; an aromatic nitro compound and a derivative thereof; an N-nitroso compound such as N-nitrosophenylhydroxylamine, and a derivative thereof; benzothiazole and a derivative thereof; dimethylaniline and a derivative thereof; phenothiazine and a derivative thereof; and vinylpyrene and a derivative thereof, and these may be used singly or as a mixture thereof.

It is preferable that the polymerization inhibiting component is present in the monomer in advance, prior to the preparation of the monomer solution.

If the amount of the polymerization inhibitor coexisting in the solution including the monomers is too small, the effect of trapping a radical is low. Accordingly, the polymer is more preferably produced by a method including a step of radically polymerizing monomers (typically monomers having ethylenic double bonds) in the coexistence of a polymerization inhibitor in an amount of 30 ppm or more (preferably 50 ppm or more, and more preferably 100 ppm or more) with respect to the total amount of the monomers.

The upper limit of the amount of the polymerization inhibitor is not particularly limited, but is preferably 5,000 ppm or less, and more preferably 3,000 ppm or less, with respect to the monomers since when it is too high, the polymerization reaction does not proceed sufficiently and the polymerization inhibitor remains in the polymer even after the purification and may absorb radiation for use in lithography, depending on the compounds.

Since oxygen also has a radical trapping function, it can be used as the polymerization inhibiting component.

Examples of the method for making oxygen coexist at the above-mentioned concentration together with the monomers include a method keeping the solution including the monomers in an oxygen or air atmosphere and a method of bubbling oxygen or air through the solution. Further, a solvent kept in the oxygen or air atmosphere or a solvent bubbled with oxygen or air may be used for the preparation of the solution including the monomers.

The amount of oxygen dissolved is, for example, 5,000 ppm or less with respect to the monomers.

<Polymerization Initiator>

The polymerization initiator is not particularly limited as long as it is a polymerization initiator that is generally used as a radical initiator, and a peroxide-based initiator or an azo-based initiator is generally used.

As the radical initiator, an azo-based initiator is preferable, and an azo-based initiator having an ester group, a cyano group, or a carboxyl group is preferable.

Specific examples of the azo-based initiator include azobisisobutyronitrile, 2,2′-azobis(2-methylbutyronitrile), 2,2′-azobis(2,4-dimethylvaleronitrile), dimethyl azobisisobutyrate, and azobis(4-cyanovaleric acid).

Specific examples of the peroxide-based initiator include peroxyester-based polymerization initiators such as benzoperoxide, decanoyl peroxide, lauroyl peroxide, bis(3,5,5-trimethylhexanoyl)peroxide, succinic acid peroxide, t-butylperoxy-2-ethylhexanoate, and 1,1,3,3-tetramethylbutylperoxy-2-ethylhexanoate, ketone peroxide-based polymerization initiators such as methyl ethyl ketone peroxide, peroxyketal-based polymerization initiators such as 1,1-bis(t-hexylperoxy)-3,3,5-trimethylcyclohexane, hydroperoxide-based polymerization initiators such as 1,1,3,3-tetramethylbutylhydroperoxide, diacylperoxide-based polymerization initiators such as isobutyrylperoxide, and peroxydicarbonate-based polymerization initiators such as di-n-propylperoxydicarbonate.

The amounts of the polymerization initiator and the chain transfer agent to be used which will be described later cannot be generally defined since they vary depending on the production conditions such as the type of a monomer as a raw material or a polymerization initiator, and the chain transfer agent used in the polymerization reaction, a polymerization temperature, a polymerization solvent, a polymerization method, and purification conditions, and an optimum amount for achieving a desired molecular weight is used.

By the amounts of the initiator and the chain transfer agent to be added, the polymerization concentration, the polymerization temperature, and the like, the weight-average molecular weight of the polymer is preferably adjusted to a range of 2,000 to 20,000, and more preferably adjusted to a range of 2,000 to 12,000.

<Polymerization Solvent>

Examples of the reaction solvent include a solvent capable of dissolving the composition according to the present invention, for example, esters such as ethyl acetate, butyl acetate, propylene glycol monomethyl ether monoacetate, ethyl lactate, ethyl 3-ethoxypropionate, ethyl pyruvate, 2-ethoxyethyl acetate, 2-(2-ethoxyethoxy)ethyl acetate, ethyl benzoate, and γ-butyrolactone, carbonates such as propylene carbonate, ketones such as acetone, ethyl methyl ketone, diethyl ketone, isobutyl methyl ketone, t-butyl methyl ketone, cyclopentanone, and cyclohexanone, ethers such as diethyl ether, diisopropyl ether, t-butyl methyl ether, dibutyl ether, dimethoxyethane, propylene glycol monomethyl ether, anisole, dioxane, dioxolane, and tetrahydrofuran, alcohols such as isopropanol and butanol, nitriles such as acetonitrile and propionitrile, aromatic hydrocarbons such as toluene and xylene, and amide solvents such as dimethylformamide and dimethylacetamide, or a mixture of these solvents. Among these, propylene glycol methyl ether acetate, propylene glycol methyl ether, ethyl lactate, γ-butyrolactone, cyclohexanone, cyclopentanone, and the like are preferable.

As the polymerization solvent, the same solvent as a solvent for dissolving an undried polymer (wet polymer) after reprecipitation, which will be described later, and a solvent for a resist are preferable.

<Polymerization Temperature>

The reaction temperature is usually 10° C. to 150° C., preferably 30° C. to 120° C., and more preferably 60° C. to 100° C.

<Chain Transfer Agent>

From the viewpoint of further inhibiting the production of the high-molecular-weight forms, it is preferable that a chain transfer agent is further added to the solution including the monomers. The chain transfer agent may be added to the polymerization system before the initiation of polymerization.

The chain transfer agent is not particularly limited as long as it is a compound capable of undergoing radical chain transfer, and examples thereof include a thiol compound and a disulfide compound.

The chain transfer agent is preferably a thiol compound having at least one selected from an alkyl group, a hydroxyl group, a fluoroalkyl group, an ester group, an acid group, and a phenyl group.

Specific examples of the thiol compound include an alkyl thiol compound such as dodecanethiol, mercaptoethanol, and mercaptopropanol, a thiol compound having a hydroxyl group, such as mercaptoethanol, mercaptopropanol, and mercaptopropanediol, a thiol compound having a fluroalkyl group, for example, perfluorooctylthiol or perfluorodecanethiol, a thiol compound having an ester group, such as methyl thioglycolate, ethyl thioglycolate, n-butyl thioglycolate, methyl mercaptopropionate, and ethyl mercaptopropionate, a thiol compound having an acid group, such as mercaptoacetic acid and mercaptopropionic acid, and a thiol compound having a phenyl group, such as toluenethiol, fluorobenzenethiol, mercaptophenol, and mercaptobenzoic acid.

<Feeding Procedure of Polymerization>

It is preferable that the polymer is obtained by supplying continuously or intermittently a solution (monomer solution) containing a monomer as a raw material and a solution (initiator solution) containing a polymerization initiator from tanks separated from each other to a polymerization system heated at a polymerization temperature to undergo radical polymerization.

It is preferable that even after the initiation of polymerization by initiating the supply of the monomer solution and the initiator solution, the monomer solution and the initiator solution are supplied continuously or intermittently.

Here, the polymerization system may be a solution having monomers dissolved in a solvent in advance, or a solvent alone.

In a case where the polymerization system is the solution obtained by dissolving the monomers in a solvent, since there is a possibility that the high-molecular-weight component is formed while the solution is kept in the state of being heated at a high temperature for a long period of time, the heating is preferably carried out immediately before the polymerization.

The polymerization reaction is preferably carried out under an inert gas atmosphere such as nitrogen and argon.

The monomer solution and the initiator solution may be supplied from tanks separated from each other to a polymerization tank or may be supplied by carrying out pre-mixing immediately before the polymerization. The pre-mixing immediately before the polymerization can be carried out so as not to generate the high-molecular-weight forms while the monomer solution and the polymerization initiator solution are preserved for a long period of time, and it is desirably carried out, for example, within one hour before the initiation of polymerization.

The supply rates of the monomer solution and the initiator solution can be set independently to each other so as to obtain a polymer having a desired molecular weight distribution. It is possible to obtain a polymer having a wide range of the molecular weight distribution from narrow dispersity to polydispersity with good reproducibility by changing one or both of the supply rates of the two solutions. For example, in a case where the supply amount of the initiator solution is reduced at the early stages of the reaction and the supply amount of the initiator solution is increased at the latter stages of the reaction, a polymer with polydispersity is obtained since a polymer having relatively high-molecular-weight forms is formed in the early stages of the reaction where a radical concentration is low.

When the monomer solution and the initiator solution are supplied as slowly as possible, the monomer composition, the temperature, and the radical concentration in the polymerization system are maintained constant so that the variations in the composition and the molecular weight of the polymers produced in the initial stages and the final stages of polymerization can be reduced.

However, when the supply rate is too slow, the time necessary for the supply becomes longer to decrease the production efficiency per time and a problem may arise in some cases in that the monomer solution deteriorates with the monomer of low stability. Therefore, the time taken for the supply of each solution is each selected in a range of 0.5 to 20 hours, and preferably a range of 1 to 10 hours.

The order of initiation of supplying the monomer solution and the initiator solution is not particularly limited, and it is preferable to supply both solutions simultaneously or to supply the initiator solution first in order to avoid the formation of the high-molecular-weight component. Since a certain period of time is necessary for the polymerization initiator to decompose in the reaction system to generate a radical, it is preferable to supply the initiator solution ahead of the monomer solution.

While supplying the monomer solution and the initiator solution, it is preferable to control the polymerization system to be at a desired temperature ±5° C., and preferably a desired temperature ±2° C.

The temperatures of the monomer solution and the initiator solution are each preferably 10° C. to 30° C.

The polymerization reaction is initiated by supplying the monomer solution and the initiator solution, and continued. However, it is preferable that even after the completion of the supply, the polymerization temperature is maintained for a certain period of time to perform aging, thereby promoting the reaction of the remaining unreacted monomer. The time for aging is preferably within 6 hours, and more preferably selected in a range of 1 to 4 hours. When the time for aging is too long, the production efficiency decreases, which is not preferable since the polymer is subjected to excessive heat history.

<Reprecipitation Step>

The polymer obtained by the polymerization reaction is precipitated by dropwise adding the polymerization reaction solution to a poor solvent singly or a mixed solvent of a poor solvent and a good solvent and washed, if desired, whereby unwanted substances such as the unreacted monomers or oligomers, the polymerization initiator, and its reaction residues can be removed to perform purification.

The poor solvent is not particularly limited as long as it is a solvent not dissolving the polymer, and depending on the kind of the polymer, the solvent which is appropriately selected from hydrocarbons (aliphatic hydrocarbons such as pentane, hexane, heptane, and octane; alicyclic hydrocarbons such as cyclohexane and methylcyclohexane; and aromatic hydrocarbons such as benzene, toluene, and xylene), halogenated hydrocarbons (halogenated aliphatic hydrocarbons such as methylene chloride, chloroform, and carbon tetrachloride; halogenated aromatic hydrocarbons such as chlorobenzene and dichlorobenzene; and the like), nitro compounds (nitromethane, nitroethane, and the like), nitriles (acetonitrile, benzonitrile, and the like), ethers (chained ethers such as diethyl ether, diisopropyl ether, and dimethoxyethane; and cyclic ethers such as tetrahydrofuran and dioxane), ketones (acetone, methyl ethyl ketone, diisobutyl ketone, and the like), esters (ethyl acetate, butyl acetate, and the like), carbonates (dimethyl carbonate, diethyl carbonate, ethylene carbonate, propylene carbonate, and the like), alcohols (methanol, ethanol, propanol, isopropyl alcohol, butanol, and the like), carboxylic acids (acetic acid and the like), water, and mixed solvents containing these solvents can be used. The poor solvent is preferably water, alcohols such as methanol and isopropanol, or saturated hydrocarbons such as hexane and heptane.

The good solvent is not particularly limited as long as it is a solvent dissolving the monomers, the oligomers, the polymerization initiator, and its reaction residues, and is preferably a solvent same as the polymerization solvent in view of control of the production step.

The polymer is precipitated as a solid by bringing the polymer into contact with a solvent (poor solvent) which hardly dissolves or does not dissolve the polymer in a volume amount 10 times or less, and preferably from 10 to 5 times than that of the reaction solution.

The amount of the solvent used for the precipitation or reprecipitation is appropriately determined taking, for example, the efficiency or yield into consideration, and is generally 100 to 10,000 parts by mass, preferably 200 to 2,000 parts by mass, and more preferably 300 to 1,000 parts by mass, with respect to 100 parts by mass of the polymer solution.

The temperature for the precipitation or reprecipitation is appropriately determined taking, for example, the efficiency or operability into consideration and is usually approximately 0° C. to 50° C., and preferably around room temperature (for example, approximately 20° C. to 35° C.). The operation of the precipitation or reprecipitation can be carried out using a conventional mixing vessel such as a stirring tank, according to a known method such as a batch type method and a continuous type method.

<Steps after Filtration>

Since the thus-obtained polymer after purification includes the solvent used in the purification, the polymer is subjected to conventional solid-liquid separation such as filtration and centrifugation, dried, and then dissolved in a resist solvent to prepare a resist solution.

The drying is carried out at normal pressure or under reduced pressure (preferably under reduced pressure), and at a temperature of approximately 30° C. to 100° C., and preferably approximately 30° C. to 50° C.

The resist solvent is not particularly limited as long as it is a solvent dissolving the polymer, and it is usually selected taking a boiling point, influence on a semiconductor substrate or other coating films and absorption of radiation used in lithography into consideration.

<Steps after Filtration (Solution Supply)>

Moreover, it is preferable that the thus-obtained polymer after purification is dissolved in a good solvent such as a solvent of a composition for forming an upper layer film and a polymerization solvent and then the other solvent is distilled off under reduced pressure while supplying the solvent of the composition for forming an upper layer film, if desired, to prepare a solution of the composition for forming an upper film layer. That is, it is preferable that the polymer (undried polymer) obtained by performing precipitation purification and then performing solid-liquid separation is redissolved in an organic solvent, and the obtained polymer solution is concentrated to distill off a low boiling point solvent included in the polymer solution.

The organic solvent for redissolving the undried polymer obtained is preferably a solvent which is the same as the polymerization solvent.

In a case where a polymer is dried under reduced pressure and then dissolved in a solvent of the composition for forming an upper layer film, the polymer may be hardly dissolved in the solvent when the composition for forming an upper layer film is prepared in some cases, probably due to hardening of the surface of the polymer particles or aggregation between the polymer particles during the drying. Further, in a case where the composition for forming an upper layer film obtained by dissolving the polymer is coated to form a hydrophobic layer as a surface layer, the coating property is poor or the coating defect occurs in some cases.

These problems are alleviated while keeping the state of dissolving the polymer in a solution by the solvent substitution without carrying out drying as described above.

The organic solvent for redissolving the undried polymer is preferably the same as a solvent used when the solution of the composition for forming an upper layer film is prepared, and suitable examples thereof include those which will be described later as the solvent of the composition for forming an upper layer film.

[2] Composition (Topcoat Composition) for Forming Upper Layer Film

Next, a composition (topcoat composition) for forming an upper layer film, for forming an upper layer film (topcoat), will be described.

The topcoat composition is a composition containing a polymer (X), and is preferably a composition containing the polymer (X) which will be described later and a solvent in order to be uniformly formed on a resist film. Here, the polymer (X) satisfies a condition where the peak area of the high-molecular-weight component having a weight-average molecular weight of 40,000 or more accounts for 0.1% or less with respect to the entire peak area in the molecular weight distribution measured by the gel permeation chromatography, and the detailed descriptions thereof are the same as those in “[1] Polymer in Composition for Forming Upper Layer Film, and Method for Synthesizing the Same” as described above.

The composition for forming an upper layer film according to the present invention is preferably for a photoresist to be provided for the development using a developer containing an organic solvent.

<Solvent>

In order to form a good pattern while not dissolving the resist film, it is preferable that the topcoat composition in the present invention contains a solvent in which the resist film is not dissolved, and it is more preferable that a solvent with components different from a developer (organic developer) containing an organic solvent is used.

Furthermore, from the viewpoint of the prevention of elution into an immersion liquid, low solubility in an immersion liquid is preferable, and low solubility in water is more preferable. In the present specification, “having low solubility in an immersion liquid” means insolubility in an immersion liquid. In the specification, “having low solubility in water” means insolubility in water. Further, from the viewpoints of volatility and coatability, the boiling point of the solvent is preferably 90° C. to 200° C.

“Having low solubility in an immersion liquid” indicates that in an example of the solubility in water, when a topcoat composition is applied onto a silicon wafer and dried to form a film, and then the film is immersed in pure water at 23° C. for 10 minutes, the decrease rate in the film thickness after drying is within 3% of the initial film thickness (typically 50 nm).

In the present invention, from the viewpoint of uniformly coating the topcoat, a solvent having a concentration of the solid contents of the topcoat composition of 0.01% to 20%⁰ by mass, more preferably 0.1% to 15% by mass, and most preferably 1% to 10% by mass is used.

The solvent that can be used is not particularly limited as long as it can dissolve the polymer (X) which will be described later and does not dissolve the resist film, but suitable examples thereof include an alcohol-based solvent, an ether-based solvent, an ester-based solvent, a fluorine-based solvent, a hydrocarbon-based solvent, and a ketone-based solvent, with a non-fluorinated alcohol-based solvent being more preferably used. Thus, the non-dissolving property for the resist film is further enhanced and in a case where the topcoat composition is applied onto the resist film, a topcoat can be more uniformly formed without dissolving the resist film. The viscosity of the solvent is preferably 5 cP (centipoises) or less, more preferably 3 cP or less, still more preferably 2 cP or less, and particularly preferably 1 cP or less. Further, centipoises can be converted into pascal seconds according to the following formula: 1,000 cP=1 Pa·s.

From the viewpoint of coatability, the alcohol-based solvent is preferably a monohydric alcohol, and more preferably a monohydric alcohol having 4 to 8 carbon atoms. As the monohydric alcohol having 4 to 8 carbon atoms, a linear, branched, or cyclic alcohol may be used, but a linear or branched alcohol is preferable. As such an alcohol-based solvent, for example, alcohols such as 1-butanol, 2-butanol, 3-methyl-1-butanol, 4-methyl-1-pentanol, 4-methyl-2-pentanol, isobutyl alcohol, tert-butyl alcohol, 1-pentanol, 2-pentanol, 1-hexanol, 1-heptanol, 1-octanol, 2-hexanol, 2-heptanol, 2-octanol, 3-hexanol, 3-heptanol, 3-octanol, and 4-octanol; glycols such as ethylene glycol, propylene glycol, diethylene glycol, and triethylene glycol; glycol ethers such as ethylene glycol monomethyl ether, propylene glycol monomethyl ether, diethylene glycol monomethyl ether, triethylene glycol monoethyl ether, and methoxymethylbutanol; or the like can be used. Among those, alcohol and glycol ether are preferable, and 1-butanol, 1-hexanol, 1-pentanol, 3-methyl-1-butanol, 4-methyl-1-pentanol, 4-methyl-2-pentanol, and propylene glycol monomethyl ether are more preferable.

Examples of the ether-based solvent include, in addition to the glycol ether-based solvents, dioxane, tetrahydrofuran, and isoamyl ether. Among the ether-based solvents, an ether-based solvent having a branched structure is preferable.

Examples of the ester-based solvent include methyl acetate, ethyl acetate, isopropyl acetate, butyl acetate (n-butyl acetate), pentyl acetate, hexyl acetate, isoamyl acetate, butyl propionate (n-butyl propionate), butyl butyrate, isobutyl butyrate, butyl butanoate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, methyl 2-hydroxyisobutyrate, isobutyl isobutyrate, and butyl propionate. Among the ester-based solvents, an ester-based solvent having a branched structure is preferable.

Examples of the fluorine-based solvent include 2,2,3,3,4,4-hexafluoro-1-butanol, 2,2,3,3,4,4,5,5-octafluoro-1-pentanol, 2,2,3,3,4,4,5,5,6,6-decafluoro-1-hexanol, 2,2,3,3,4,4-hexafluoro-1,5-pentanediol, 2,2,3,3,4,4,5,5-octafluoro-1,6-hexanediol, 2,2,3,3,4,4,5,5,6,6,7,7-dodecafluoro-1,8-octanediol, 2-fluoroanisole, 2,3-difluoroanisole, perfluorohexane, perfluoroheptane, perfluoro-2-pentanone, perfluoro-2-butyltetrahydrofuran, perfluorotetrahydrofuran, perfluorotributylamine, and perfluorotetrapentylamine. Among these, a fluorinated alcohol and a fluorinated hydrocarbon-based solvent can be suitably used.

Examples of the hydrocarbon-based solvent include aromatic hydrocarbon-based solvents such as toluene, xylene, and anisole; and aliphatic hydrocarbon-based solvents such as n-heptane, n-nonane, n-octane, n-decane, 2-methylheptane, 3-methylheptane, 3,3-dimethylhexane, and 2,3,4-trimethylpentane.

Examples of the ketone-based solvent include 3-penten-2-one and 2-nonanone.

These solvents are used singly or as a mixture of a plurality thereof.

In a case of mixing a solvent other than those recited above, the mixing ratio thereof is usually 0% to 30% by mass, preferably 0% to 20% by mass, and more preferably 0% to 10% by mass, with respect to the total amount of solvents in the topcoat composition. By mixing a solvent other than those recited above, the solubility for the resist film, the solubility of the polymer in the topcoat composition, the elution characteristics from the resist film, or the like can be appropriately adjusted.

<Polymer (X)>

The polymer (X) in the topcoat composition is preferably transparent to the exposure light source used, in order to make light reach the resist film through a topcoat upon exposure. In a case where the polymer (X) is used for ArF liquid immersion exposure, it is preferable that the polymer has no aromatic group from the viewpoint of transparency to ArF light (wavelength: 193 nm).

The polymer (X) preferably has any one or more of a “fluorine atom,” a “silicon atom,” or a “CH₃ partial structure contained in a side chain moiety of the polymer”, and more preferably has two or more of the atoms or structure. Further, the polymer (X) is preferably a water-insoluble polymer (hydrophobic polymer).

In a case where the polymer (X) has a fluorine atom and/or a silicon atom, the fluorine atom and/or the silicon atom may be contained in the main chain or substituted in the side chain of the polymer (X).

In a case where the polymer (X) has a fluorine atom, it is preferably a polymer which has an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have another substituent.

The cycloalkyl group having a fluorine atom is a monocyclic or polycyclic cycloalkyl group in which at least one hydrogen atom is substituted with a fluorine atom, and they may further have another substituent.

The aryl group having a fluorine atom is an aryl group in which at least one hydrogen atom is substituted with a fluorine atom, such as a phenyl group and a naphthyl group, and they may further have another substituent.

Specific examples of the alkyl group having a fluorine atom, the cycloalkyl group having a fluorine atom, and the aryl group having a fluorine atom are shown below, but the present invention is not limited thereto.

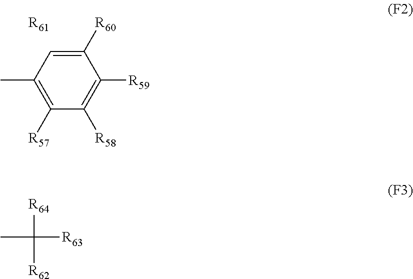

In General Formulae (F2) to (F3),

R₅₇ to R₆₄ each independently represent a hydrogen atom, a fluorine atom, or an alkyl group, provided that at least one of R₅₇, . . . , or R₆₁ or of R₆₂, . . . , or R₆₄ is a fluorine atom or an alkyl group (preferably having 1 to 4 carbon atoms) in which at least one hydrogen atom is substituted for by a fluorine atom. It is preferable that all of R₅₇ to R₆₁ are a fluorine atom. Each of R₆₂ and R₆₃ is preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be linked to each other to form a ring.

Specific examples of the group represented by General Formula (F2) include a p-fluorophenyl group, a pentafluorophenyl group, and a 3,5-di(trifluoromethyl)phenyl group.

Specific examples of the group represented by General Formula (F3) include a trifluoroethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, and a perfluorocyclohexyl group. A hexafluoroisopropyl group, a heptafluoroisopropyl group, a hexafluoro(2-methyl)isopropyl group, an octafluoroisobutyl group, a nonafluoro-t-butyl group, or a perfluoroisopentyl group is preferable, and a hexafluoroisopropyl group or a heptafluoroisopropyl group is more preferable.

In a case where the polymer (X) has a silicon atom, it is preferably a polymer having an alkylsilyl structure (preferably a trialkylsilyl group) or a cyclic siloxane structure as a partial structure having a silicon atom.

Specific examples of the alkylsilyl structure and the cyclic siloxane structure include groups represented by General Formulae (CS-1) to (CS-3).

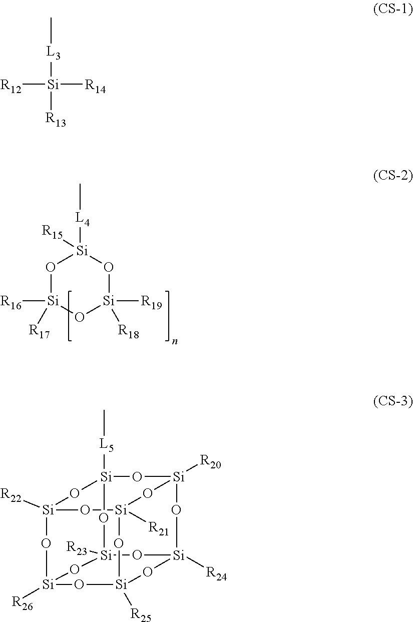

In General Formulae (CS-1) to (CS-3),

R₁₂ to R₂₆ each independently represent a linear or branched alkyl group (preferably having 1 to 20 carbon atoms) or a cycloalkyl group (preferably having 3 to 20 carbon atoms).

L₃ to L₅ each represent a single bond or a divalent linking group. Examples of the divalent linking group include one group or a combination of two or more groups selected from the group consisting of an alkylene group, a phenyl group, an ether group, a thioether group, a carbonyl group, an ester group, an amido group, a urethane group, and a urea group.

n represents an integer of 1 to 5.

Examples of the polymer (X) include a polymer having at least one repeating unit selected from the group consisting of the repeating units represented by General Formulae (C-I) to (C-V).

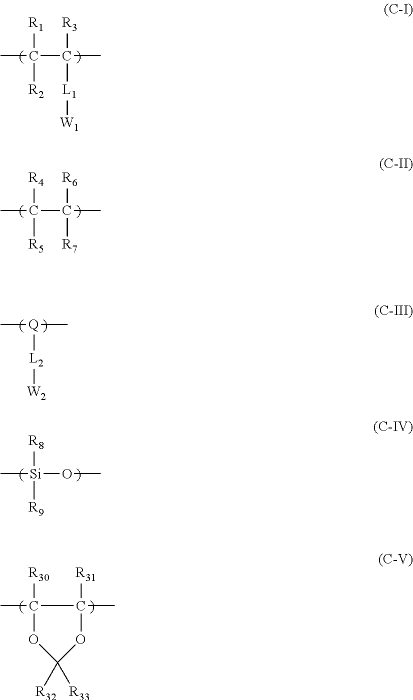

In General Formulae (C-1) to (C-V),

R₁ to R₃ each represent a hydrogen atom, a fluorine atom, a linear or branched alkyl group having 1 to 4 carbon atoms, or a linear or branched fluorinated alkyl group having 1 to 4 carbon atoms.

W₁ and W₂ each independently represent an organic group having at least one of a fluorine atom or a silicon atom.

R₄ to R₇ each independently represent a hydrogen atom, a fluorine atom, a linear or branched alkyl group having 1 to 4 carbon atoms, or a linear or branched fluorinated alkyl group having 1 to 4 carbon atoms, provided that at least one of R₄, . . . , or R₇ represents a fluorine atom. R₄ and R₅, or R₆ and R₇ may be combined to form a ring.

R₈ represents a hydrogen atom or a linear or branched alkyl group having 1 to 4 carbon atoms.

R₉ represents a linear or branched alkyl group having 1 to 4 carbon atoms or a linear or branched fluorinated alkyl group having 1 to 4 carbon atoms.

L₁ and L₂ each independently represent a single bond or a divalent linking group, which are the same as L₃ to L₅.

Q represents a monocyclic or polycyclic aliphatic group. That is, it represents an atomic group containing two carbon atoms (C—C) bonded to each other for forming an alicyclic structure.

R₃₀ and R₃₁ each independently represent a hydrogen atom or a fluorine atom.

R₃₂ and R₃₃ each independently represent an alkyl group, a cycloalkyl group, a fluorinated alkyl group, or a fluorinated cycloalkyl group.

It is to be noted that the repeating unit represented by General Formula (C-V) has at least one fluorine atom in at least one of R₃₀, R₃₁, R₃₂, or R₃₃.

The polymer (X) preferably has a repeating unit represented by General Formula (C-I), and more preferably a repeating unit represented by any of General Formulae (C-Ia) to (C-Id).

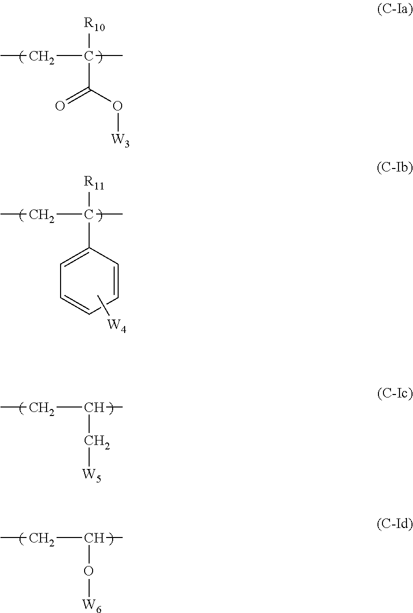

In General Formulae (C-Ia) to (C-Id),

R₁₀ and R₁₁ each represents a hydrogen atom, a fluorine atom, a linear or branched alkyl group having 1 to 4 carbon atoms, or a linear or branched fluorinated alkyl group having 1 to 4 carbon atoms.

W₃ to W₆ are each an organic group having one or more of at least one of a fluorine atom or a silicon atom.

When W₃ to W₆ are each an organic group having a fluorine atom, they are each preferably a fluorinated, linear or branched alkyl group or cycloalkyl group having 1 to 20 carbon atoms, or a linear, branched, or cyclic fluorinated alkyl ether group having 1 to 20 carbon atoms.

Examples of the fluorinated alkyl group represented by each of W₃ to W₆ include a trifluoroethyl group, a pentafluoropropyl group, a hexafluoroisopropyl group, a hexafluoro(2-methyl)isopropyl group, a heptafluorobutyl group, a heptafluoroisopropyl group, an octafluoroisobutyl group, a nonafluorohexyl group, a nonafluoro-t-butyl group, a perfluoroisopentyl group, a perfluorooctyl group, and a perfluoro(trimethyl)hexyl group.

When W₃ to W₆ are each an organic group having a silicon atom, an alkylsilyl structure or a cyclic siloxane structure is preferable. Specific examples thereof include groups represented by General Formulae (CS-1) to (CS-3).

Specific examples of the repeating unit represented by General Formula (C-I) are shown below, but are not limited thereto. X represents a hydrogen atom, —CH₃, —F, or —CF₃.

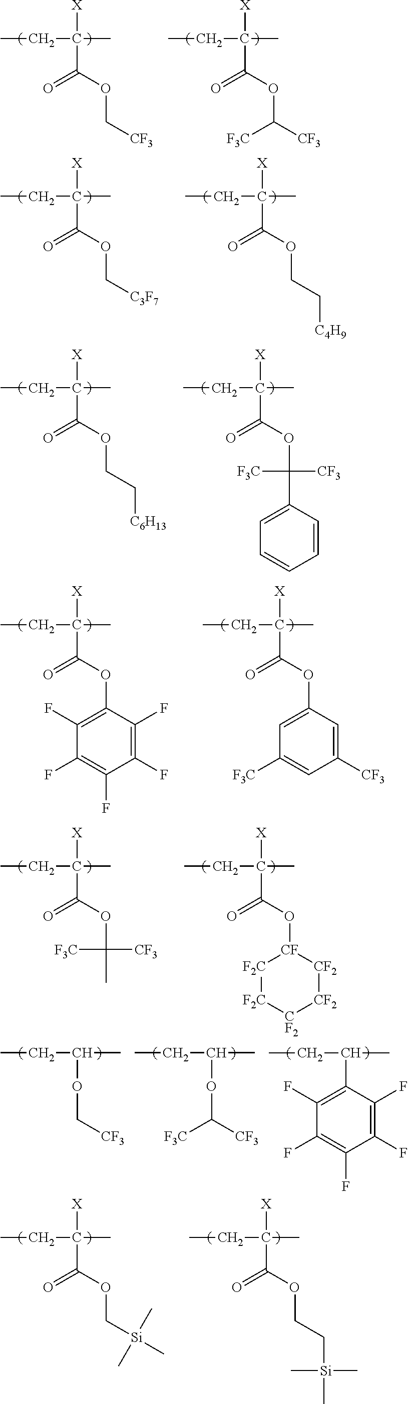

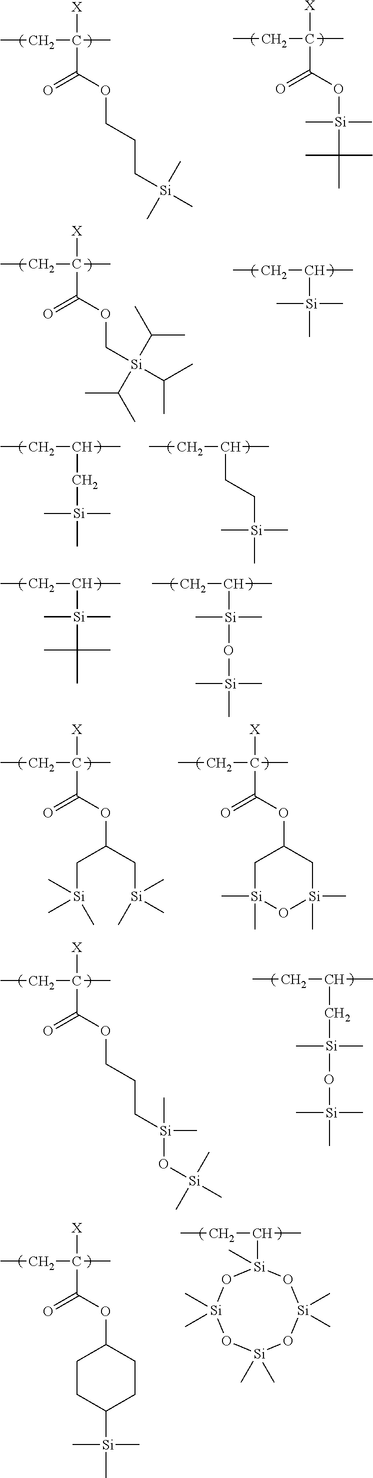

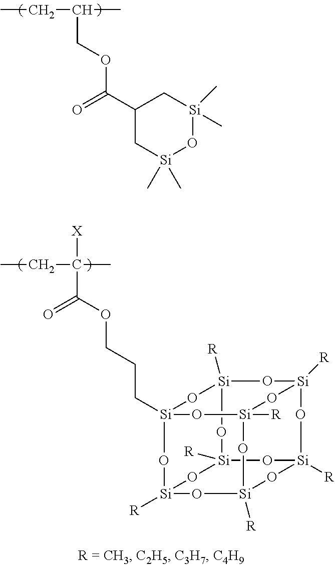

Furthermore, it is also preferable that the polymer (X) includes a CH₃ partial structure in the side chain moiety, as described above. The polymer (X) preferably includes a repeating unit having at least one CH₃ partial structure in the side chain moiety, more preferably includes a repeating unit having at least two CH₃ partial structures in the side chain moiety, and still more preferably includes a repeating unit having at least three CH₃ partial structures in the side chain moiety.

Here, the CH₃ partial structure (hereinafter also simply referred to as a “side chain CH₃ partial structure”) contained in the side chain moiety in the polymer (X) includes a CH₃ partial structure contained in an ethyl group, a propyl group, or the like.

On the other band, a methyl group bonded directly to the main chain of the polymer (X) (for example, an α-methyl group in the repeating unit having a methacrylic acid structure) only makes a small contribution of uneven distribution to the surface of the polymer (X) due to the effect of the main chain, and it is therefore not included in the CH₃ partial structure in the present invention.

More specifically, in a case where the polymer (X) contains a repeating unit derived from a monomer having a polymerizable moiety with a carbon-carbon double bond, such as a repeating unit represented by General Formula (M), and in addition, R₁₁ to R₁₄ are CH₃ “themselves,” such CH₃ is not included in the CH₃ partial structure contained in the side chain moiety in the present invention.

On the other hand, a CH₃ partial structure which is present via a certain atom from a C—C main chain corresponds to the CH₃ partial structure in the present invention. For example, in a case where R₁₁ is an ethyl group (CH₂CH₃), the polymer (X) has “one” CH₃ partial structure in the present invention.

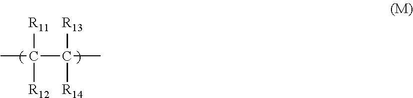

In General Formula (M),

R₁₁ to R₁₄ each independently represent a side chain moiety.

Examples of R₁₁ to R₁₄ in the side chain moiety include a hydrogen atom and a monovalent organic group.

Examples of the monovalent organic group for R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, each of which may further have a substituent.

The polymer (X) is preferably a polymer including a repeating unit having the CH₃ partial structure in the side chain moiety thereof, and more preferably has, as such a repeating unit, at least one repeating unit (x) of a repeating unit represented by General Formula (II) or a repeating unit represented by General Formula (III). In particular, in a case where KrF, EUV, or electron beams (EB) are used as an exposure light source, the polymer (X) can suitably include the repeating unit represented by General Formula (III).

Hereinafter, the repeating unit represented by General Formula (II) will be described in detail.

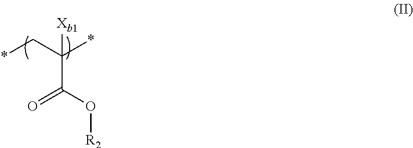

In General Formula (II), X_{b1} represents a hydrogen atom, an alkyl group, a cyano group, or a halogen atom, and R₂ represents an organic group which has one or more CH₃ partial structures and is stable against an acid. Here, more specifically, the organic group which is stable against an acid is preferably an organic group which does not have a “group that decomposes by the action of an acid to generate a polar group” described above with respect to the resin (A).

The alkyl group of X_{b1} is preferably an alkyl group having 1 to 4 carbon atoms, and examples thereof include a methyl group, an ethyl group, a propyl group, a hydroxymethyl group, and a trifluoromethyl group, with the methyl group being preferable.

X_{b1} is preferably a hydrogen atom or a methyl group.

Examples of R₂ include an alkyl group, a cycloalkyl group, an alkenyl group, a cycloalkenyl group, an aryl group, and an aralkyl group, each of which has one or more CH₃ partial structures. The cycloalkyl group, the alkenyl group, the cycloalkenyl group, the aryl group, and the aralkyl group may further have an alkyl group as a substituent.

R₂ is preferably an alkyl group or an alkyl-substituted cycloalkyl group, which has one or more CH₃ partial structures.

The number of the CH₃ partial structures contained in the organic group which has one or more CH₃ partial structures and is stable against an acid as R₂ is preferably from 2 to 10, and more preferably from 2 to 8.

The alkyl group having one or more CH₃ partial structures in R₂ is preferably a branched alkyl group having 3 to 20 carbon atoms. Specific preferred examples of the alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group, and the alkyl group is more preferably an isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, or a 2,3,5,7-tetramethyl-4-heptyl group.

The cycloalkyl group having one or more CH₃ partial structures in R₂ may be monocyclic or polycyclic. Specific examples thereof include groups having a monocyclo, bicyclo, tricyclo, or tetracyclo structure having 5 or more carbon atoms. The number of carbon atoms is preferably 6 to 30, and particularly preferably 7 to 25. Preferred examples of the cycloalkyl group include an adamantyl group, a noradamantyl group, a decalin residue, a tricyclodecanyl group, a tetracyclododecanyl group, a norbornyl group, cedrol group, a cyclopentyl group, a cyclohexyl group, a cycloheptyl group, a cyclooctyl group, a cyclodecanyl group, and a cyclododecanyl group, and the cycloalkyl group is more preferably an adamantyl group, a norbornyl group, a cyclohexyl group, a cyclopentyl group, a tetracyclododecanyl group, or a tricyclodecanyl group, and even more preferably a norbornyl group, a cyclopentyl group, or a cyclohexyl group.

The alkenyl group having one or more CH₃ partial structures in R₂ is preferably a linear or branched alkenyl group having 1 to 20 carbon atoms, and more preferably a branched alkenyl group.

The aryl group having one or more CH₃ partial structures in R₂ is preferably an aryl group having 6 to 20 carbon atoms, and examples thereof include a phenyl group and a naphthyl group, and the aryl group is preferably a phenyl group.

The aralkyl group having one or more CH₃ partial structures in R₂ is preferably an aralkyl group having 7 to 12 carbon atoms, and examples thereof include a benzyl group, a phenethyl group, and a naphthylmethyl group.

Specific examples of the hydrocarbon group having two or more CH₃ partial structures in R₂ include an isopropyl group, an isobutyl group, a t-butyl group, a 3-pentyl group, a 2-methyl-3-butyl group, a 3-hexyl group, a 2,3-dimethyl-2-butyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 4-isopropylcyclohexyl group, a 4-t-butylcyclohexyl group, and an isobornyl group. The hydrocarbon structure is more preferably an isobutyl group, a t-butyl group, a 2-methyl-3-butyl group, a 2,3-dimethyl-2-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 3,5-di-tert-butylcyclohexyl group, a 4-isopropylcyclohexyl group, a 4-t-butylcyclohexyl group, or an isobornyl group.

Specific preferred examples of the repeating unit represented by General Formula (II) are shown below. The present invention is not limited thereto.

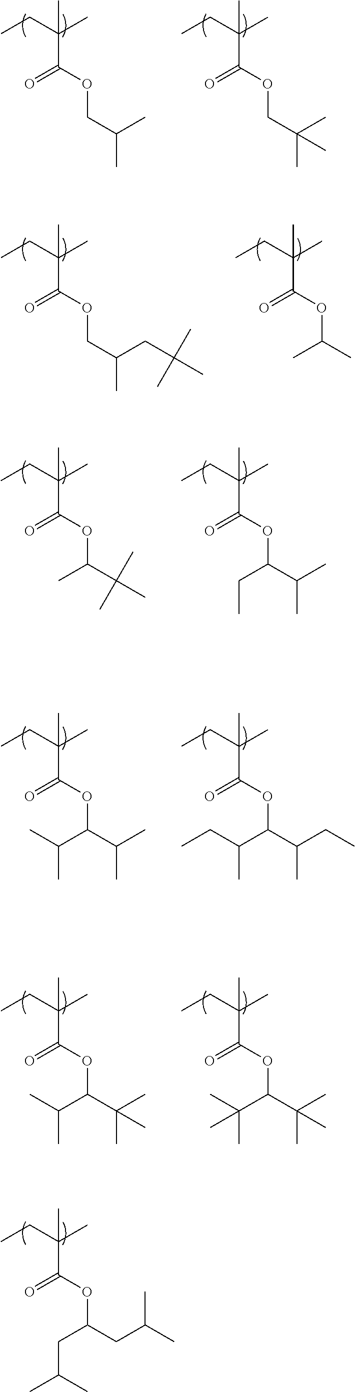

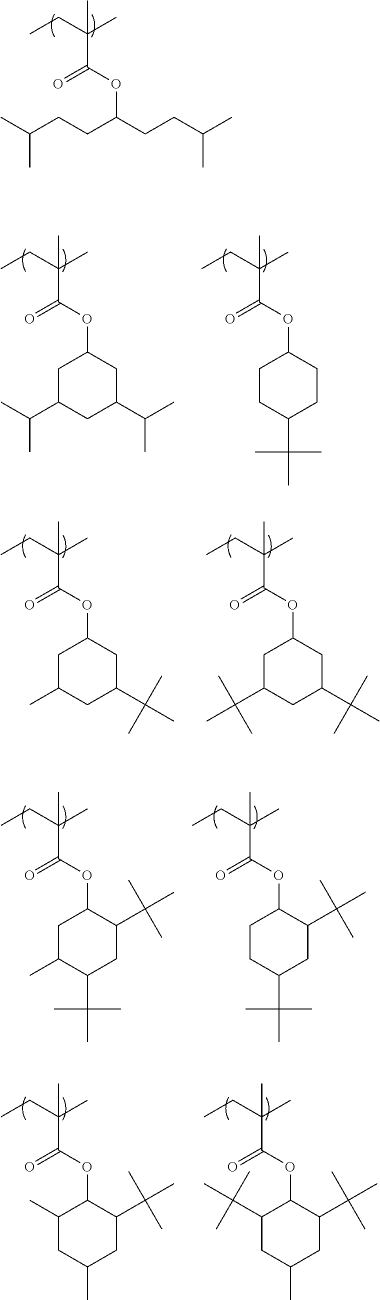

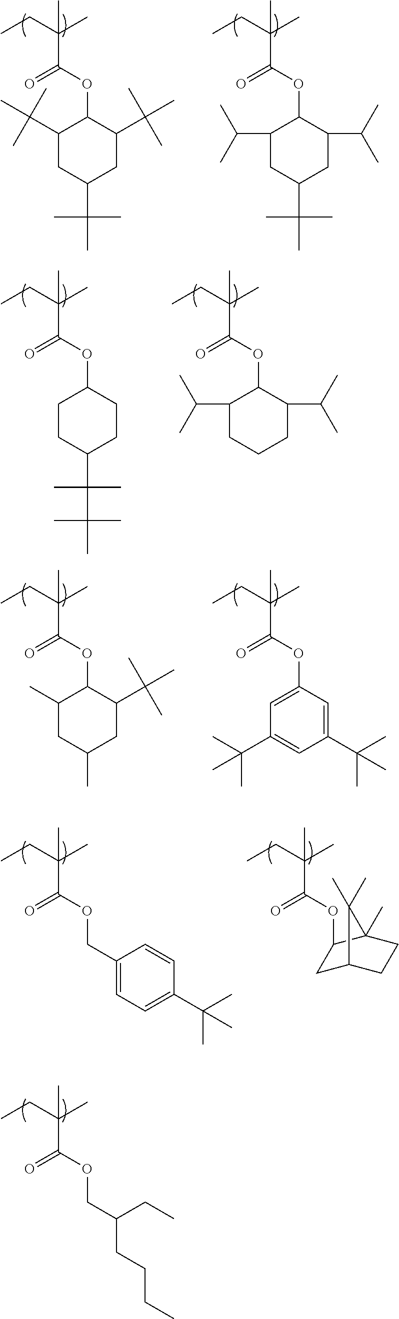

The repeating unit represented by General Formula (II) is preferably a repeating unit which is stable against an acid (non-acid-decomposable), and specifically, it is preferably a repeating unit not having a group that decomposes by the action of an acid to generate a polar group.

Hereinafter, the repeating unit represented by General Formula (III) will be described in detail.

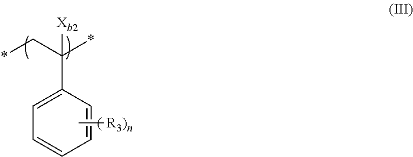

In General Formula (III), X_{b2} represents a hydrogen atom, an alkyl group, a cyano group, or a halogen atom, R₃ represents an organic group having one or more CH₃ partial structures, which is stable against an acid, and n represents an integer of 1 to 5.

The alkyl group of X_{b2} is preferably an alkyl group having 1 to 4 carbon atoms, and examples thereof include a methyl group, an ethyl group, a propyl group, a hydroxymethyl group, and a trifluoromethyl group, but a hydrogen atom is preferable.

X_{b2} is preferably a hydrogen atom.

Since R₃ is an organic group which is stable against an acid, more specifically, R₃ is preferably an organic group which does not have the “group that decomposes by the action of an acid to generate a polar group” described later with respect to a resin (A).

Examples of R₃ include an alkyl group having one or more CH₃ partial structures.

The number of the CH₃ partial structures contained in the organic group which has one or more CH₃ partial structures and is stable against an acid as R₃ is preferably from 1 to 10, more preferably from 1 to 8, and still more preferably from 1 to 4.

The alkyl group having one or more CH₃ partial structures in R₃ is preferably a branched alkyl group having 3 to 20 carbon atoms. Specific preferred examples of the alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group. The alkyl group is more preferably an isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, or a 2,3,5,7-tetramethyl-4-heptyl group.

Specific examples of the alkyl group having two or more CH₃ partial structures in R₃ include an isopropyl group, an isobutyl group, a t-butyl group, a 3-pentyl group, a 2,3-dimethylbutyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group. The alkyl group is more preferably one having 5 to 20 carbon atoms, and is more preferably an isopropyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, or a 2,3,5,7-tetramethyl-4-heptyl group.

n represents an integer of 1 to 5, preferably an integer of 1 to 3, and more preferably 1 or 2.

Specific preferred examples of the repeating unit represented by General Formula (III) are shown below. The present invention is not limited thereto.

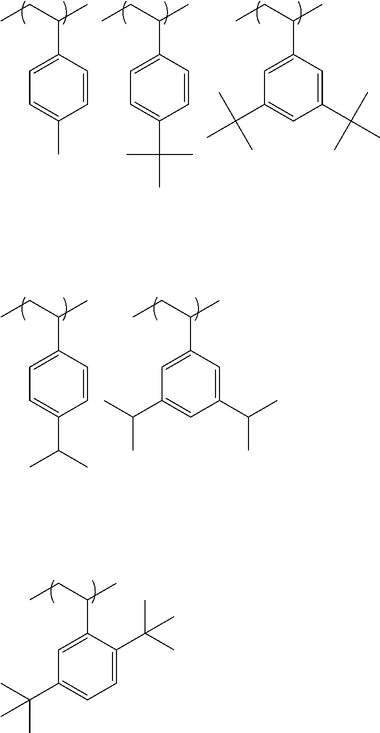

The repeating unit represented by General Formula (III) is preferably a repeating unit which is stable against an acid (non-acid-decomposable), and specifically, it is preferably a repeating unit which does not have a group that decomposes by the action of an acid to generate a polar group.

In a case where the polymer (X) includes a CH₃ partial structure in the side chain moiety, and in particular, in a case where the polymer (X) has neither a fluorine atom nor a silicon atom, the content of at least one repeating unit (x) of the repeating unit represented by General Formula (II) or the repeating unit represented by General Formula (III) is preferably 90% by mole or more, and more preferably 95% by mole or more, with respect to all the repeating units of the polymer (X).

In order to adjust the solubility in an organic developer, the polymer (X) may have a repeating unit represented by General Formula (Ia).

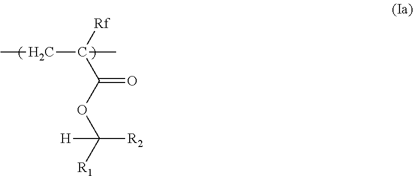

In General Formula (Ia),

Rf represents a fluorine atom or an alkyl group in which at least one hydrogen atom is substituted with a fluorine atom.

R₁ represents an alkyl group.

R₂ represents a hydrogen atom or an alkyl group.

In General Formula (Ia), the alkyl group in which at least one hydrogen atom is substituted with a fluorine atom among Rf's is preferably one having 1 to 3 carbon atoms, and more preferably a trifluoromethyl group.

The alkyl group of R₁ is preferably a linear or branched alkyl group having 3 to 10 carbon atoms, and more preferably a branched alkyl group having 3 to 10 carbon atoms.

R₂ is preferably a linear or branched alkyl group having 1 to 10 carbon atoms, and more preferably a linear or branched alkyl group having 3 to 10 carbon atoms.

Specific examples of the repeating unit represented by General Formula (Ia) are shown below, but the present invention is not limited thereto.

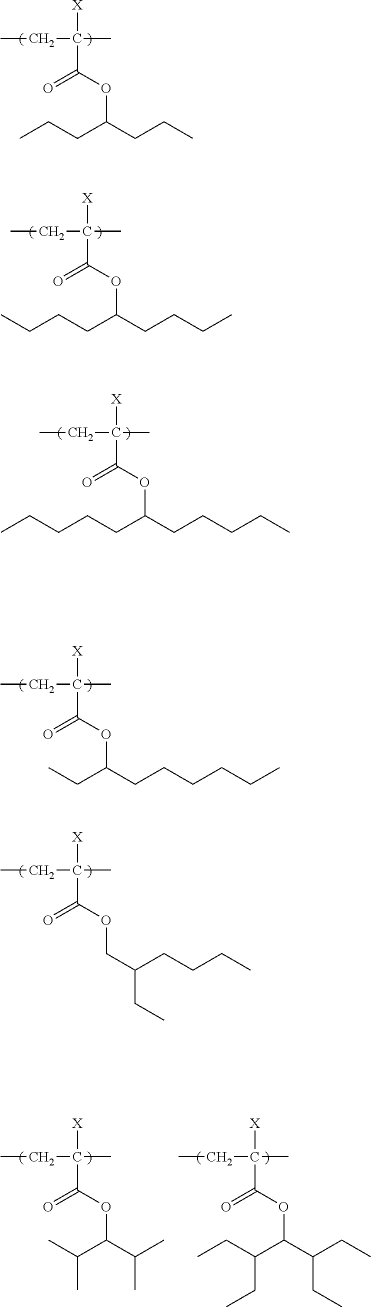

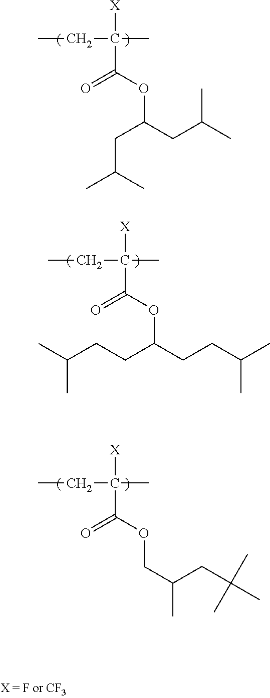

The polymer (X) may further have a repeating unit represented by General Formula (III).

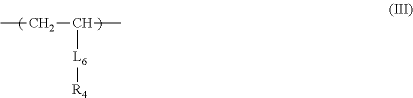

In General Formula (III),

R₄ represents an alkyl group, a cycloalkyl group, an alkenyl group, a cycloalkenyl group, a trialkylsilyl group, or a group having a cyclic siloxane structure.

L₆ represents a single bond or a divalent linking group.

In General Formula (III), the alkyl group of R₄ is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The trialkylsilyl group is preferably a trialkylsilyl group having 3 to 20 carbon atoms.

The group having a cyclic siloxane structure is preferably a group containing a cyclic siloxane structure having 3 to 20 carbon atoms.

The divalent linking group of L₆ is preferably an alkylene group (preferably having 1 to 5 carbon atoms) or an oxy group.

The polymer (X) may have a lactone group, an ester group, an acid anhydride, or the same group as the acid-decomposable group in the resin (A).

The polymer (X) may further have a repeating unit represented by General Formula (VIII).

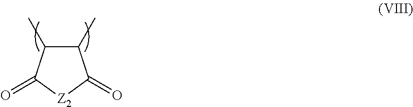

In General Formula (VIII),

Z₂ represents —O— or —N(R₄₁)—. R₄₁ represents a hydrogen atom, a hydroxyl group, an alkyl group or —OSO₂—R₄₂. R₄₂ represents an alkyl group, a cycloalkyl group, or a camphor residue. The alkyl group of each of R₄₁ and R₄₂ may further be substituted with a halogen atom (preferably a fluorine atom) or the like.

Examples of the repeating unit represented by General Formula (VIII) include the following specific examples, but the present invention is not limited thereto.

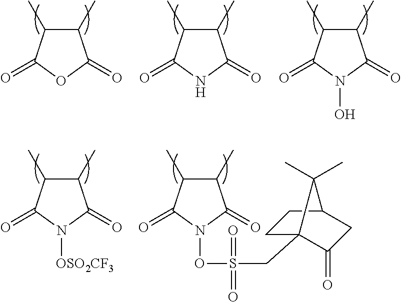

The polymer (X) preferably contains a repeating unit (d) derived from a monomer having an alkali-soluble group. Thus, it is possible to control the solubility in an immersion liquid and the solubility in a coating solvent. Examples of the alkali-soluble group include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a group having a tris(alkylsulfonyl)methylene group.

As the monomer having an alkali-soluble group, a monomer having an acid dissociation constant pKa of 4 or more is preferable, a monomer having a pKa of 4 to 13 is more preferable, and a monomer having a pKa of 8 to 13 is most preferable. By incorporation of a monomer having a pKa of 4 or more, swelling upon development of a negative tone and a positive tone is suppressed, and thus, not only good developability for an organic developer but also good developability in a case of using an alkali developer are obtained.

The acid dissociation constant pKa is described in Chemical Handbook (II) (Revised 4^{th} Edition, 1993, compiled by the Chemical Society of Japan, Maruzen Inc.), and the pKa value of a monomer having an alkali-soluble group can be measured, for example, at 25° C. using an infinite-dilution solvent.

The monomer having a pKa of 4 or more is not particularly limited, and examples thereof include a monomer containing an acid group (an alkali-soluble group) such as a phenolic hydroxyl group, a sulfonamido group, —COCH₂CO—, a fluoroalcohol group, and a carboxylic acid group. A monomer containing a fluoroalcohol group is particularly preferable. The fluoroalcohol group is a fluoroalkyl group substituted with at least one hydroxyl group, preferably having 1 to 10 carbon atoms, and more preferably 1 to 5 carbon atoms. Specific examples of the fluoroalcohol group include —CF₂OH, —CH₂CF₂OH, —CH₂CF₂CF₂OH, —C(CF₃)₂OH, —CF₂CF(CF₃)OH, and —CH₂C(CF₃)₂OH. As a fluoroalcohol group, a hexafluoroisopropanol group is particularly preferable.

The total amount of the repeating unit derived from a monomer having an alkali-soluble group in the polymer (X) is preferably 0% to 90% by mole, more preferably 0% to 80% by mole, and still more preferably 0% to 70% by mole, with respect to all the repeating units constituting the polymer (X).

The monomer having an alkali-soluble group may contain only one or two or more acid groups. The repeating unit derived from the monomer preferably has 2 or more acid groups, more preferably 2 to 5 acid groups, and particularly preferably 2 or 3 acid groups, per one repeating unit.

Specific examples of the repeating unit derived from a monomer having an alkali-soluble group include, but not limited to, those described in paragraphs [0278] to [0287] of JP2008-309878A.

In one of the preferred aspects, the polymer (X) may be any polymer selected from (X-1) to (X-8) described in paragraph [0288] of JP2008-309878A.

The polymer (X) is preferably solid at normal temperature (25° C.). Further, the glass transition temperature (Tg) is preferably 50° C. to 250° C., more preferably 70° C. to 250° C., still more preferably 80° C. to 250° C., particularly preferably 90° C. to 250° C., and most preferably 100° C. to 250° C.

The polymer (X) preferably has a repeating unit having a monocyclic or polycyclic cycloalkyl group. The monocyclic or polycyclic cycloalkyl group may be included in any one of the main chain and the side chain of the repeating unit. The polymer (X) more preferably has a repeating unit having both of a monocyclic or polycyclic cycloalkyl group and a CH₃ partial structure, and still more preferably a repeating unit having both of a monocyclic or polycyclic cycloalkyl group and a CH₃ partial structure in the side chain.

The polymer being solid at 25*C means that the melting point is 25° C. or higher. The glass transition temperature (Tg) can be measured by a differential scanning calorimetry. For example, it can be determined by after heating a sample and then cooling, analyzing the change in the specific volume when the sample is heated again at 5° C./min.

It is preferable that the polymer (X) is insoluble in an immersion liquid (preferably water) and is soluble in an organic developer. From the viewpoint of the possibility of release by development using an alkali developer, it is preferable that the polymer (X) is also soluble in an alkali developer.

In a case where the polymer (X) has silicon atoms, the content of the silicon atoms is preferably 2% to 50% by mass, and more preferably 2% to 30% by mass, with respect to the molecular weight of the polymer (X). Further, the amount of the repeating units containing silicon atoms is preferably 10% to 100% by mass, and more preferably 20% to 100% by mass, in the polymer (X).

In a case where the polymer (X) contains fluorine atoms, the content of fluorine atoms is preferably 5% to 80% by mass, and more preferably 10% to 80% by mass, with respect to the molecular weight of the polymer (X). Further, the content of the repeating units containing fluorine atoms is preferably 10% to 100% by mass, and more preferably 30% to 100% by mass, in the polymer (X).

On the other hand, particularly in a case where the polymer (X) includes a CH₃ partial structure in the side chain moiety, an aspect in which the polymer (X) does not substantially contain a fluorine atom is also preferable, and in this case, specifically, the content of the repeating unit having a fluorine atom in the polymer (X) is preferably 0% to 20% by mole, more preferably 0% to 10% by mole, still more preferably 0% to 5% by mole, particularly preferably 0% to 3% by mole, and ideally 0% by mole, that is, containing no fluorine atom, with respect to all the repeating units.

Furthermore, the polymer (X) preferably consists substantially only of a repeating unit composed of only atoms selected from a carbon atom, an oxygen atom, a hydrogen atom, a nitrogen atom, and a sulfur atom. More specifically, the repeating unit composed of only atoms selected from a carbon atom, an oxygen atom, a hydrogen atom, a nitrogen atom, and a sulfur atom preferably accounts for 95% by mole or more, more preferably 97% by mole or more, still more preferably 99% by mole or more, and ideally 100% by mole, with respect to all the repeating units in the polymer (X).

The weight-average molecular weight of the polymer (X) measured by GPC is preferably 2,000 to 20,000, and more preferably 2,000 to 12,000, in terms of standard polystyrene.

In the polymer (X), naturally, it is preferable that the content of impurities such as metal is small, but the amount of residual monomers is preferably 0% to 10% by mass, more preferably 0% to 5% by mass, and still more preferably 0% to 1% by mass, from the viewpoint of reduction in elution from a topcoat to an immersion liquid. Further, the molecular weight distribution (Mw/Mn, also referred to as dispersity) is preferably 1 to 5, more preferably in a range of 1 to 3, and still more preferably in a range of 1 to 1.95.

The polymer (X) may be used singly or in combination of a plurality thereof.

The blend amount of the polymer (X) in the entire topcoat composition is preferably 50% to 99.9% by mass, and more preferably 60% to 99.0% by mass, with respect to the total solid content.

The topcoat composition preferably further includes at least one compound selected from the group consisting of (A1) a basic compound or base generator, and (A2) a compound containing a bond or group selected from the group consisting of an ether bond, a thioether bond, a hydroxyl group, a thiol group, a carbonyl bond, and an ester bond.

<(A1) Basic Compound or Base Generator>

The topcoat composition preferably further contains at least one of a basic compound or a base generator (hereinafter collectively referred to as an “additive” or a “compound (A1)” in some cases), whereby the effects of the present invention are more excellent.

(Basic Compound)

As the basic compound which can be contained in the topcoat composition, an organic basic compound is preferable, and a nitrogen-containing basic compound is more preferable. For example, the same ones as the basic compound which may be contained in the resist composition of the present invention can be used, and specific suitable examples thereof include the compounds having the structures represented by Formulae (A) to (E) which will be described later.

In addition, for example, the compounds which are classified into (1) to (7) below can be used.

(1) Compound Represented by General Formula (BS-1)

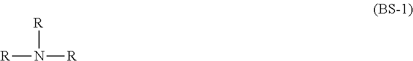

In General Formula (BS-1),

R's each independently represent a hydrogen atom or an organic group. Here, at least one of three R's is an organic group. This organic group is a linear or branched alkyl group, a monocyclic or polycyclic cycloalkyl group, an aryl group, or an aralkyl group.

The number of carbon atoms in the alkyl group as R is not particularly limited, but is normally 1 to 20, and preferably 1 to 12.

The number of carbon atoms in the cycloalkyl group as R is not particularly limited, but is normally 3 to 20, and preferably 5 to 15.

The number of carbon atoms in the aryl group as R is not particularly limited, but is normally 6 to 20, and preferably 6 to 10. Specific examples thereof include a phenyl group and a naphthyl group.

The number of carbon atoms in the aralkyl group as R is not particularly limited, but is normally 7 to 20, and preferably 7 to 11. Specifically, examples thereof include a benzyl group.

A hydrogen atom in the alkyl group, the cycloalkyl group, the aryl group, or the aralkyl group as R may be substituted with a substituent. Examples of the substituent include an alkyl group, a cycloalkyl group, an aryl group, an aralkyl group, a hydroxyl group, a carboxyl group, an alkoxy group, an aryloxy group, an alkylcarbonyloxy group, and an alkyloxycarbonyl group.

Furthermore, it is preferable that at least two of R's in the compound represented by General Formula (BS-1) are organic groups.

Specific examples of the compound represented by General Formula (BS-1) include tri-n-butylamine, tri-isopropylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyl octadecylamine, dimethylundecylamine, N,N-dimethyldodecylamine, methyl dioctadecylamine, N,N-dibutylaniline, N,N-dihexylaniline, 2,6-diisopropylaniline, and 2,4,6-tri(t-butyl)aniline.

In addition, as the preferable basic compound represented by General Formula (BS-1), an alkyl group in which at least one R is substituted with a hydroxyl group is exemplified. Specific examples thereof include triethanolamine and N,N-dihydroxyethylaniline.

Moreover, the alkyl group as R may have an oxygen atom in the alkyl chain. That is, an oxyalkylene chain may be formed. As the oxyalkylene chain, —CH₂CH₂O— is preferable. Specific examples thereof include tris(methoxyethoxyethyl)amine and a compound disclosed after line 60 of column 3 in the specification of U.S. Pat. No. 6,040,112A.

Examples of the basic compound represented by General Formula (BS-1) include the following ones.

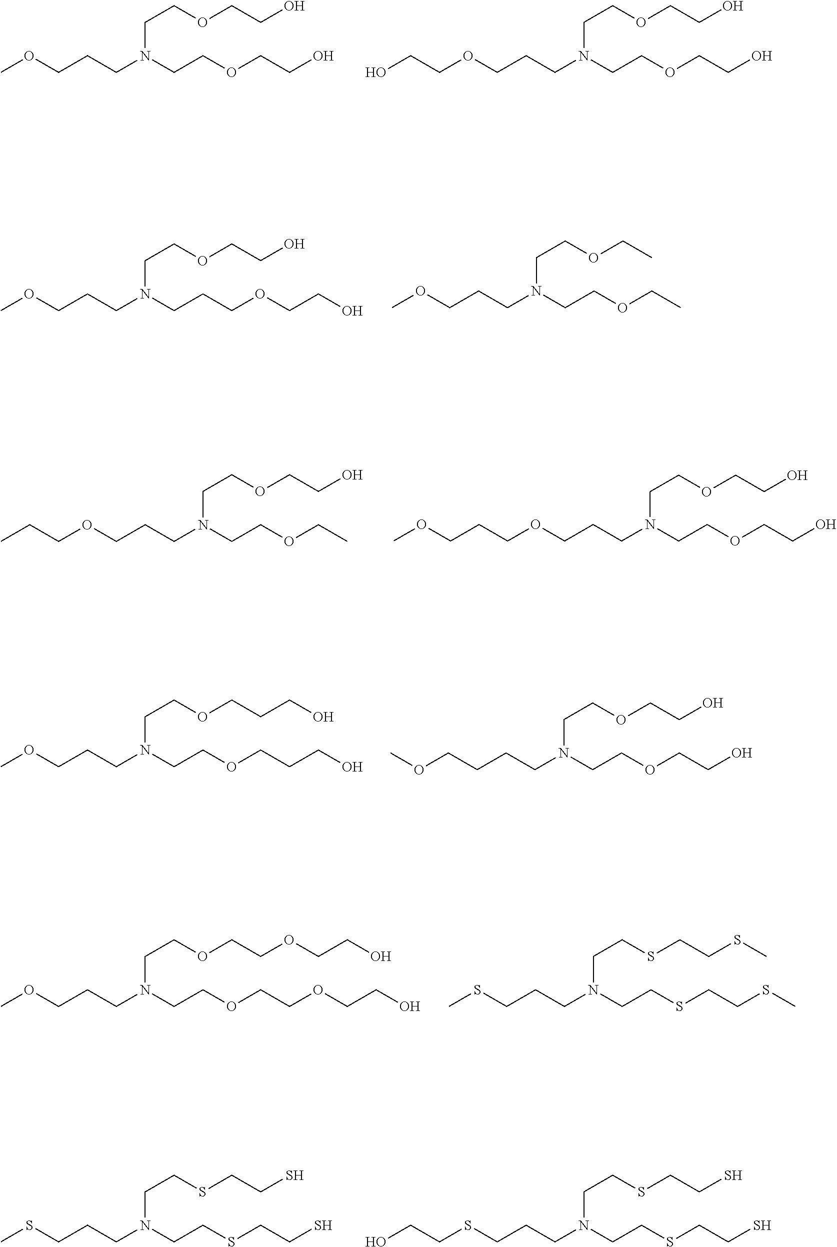

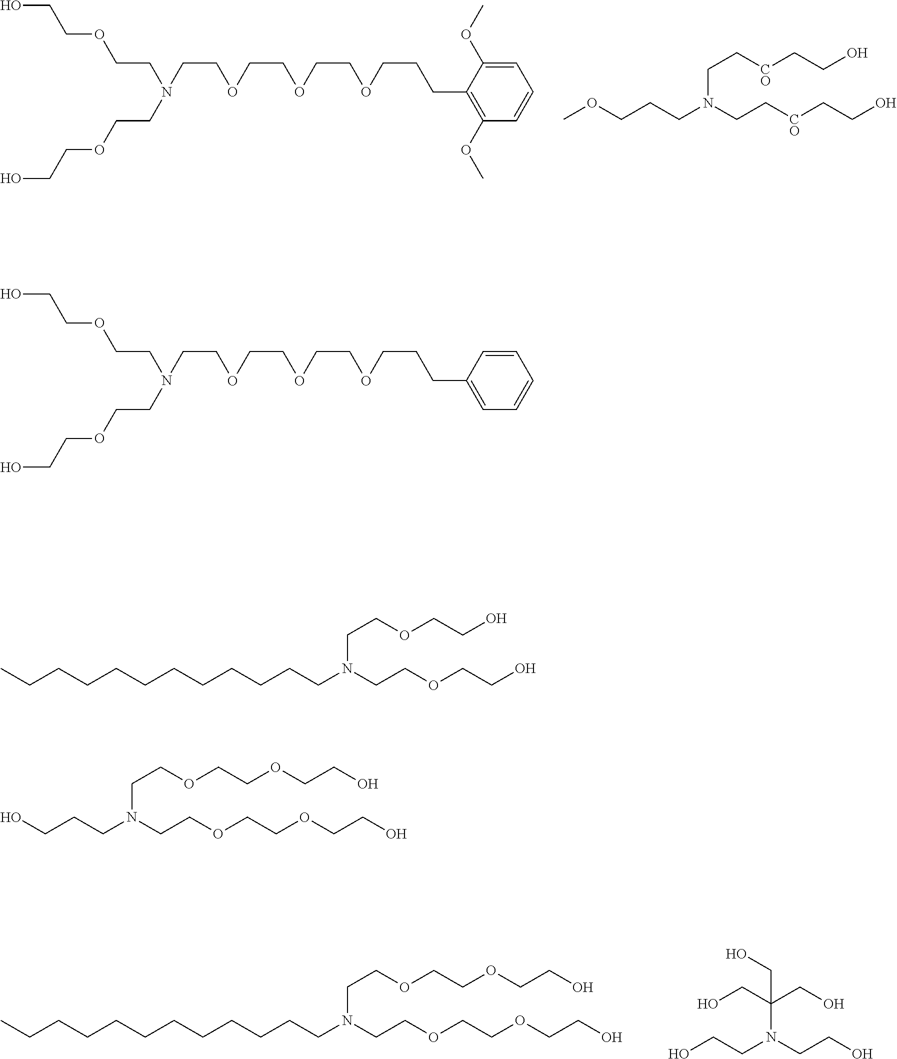

(2) Compound Having Nitrogen-Containing Heterocyclic Structure

The nitrogen-containing heterocycle may have aromatic properties, or may not have aromatic properties. The nitrogen-containing heterocycle may have a plurality of nitrogen atoms. Furthermore, the nitrogen-containing heterocycle may contain heteroatoms other than the nitrogen atom. Specific examples thereof include a compound having an imidazole structure (2-phenylbenzimidazole, 2,4,5-triphenylimidazole and the like), a compound having a piperidine structure [N-hydroxyethylpiperidine, bis(1,2,2,6,6-pentamethyl-4-piperidyl)sebacate, and the like], a compound having a pyridine structure (4-dimethylaminopyridine and the like), and a compound having an antipyrine structure (antipyrine, hydroxyantipyrine, and the like).

Furthermore, a compound having two or more ring structures is suitably used. Specific examples thereof include 1,5-diazabicyclo[4.3.0]non-5-ene and 1,8-diazabicyclo[5.4.0]undec-7-ene.

(3) Amine Compound Having Phenoxy Group

An amine compound having a phenoxy group is a compound having a phenoxy group at the terminal on the opposite side to the N atom of the alkyl group which is contained in an amine compound. The phenoxy group may have a substituent such as an alkyl group, an alkoxy group, a halogen atom, a cyano group, a nitro group, a carboxyl group, a carboxylic acid ester group, a sulfonic acid ester group, an aryl group, an aralkyl group, an acyloxy group, or an aryloxy group.

This compound more preferably has at least one oxyalkylene chain between the phenoxy group and the nitrogen atom. The number of oxyalkylene chains in one molecule is preferably 3 to 9, and more preferably 4 to 6. Among oxyalkylene chains, —CH₂CH₂O— is particularly preterable.

Specific examples thereof include 2-[2-{2-(2,2-dimethoxyphenoxyethoxy)ethyl}-bis-(2-methoxyethyl)amine and the compounds (C1-1) to (C3-3) exemplified in paragraph 100661 in the specification of US2007/0224539A1.

An amine compound having a phenoxy group is obtained by, for example, heating a mixture of a primary or secondary amine having a phenoxy group and an haloalkyl ether to be reacted, by adding an aqueous solution of a strong base such as sodium hydroxide, potassium hydroxide, or tetraalkylammonium thereto, and by extracting the resultant product with an organic solvent such as ethyl acetate and chloroform. In addition, an amine compound having a phenoxy group can also be obtained by heating a mixture of a primary or secondary amine and an haloalkyl ether having a phenoxy group at the terminal to be reacted, by adding an aqueous solution of a strong base such as sodium hydroxide, potassium hydroxide, or tetraalkylammonium thereto, and by extracting the resultant product with an organic solvent such as ethyl acetate and chloroform.

(4) Ammonium Salt

An ammonium salt can also be appropriately used as the basic compound. Examples of the anion of the ammonium salt include halide, sulfonate, borate, and phosphate. Among these, halide and sulfonate are particularly preferable.

As the halide, chloride, bromide, or iodide is particularly preferable.

As the sulfonate, an organic sulfonate having 1 to 20 carbon atoms is particularly preferable. Examples of the organic sulfonate include alkyl sulfonate and aryl sulfonate having 1 to 20 carbon atoms.

The alkyl group included in the alkyl sulfonate may have a substituent. Examples of the substituent include a fluorine atom, a chlorine atom, a bromine atom, an alkoxy group, an acyl group, and an aryl group. Specific examples of the alkyl sulfonate include methanesulfonate, ethanesulfonate, butanesulfonate, hexanesulfonate, octanesulfonate, benzylsulfonate, trifluoromethanesulfonate, pentafluoroethanesulfonate, and nonafluorobutanesulfonate.

Examples of the aryl group included in the aryl sulfonate include a phenyl group, a naphthyl group, and an anthryl group. These aryl groups may have a substituent. As the substituent, for example, a linear or branched alkyl group having 1 to 6 carbon atoms or a cycloalkyl group having 3 to 6 carbon atoms is preferable. Specifically, for example, a methyl group, an ethyl group, an n-propyl group, an isopropyl group, an n-butyl group, an i-butyl group, a t-butyl group, an n-hexyl group, or a cyclohexyl group is preferable. Examples of other substituents include an alkoxy group having 1 to 6 carbon atoms, a halogen atom, a cyano group, a nitro group, an acyl group, and an acyloxy group.

The ammonium salt may be a hydroxide or a carboxylate. In this case, the ammonium salt is particularly preferably tetraalkylammonium hydroxide (tetraalkylammonium hydroxide such as tetramethylammonium hydroxide, tetraethylammonium hydroxide, or tetra-(n-butyl)ammonium hydroxide) having 1 to 8 carbon atoms.

Preferred examples of the basic compound include guanidine, aminopyridine, aminoalkylpyridine, aminopyrrolidine, indazole, imidazole, pyrazole, pyrazine, pyrimidine, purine, imidazoline, pyrazoline, piperazine, aminomorpholine, and aminoalkylmorpholine. These may further have a substituent.

Preferred examples of the substituent include an amino group, an aminoalkyl group, an alkylamino group, an aminoaryl group, an arylamino group, an alkyl group, an alkoxy group, an acyl group, an acyloxy group, an aryl group, an aryloxy group, a nitro group, a hydroxyl group, and a cyano group.

Particularly preferred examples of the basic compound include guanidine, 1,1-dimethylguanidine, 1,1,3,3-tetramethylguanidine, imidazole, 2-methylimidazole, 4-methylimidazole, N-methylimidazole, 2-phenylimidazole, 4,5-diphenylimidazole, 2,4,5-triphenylimidazole, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethyl piperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-S-methylpyrazine, pyrimidine, 2,4-diaminopyrimidine, 4,6-dihydroxypyrimidine, 2-pyrazoline, 3-pyrazoline, N-aminomorpholine, and N-(2-aminoethyl)morpholine.

(5) Compound (PA) that has Proton-Accepting Functional Group and Generates Compound in which Proton-Acceptability is Reduced or Lost, or which is Changed from being Proton-Accepting to be Acidic, by being Decomposed Upon Irradiation with Actinic Ray or Radiation

The topcoat composition according to the present invention may further include, as a basic compound, a compound [hereinafter also referred to as a compound (PA)] that has a functional group with proton acceptor properties and generates a compound in which proton acceptor properties are reduced or lost, or which is changed from being proton-accepting to being acidic, by decomposing upon irradiation with actinic ray or radiation.

The functional group with proton acceptor properties refers to a functional group having a group or electron which is capable of electrostatically interacting with a proton, and for example, means a functional group with a macrocyclic structure, such as a cyclic polyether, or a functional group containing a nitrogen atom having an unshared electron pair not contributing to π-conjugation. The nitrogen atom having an unshared electron pair not contributing to π-conjugation is, for example, a nitrogen atom having a partial structure represented by the following general formula.

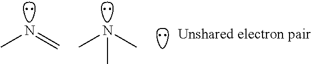

Preferred examples of the partial structure of the functional group with proton acceptor properties include crown ether, azacrown ether, primary to tertiary amines, pyridine, imidazole, and pyrazine structures.

The compound (PA) decomposes upon irradiation with actinic ray or radiation to generate a compound exhibiting deterioration in proton acceptor properties, no proton acceptor properties, or a change from the proton acceptor properties to acid properties. Here, exhibiting deterioration in proton acceptor properties, no proton acceptor properties, or a change from the proton acceptor properties to acid properties means a change of proton acceptor properties due to the proton being added to the functional group with proton acceptor properties, and specifically a decrease in the equilibrium constant at chemical equilibrium when a proton adduct is generated from the compound (PA) having the functional group with proton acceptor properties and the proton.

The proton acceptor properties can be confirmed by carrying out pH measurement. In the present invention, the acid dissociation constant pKa of the compound generated by the decomposition of the compound (PA) upon irradiation with actinic ray or radiation preferably satisfies pKa <−1, more preferably −13<pKa <−1, and still more preferably −13<pKa <−3.

In the present invention, the acid dissociation constant pKa indicates an acid dissociation constant pKa in an aqueous solution, and is described, for example, in Chemical Handbook (II) (Revised 4^{th} Edition, 1993, compiled by the Chemical Society of Japan, Maruzen Inc.), and a lower value thereof indicates higher acid strength. Specifically, the pKa in an aqueous solution may be measured by using an infinite-dilution aqueous solution and measuring the acid dissociation constant at 25° C., or a value with respect to the Hammett substituent constants and the database of publicly known literature data can also be obtained by computation using the following software package 1. All the values of pKa described in the present specification indicate values determined by computation using this software package.

Software package 1: Advanced Chemistry Development (ACD/Labs) Software V 8.14 for Solaris (1994-2007 ACD/Labs).

The compound (PA) generates a compound represented by General Formula (PA-1), for example, as the proton adduct generated by decomposition upon irradiation with actinic ray or radiation. The compound represented by General Formula (PA-1) is a compound exhibiting deterioration in proton acceptor properties, no proton acceptor properties, or a change from the proton acceptor properties to acid properties since the compound has a functional group with proton acceptor properties as well as an acidic group, as compared with the compound (PA).

Q-A-(X)ₙ—B—R (PA-1)

In General Formula (PA-1),

Q represents —SO₃H, —CO₂H, or —X₁NHX₂R_{f}, in which R_{f} represents an alkyl group, a cycloalkyl group, or an aryl group, and X₁ and X₂ each independently represent —SO₂— or —CO—.

A represents a single bond or a divalent linking group.

X represents —SO₂ or —CO—.

n is 0 or 1.

B represents a single bond, an oxygen atom, or —N(Rₓ)R_{y}—, in which Rₓ represents a hydrogen atom or a monovalent organic group, and R_{y} represents a single bond or a divalent organic group, provided that Rₓ may be bonded to R_{y} to form a ring or may be bonded to R to form a ring.

R represents a monovalent organic group having a functional group with proton acceptor properties.

General Formula (PA-L) will be described in more detail.

The divalent linking group in A is preferably a divalent linking group having 2 to 12 carbon atoms, such as and examples thereof include an alkylene group and a phenylene group. The divalent linking group is more preferably an alkylene group having at least one fluorine atom, preferably having 2 to 6 carbon atoms, and more preferably having 2 to 4 carbon atoms. The alkylene chain may contain a linking group such as an oxygen atom and a sulfur atom. In particular, the alkylene group is preferably an alkylene group in which 30% to 100% by number of the hydrogen atoms are substituted with fluorine atoms, and more preferably the carbon atom bonded to the Q site has a fluorine atom. The alkylene group is still more preferably a perfluoroalkylene group, and even still more preferably a perfluoroethylene group, a perfluoropropylene group, or a perfluorobutylene group.

The monovalent organic group in Rx is preferably an organic group having 1 to 30 carbon atoms, and examples thereof include an alkyl group, a cycloalkyl group, an aryl group, an aralkyl group, and an alkenyl group. These groups may further have a substituent.

The alkyl group in Rx may have a substituent, is preferably a linear and branched alkyl group having 1 to 20 carbon atoms, and may have an oxygen atom, a sulfur atom, or a nitrogen atom in the alkyl chain.

Preferred examples of the divalent organic group in Ry include an alkylene group.

Other examples include a ring structure which may be formed by the mutual bonding of Rx and Ry include 5- to 10-membered rings, and particularly preferably 6-membered rings, each of which contains a nitrogen atom.

Furthermore, examples of the alkyl group having a substituent include a group formed by substituting a cycloalkyl group on a linear or branched alkyl group (for example, an adamantylmethyl group, an adamantylethyl group, a cyclohexylethyl group, and a camphor residue).

The cycloalkyl group in Rx may have a substituent, is preferably a cycloalkyl group having 3 to 20 carbon atoms, and may have an oxygen atom in the ring.

The aryl group in Rx may have a substituent, is preferably an aryl group having 6 to 14 carbon atoms.

The aralkyl group in Rx may have a substituent, is preferably an aralkyl group having 7 to 20 carbon atoms.

The alkenyl group in Rx may have a substituent and examples of the alkenyl group include a group having a double bond at an arbitrary position of the alkyl group mentioned as Rx.

The functional group with proton acceptor properties in R is the same as described above, and examples thereof include groups having nitrogen-containing heterocyclic aromatic structures or the like, such as azacrown ether, primary to tertiary amines, pyridine, and imidazole.

As the organic group having such a structure, ones having 4 to 30 carbon atoms are preferable, and examples thereof include an alkyl group, a cycloalkyl group, an aryl group, an aralkyl group, and an alkenyl group.

The alkyl group, the cycloalkyl group, the aryl group, the aralkyl group, and the alkenyl group in the alkyl group, the cycloalkyl group, the aryl group, the aralkyl group, and the alkenyl group, each including a functional group with proton acceptor properties or an ammonium group in R are the same as the alkyl group, the cycloalkyl group, the aryl group, the aralkyl group, and the alkenyl group, respectively, mentioned as Rx.

Examples of the substituent which may be contained in each of the groups include a halogen atom, a hydroxyl group, a nitro group, a cyano group, a carboxyl group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 20 carbon atoms), an acyloxy group (preferably having 2 to 10 carbon atoms), an alkoxycarbonyl group (preferably having 2 to 20 carbon atoms), and an aminoacyl group (preferably having 2 to 20 carbon atoms). With regard to the cyclic structure and the aminoacyl group in the aryl group, the cycloalkyl group, or the like, examples of the substituent further include an alkyl group (preferably having 1 to 20 carbon atoms).

When B is —N(Rx)Ry-, it is preferable that R and Rx are bonded to each other to form a ring. The formation of a ring structure improves the stability and enhances the storage stability of a composition using the same. The number of carbon atoms which form a ring is preferably 4 to 20, the ring may be monocyclic or polycyclic, and an oxygen atom, and a sulfur atom, or a nitrogen atom may be contained in the ring.

Examples of the monocyclic structure include a 4-membered ring, a 5-membered ring, a 6-membered ring, a 7-membered ring, and an 8-membered ring, each containing a nitrogen atom, or the like. Examples of the polycyclic structure include structures formed by a combination of two or three, or more monocyclic structures. The monocyclic structure or the polycyclic structure may have a substituent, and as the substituent, for example, a halogen atom, a hydroxyl group, a cyano group, a carboxyl group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 15 carbon atoms), an acyloxy group (preferably having 2 to 15 carbon atoms), an alkoxycarbonyl group (preferably having 2 to 15 carbon atoms), an aminoacyl group (preferably having 2 to 20 carbon atoms), or the like is preferable. With regard to the cyclic structure in the aryl group, the cycloalkyl group, or the like, examples of the substituent include an alkyl group (preferably having 1 to 15 carbon atoms). With regard to the aminoacyl group, examples of the substituent further include an alkyl group (preferably having 1 to 15 carbon atoms).

R_{f} in —X₁NHX₂R_{f} represented by Q is preferably an alkyl group having 1 to 6 carbon atoms, which may have a fluorine atom, and more preferably a perfluoroalkyl group having 1 to 6 carbon atoms. Further, it is preferable that at least one of X₁ or X₂ is —SO₂—, with a case where both X₁ and X₂ are —SO2- being more preferable.

The compound represented by General Formula (PA-1) in which the Q site is sulfonic acid can be synthesized by a common sulfonamidation reaction. For example, the compound can be synthesized by a method in which one sulfonyl halide moiety of a bissulfonyl halide compound is selectively reacted with an amine compound to form a sulfonamide bond, and then the another sulfonyl halide moiety thereof is hydrolyzed, or a method in which a cyclic sulfonic acid anhydride is reacted with an amine compound to cause ring opening.

The compound (PA) is preferably an ionic compound. The functional group with proton acceptor properties may be contained in an anionic moiety or a cationic moiety, and it is preferable that the functional group is contained in an anionic moiety.

Preferred examples of the compound (PA) include compounds represented by General Formulae (4) to (6).

R—X₂—N⁻—X₁-A-(X)ₙ—B—R[C]⁺ (4)

R—SO₃⁻[C]⁺ (5)

R—CO₂⁻[C]⁺ (6)

In General Formulae (4) to (6), A, X, n, B, R, R_{f}, X₁, and X₂ each have the same definitions as in General Formula (PA-1).

C⁺ represents a counter cation.

As the counter cation, an onium cation is preferable. More specifically, preferred examples thereof include a sulfonium cation described as S⁺(R₂₀₁)(R₂₀₂)(R₂₀₃) in General Formula (ZI) and an iodonium cation described as I⁺(R₂₀₄)(R₂₀₅) in General Formula (ZII), each described with regard to the photoacid generator which will be described later.

Specific examples of the compound (PA) include, but not limited to, the compounds described in paragraphs [0743] to [0750] of JP2013-83966A.

Furthermore, in the present invention, compounds (PA) other than a compound which generates the compound represented by General Formula (PA-1) can also be appropriately selected. For example, a compound containing a proton acceptor moiety at its cationic moiety may be used as an ionic compound. More specific examples thereof include a compound represented by General Formula (7).

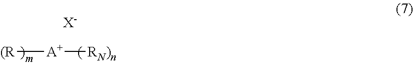

In the formulae, A represents a sulfur atom or an iodine atom.

m represents 1 or 2 and n represents 1 or 2, provided that m+n=3 when A is a sulfur atom and that m+n=2 when A is an iodine atom.

R represents an aryl group.

R_{N} represents an aryl group substituted with the functional group with proton acceptor properties.

X⁻ represents a counter anion.

Specific examples of X⁻ include the same ones as X⁻ in General Formula (ZI) which will be described later.

Specific preferred examples of the aryl group of R and R_{N} include a phenyl group.

Specific examples of the functional group with proton acceptor properties, contained in RN, are the same as the functional groups with proton acceptor properties described above in Formula (PA-1).

In the topcoat composition of the present invention, the blend ratio of the compound (PA) in the total composition is preferably 0.1% to 10% by mass, and more preferably 1% to 8% by mass in the total solid content.

(6) Guanidine Compound

The topcoat composition of the present invention may further contain a guanidine compound having a structure represented by the following formula.

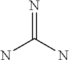

The guanidine compound exhibits strong basicity since the positive charge of the conjugate acid is dispersed and stabilized by the three nitrogen atoms.

For the basicity of the guanidine compound (A) of the present invention, the pKa of a conjugate acid is preferably 6.0 or more, more preferably 7.0 to 20.0 since neutralization reactivity with an acid is high and the roughness properties are excellent, and still more preferably 8.0 to 16.0.

Due to such strong basicity, the diffusibility of an acid is suppressed, and the strong basicity can contribute to formation of an excellent pattern shape.

In the present invention, the log P is a logarithmic value of an n-octanol/water distribution coefficient (P), and with respect to a wide range of compounds, it is an effective parameter that can characterize the hydrophilicity/hydrophobicity. In general, the distribution coefficient is determined not by experiment but by calculation, and in the present invention, the distribution coefficient is a value calculated by a CS Chem Draw Ultra Ver. 8.0 software package (Crippen's fragmentation method).

In addition, the log P of the guanidine compound (A) is preferably 10 or less. When the log P is the above value or less, the guanidine compound (A) can be uniformly contained in a resist film.

The log P of the guanidine compound (A) in the present invention is preferably in a range of 2 to 10, more preferably in a range of 3 to 8, and particularly preferably in a range of 4 to 8.

Furthermore, it is preferable that the guanidine compound (A) in the present invention has no nitrogen atom other than the guanidine structure.

Specific examples of the guanidine compound include the compounds described in paragraphs [0765] to [0768] of JP2013-83966A, but are not limited thereto.

(7) Low Molecular Compound Having Nitrogen Atom and Group that Leaves by Action of Acid

The topcoat composition of the present invention can include a low molecular compound (hereinafter referred to as a “low molecular compound (D)” or a “compound (D)”) which has a nitrogen atom and a group that leaves by the action of an acid. The low molecular compound (D) preferably has basicity after the group that leaves by the action of an acid.

The group that leaves by the action of an acid is not particularly limited, but an acetal group, a carbonate group, a carbamate group, a tertiary ester group, a tertiary hydroxyl group, or a hemiaminal ether group is preferable, and a carbamate group or a hemiaminal ether group is particularly preferable.

The molecular weight of the low molecular compound (D) having a group that leaves by the action of an acid is preferably 100 to 1,000, more preferably 100 to 700, and particularly preferably 100 to 500.

As the compound (D), an amine derivative having a group that leaves by the action of an acid on a nitrogen atom is preferable.

The compound (D) may also have a carbamate group having a protecting group on a nitrogen atom. The protecting group constituting the carbamate group can be represented by General Formula (d-1).

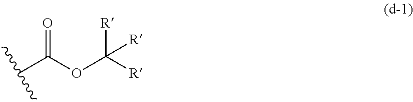

In General Formula (d-1),

R″s each independently represent a hydrogen atom, linear or branched alkyl group, a cycloalkyl group, an aryl group, an aralkyl group, or an alkoxyalkyl group. R″s may be bonded to each other to form a ring.

R′ is preferably a linear or branched alkyl group, a cycloalkyl group, or an aryl group, and more preferably a linear or branched alkyl group or a cycloalkyl group.

Specific structures of such a group are shown below.

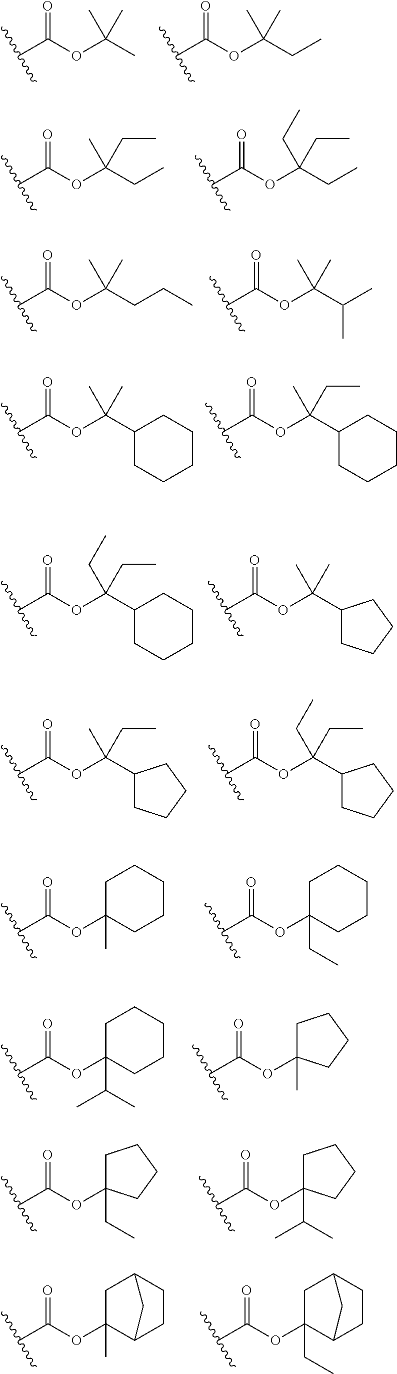

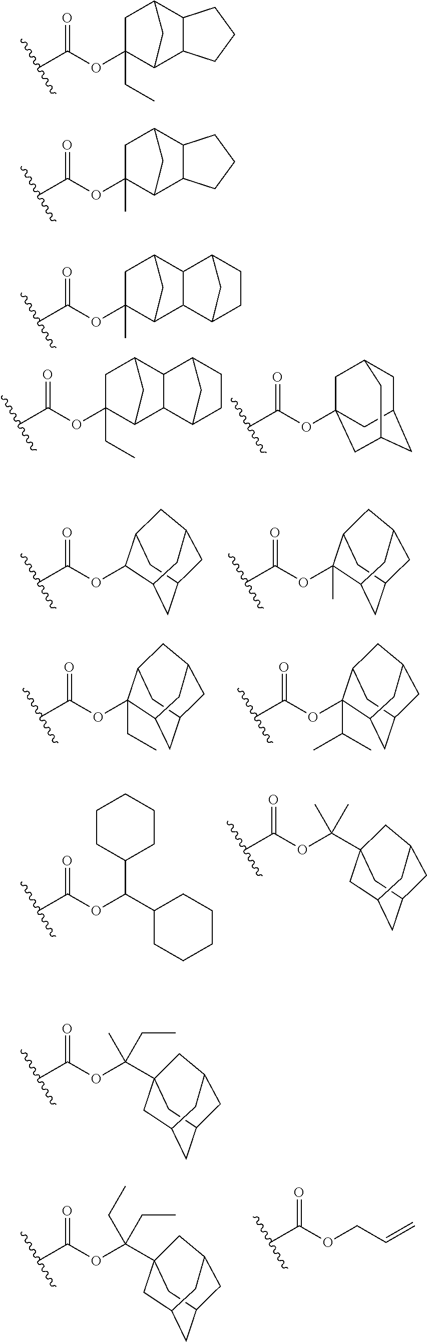

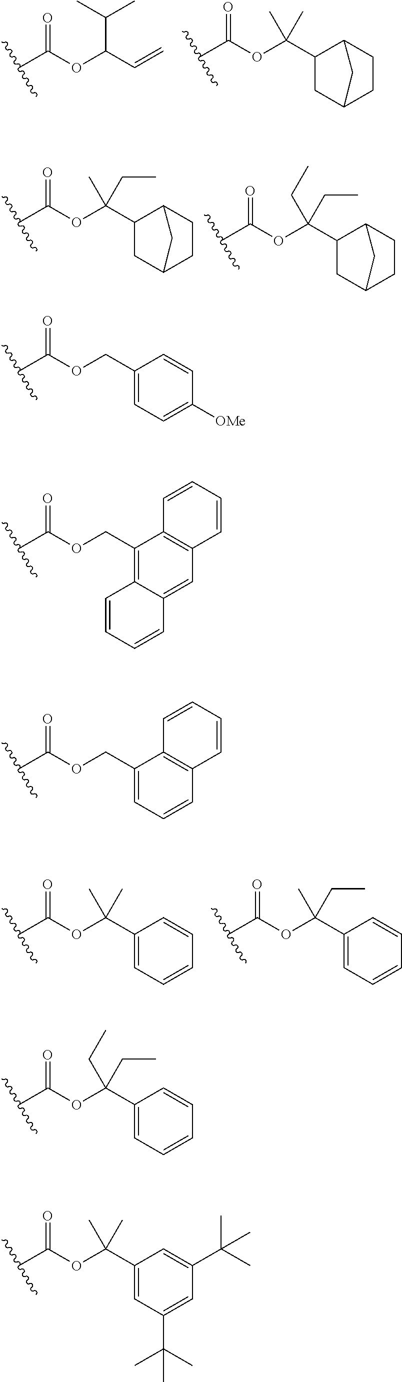

The compound (D) may also be constituted by arbitrarily combining various basic compounds as described above with the structure represented by General Formula (d-1).

The compound (D) is particularly preferably a compound having a structure represented by General Formula (A).

Incidentally, the compound (D) may be a compound corresponding to various basic compounds described above as long as it is a low molecular compound having a group that leaves by the action of an acid.

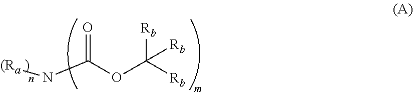

In General Formula (A), Rₐ represents a hydrogen atom, an alkyl group, a cycloalkyl group, an aryl group, or an aralkyl group. Further, with n=2, two Ra's may be the same as or different from each other, and two Ra's may be bonded to each other to form a divalent heterocyclic hydrocarbon group (preferably having 20 or less carbon atoms) or a derivative thereof.

Rb's each independently represent a hydrogen atom, an alkyl group, a cycloalkyl group, an aryl group, an aralkyl group, or an alkoxyalkyl group, provided that when one or more Rb in —C(Rb)(Rb)(Rb) are hydrogen atoms, at least one of the remaining Rb's is a cyclopropyl group, a 1-alkoxyalkyl group, or an aryl group.

At least two Rb's may be bonded to each other to form an alicyclic hydrocarbon group, an aromatic hydrocarbon group, a heterocyclic hydrocarbon group, or a derivative thereof.

n represents an integer of 0 to 2, m represents an integer of 1 to 3, and n+m=3.

In General Formula (A), the alkyl group, the cycloalkyl group, the aryl group, and the aralkyl group represented by Ra and Rb may be substituted with a functional group such as a hydroxyl group, a cyano group, an amino group, a pyrrolidino group, a piperidino group, a morpholino group, and an oxo group, an alkoxy group, or a halogen atom. The same applies to the alkoxyalkyl group represented by Rb.

Examples of the alkyl group, the cycloalkyl group, the aryl group, and the aralkyl group (each of the alkyl group, the cycloalkyl group, the aryl group, and the aralkyl group may be substituted with the functional group, an alkoxy group, or a halogen atom) of Ra and/or Rb include:

a group derived from a linear or branched alkane, such as methane, ethane, propane, butane, pentane, hexane, heptane, octane, nonane, decane, undecane, and dodecane, or a group in which the group derived from an alkane is substituted with one or more kinds of or one or more groups of cycloalkyl groups such as a cyclobutyl group, a cyclopentyl group, and a cyclohexyl group;

a group derived from a cycloalkane, such as cyclobutane, cyclopentane, cyclohexane, cycloheptane, cyclooctane, norbornane, adamantane, and noradamantane, or a group in which the group derived from a cycloalkane is substituted with one or more kinds of or one or more groups of linear or branched alkyl groups such as a methyl group, an ethyl group, an n-propyl group, an i-propyl group, an n-butyl group, a 2-methylpropyl group, a 1-methylpropyl group, and a t-butyl group;

a group derived from an aromatic compound, such as benzene, naphthalene, and anthracene, or a group in which the group derived from an aromatic compound is substituted with one or more kinds of or one or more groups of linear or branched alkyl groups such as a methyl group, an ethyl group, an n-propyl group, an i-propyl group, an n-butyl group, a 2-methylpropyl group, a 1-methylpropyl group, and a t-butyl group;

a group derived from a heterocyclic compound, such as pyrrolidine, piperidine, morpholine, tetrahydrofuran, terahydropyran, indole, indoline, quinoline, perhydroquinoline, indazole, and benzimidazole, or a group in which the group derived from a heterocyclic compound is substituted with one or more kinds of or one or more groups of linear or branched alkyl groups or aromatic compound-derived groups; a group in which the group derived from a linear or branched alkane or the group derived from a cycloalkane is substituted with one or more kinds of or one or more groups of aromatic compound-derived groups such as a phenyl group, a naphthyl group, and an anthracenyl group; and a group in which the substituent above is substituted with a functional group such as a hydroxyl group, a cyano group, an amino group, a pyrrolidino group, a piperidino group, a morpholino group, and an oxo group.

Examples of the divalent heterocyclic hydrocarbon group (preferably having 1 to 20 carbon atoms) formed by the mutual bonding of Ra's, or a derivative thereof include a group derived from a heterocyclic compound, such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclonononane, tetrazole, 7-azaindole, indazole, benzimidazole, imidazo[1,2-a]pyridine, (1S,4S)-(+)-2,5-diazabicyclo[2.2. I]heptane, 1,5,7-triazabicyclo[4.4.0]dec-5-ene, indole, indoline, 1,2,3,4-tetrahydroquinoxaline, perhydroquinoline and 1,5,9-triazacyclododecane, and a group in which the group derived from a heterocyclic compound is substituted with one or more kinds of or one or more groups of a linear or branched alkane-derived group, a cycloalkane-derived group, an aromatic compound-derived group, a heterocyclic compound-derived group, and a functional group such as a hydroxyl group, a cyano group, an amino group, a pyrrolidino group, a piperidino group, a morpholino group, and an oxo group.

Specific examples of the particularly preferred compound (D) in the present invention include the compounds described in paragraphs [0786] to [0788] of JP2013-83966A, but the present invention is not limited thereto.

The compound represented by General Formula (A) can be synthesized in accordance with JP2007-298569A, JP2009-199021 A, or the like.

In the present invention, the low molecular compound (D) may be used singly or as a mixture of two or more kinds thereof.

Other examples of the basic compound which can be used include the compounds synthesized in Examples of JP2002-363146A and the compounds described in paragraph 0108 of JP2007-298569A.

A photosensitive basic compound may also be used as the basic compound. As the photosensitive basic compound, for example, the compounds described in JP2003-524799A. J. Photopolym. Sci. & Tech. Vol. 8, pp. 543-553 (1995), or the like can be used.

As the basic compound, a compound called a so-called photodisintegrating base may also be used. Examples of the photodisintegrating base include an onium salt of carboxylic acid, and an onium salt of sulfonium acid having the α-position which is not fluorinated. Specific examples of the photodisintegrating base include those in paragraph 0145 of WO2014/133048A1, JP2008-158339A, and JP399146B.

(Content of Basic Compound)

The content of the basic compound in the topcoat composition is preferably 0.01% to 20% by mass, more preferably 0.1% to 10% by mass, and still more preferably 1% to 5% by mass, with respect to the solid contents of the topcoat composition.

(Base Generator)

Examples of the base generator (photobase generator) which can be contained in the topcoat composition include compounds described in JP1992-151156A (JP-H04-151156A), JP1992-162040A (JP-H04-162040A), JP1993-197148A (JP-H05-197148A), JP1993-5995A (JP-H05-5995A), JP1994-194834A (JP-H06-194834A), JP1996-146608A (JP-H08-146608A), JP1998-83079A (JP-H10-83079A), and EP622682B.

Furthermore, the compounds described in JP2010-243773A can also be appropriately used.

Specific suitable examples of the photobase generator include 2-nitrobenzyl carbamate, 2,5-dinitrobenzylcyclohexyl carbamate, N-cyclohexyl-4-methylphenylsulfonamide, and 1,1-dimethyl-2-phenylethyl-N-isopropyl carbamate, but are not limited thereto.

(Content of Base Generator)

The content of the base generator in the topcoat composition is preferably 0.01% to 20% by mass, more preferably 0.1% to 10% by mass, and still more preferably 1% to 5% by mass, with respect to the total solid contents of the topcoat composition.

<(A2) Compound Containing Bond or Group Selected from Group Consisting of Ether Bond, Thioether Bond, Hydroxyl Group, Thiol Group, Carbonyl Bond, and Ester Bond>

A compound (hereinafter also referred to as a “compound (A2)”) including at least one group or bond selected from the group consisting of an ether bond, a thioether bond, a hydroxyl group, a thiol group, a carbonyl bond, and an ester bond will be described below.

As described above, the compound (A2) is a compound including at least one group or bond selected from the group consisting of an ether bond, a thioether bond, a hydroxyl group, a thiol group, a carbonyl bond, and an ester bond. Since the oxygen atoms or sulfur atoms included in these groups or bonds have unshared electron pairs, acids can be captured by the interaction with the acids diffused from the actinic ray-sensitive or radiation-sensitive film.

In one aspect of the present invention, the compound (A2) preferably has two or more groups or bonds selected from the group, more preferably has three or more groups or bonds selected from the group, and still more preferably four or more groups or bonds selected from the group. In this case, groups or bonds selected from the group consisting of ether bonds, thioether bonds, hydroxyl groups, thiol groups, carbonyl bonds, and ester bonds included in plural numbers in the compound (A2) may be the same as or different from each other.

In one aspect of the present invention, the compound (A2) preferably has a molecular weight of 3,000 or less, more preferably has a molecular weight of 2,500 or less, still more preferably has a molecular weight of 2,000 or less, and particularly preferably has a molecular weight of 1,500 or less.

Furthermore, in one aspect of the present invention, the number of carbon atoms included in the compound (A2) is preferably 8 or more, more preferably 9 or more, and still more preferably 10 or more.

Moreover, in one aspect of the present invention, the number of carbon atoms included in the compound (A2) is preferably 30 or less, more preferably 20 or less, and still more preferably 15 or less.

Furthermore, in one aspect of the present invention, the compound (A2) is preferably a compound having a boiling point of 200° C. or higher, more preferably a compound having a boiling point of 220° C. or higher, and still more preferably a compound having a boiling point of 240° C. or higher.

Moreover, in one aspect of the present invention, the compound (A2) is preferably a compound having an ether bond, more preferably a compound having 2 or more ether bonds, still more preferably a compound having 3 or more ether bonds, and particularly preferably a compound having 4 or more ether bonds.

In one aspect of the present invention, the compound (A2) is more preferably a compound including a repeating unit containing an oxyalkylene structure represented by General Formula (1).

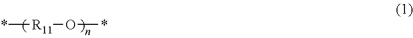

In the formula,

R₁₁ represents an alkylene group which may have a substituent,

n represents an integer of 2 or more, and

* represents a bonding arm.

The number of carbon atoms of the alkylene group represented by R₁₁ in General Formula (1) is not particularly limited, but is preferably 1 to 15, more preferably 1 to 5, still more preferably 2 or 3, and particularly preferably 2. In a case where this alkylene group has a substituent, the substituent is not particularly limited, but is preferably, for example, an alkyl group (preferably having 1 to 10 carbon atoms).

n is preferably an integer of 2 to 20, among which an integer of 10 or less is more preferable due to an increase in DOF.

The average value of n's is preferably 20 or less, more preferably 2 to 10, still more preferably 2 to 8, and particularly preferably 4 to 6 due to an increase in DOF. Here, “the average value of n's” means the value of n determined when the weight-average molecular weight of the compound (A2) is measured by GPC, and the obtained weight-average molecular weight is allowed to match the general formula. In a case where n is not an integer, it is a value rounded off to the nearest integer of the specified numerical value.

In a case where n is 2 or more, R₁₁'s which are present in plural numbers may be the same as or different from each other.

Furthermore, a compound having a partial structure represented by General Formula (1) is preferably a compound represented by General Formula (1-1) due to an increase in DOF.

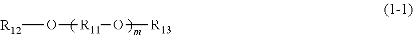

In the formula,

the definition, specific examples, and suitable aspects of R₁₁ are the same as those of R₁₁ in General Formula (1) as described above, respectively.

R₁₂ and R₁₃ each independently represent a hydrogen atom or an alkyl group. The number of carbon atoms of the alkyl group is not particularly limited, but is preferably 1 to 15. R₁₂ and R₁₃ may be bonded to each other to form a ring.

m represents an integer of 1 or more. m is preferably an integer of 1 to 20, and above all, is more preferably an integer of 10 or less due to an increase in DOF.

The average value of m's is preferably 20 or less, more preferably 1 to 10, still more preferably 1 to 8, and particularly preferably 4 to 6 due to an increase in DOF. Here, “the average value of m's” has the same definition as the “average value of n's” as described above.

In a case where m is 2 or more, R₁₁'s present in plural numbers may be the same as or different from each other.

In one aspect of the present invention, the compound having a partial structure represented by General Formula (1) is preferably alkylene glycol including at least two ether bonds.

The compound (A2) may be used as a commercially available product or may be synthesized according to a known method.

Specific examples of the compound (A2) are shown below but the present invention is not limited thereto.

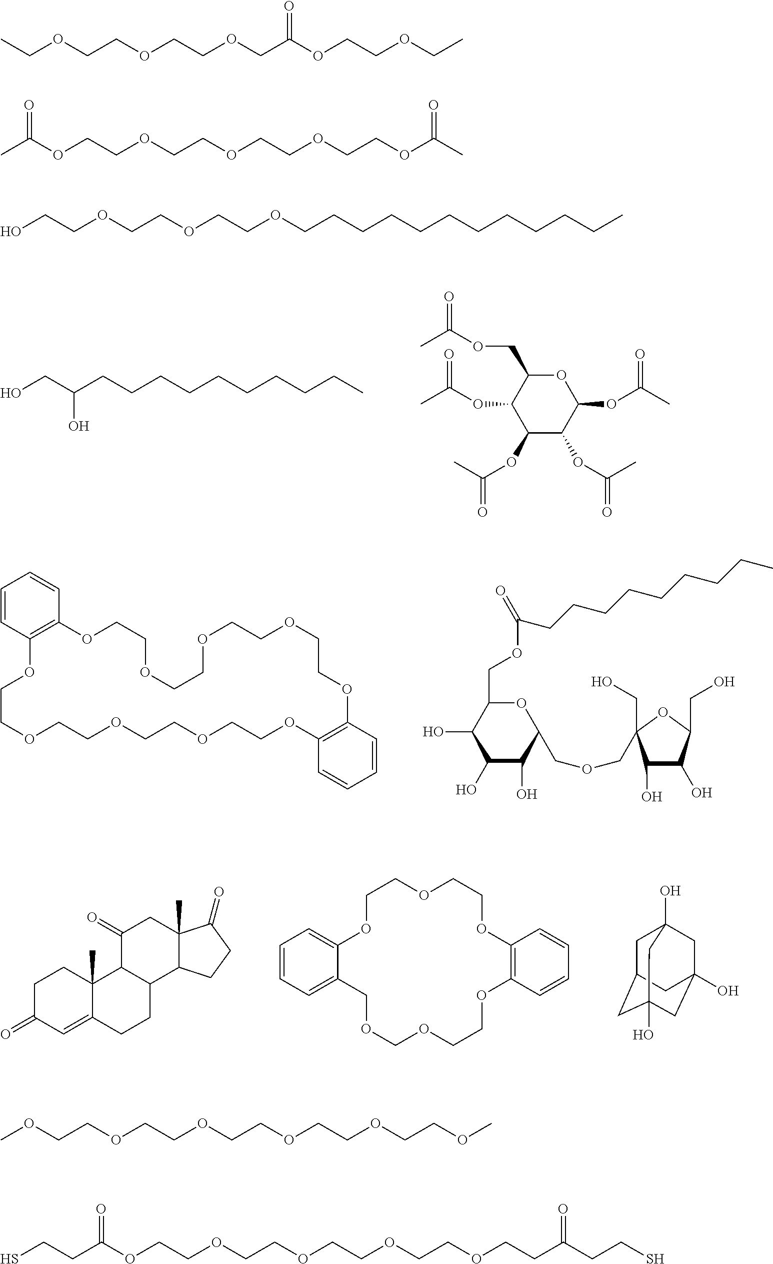

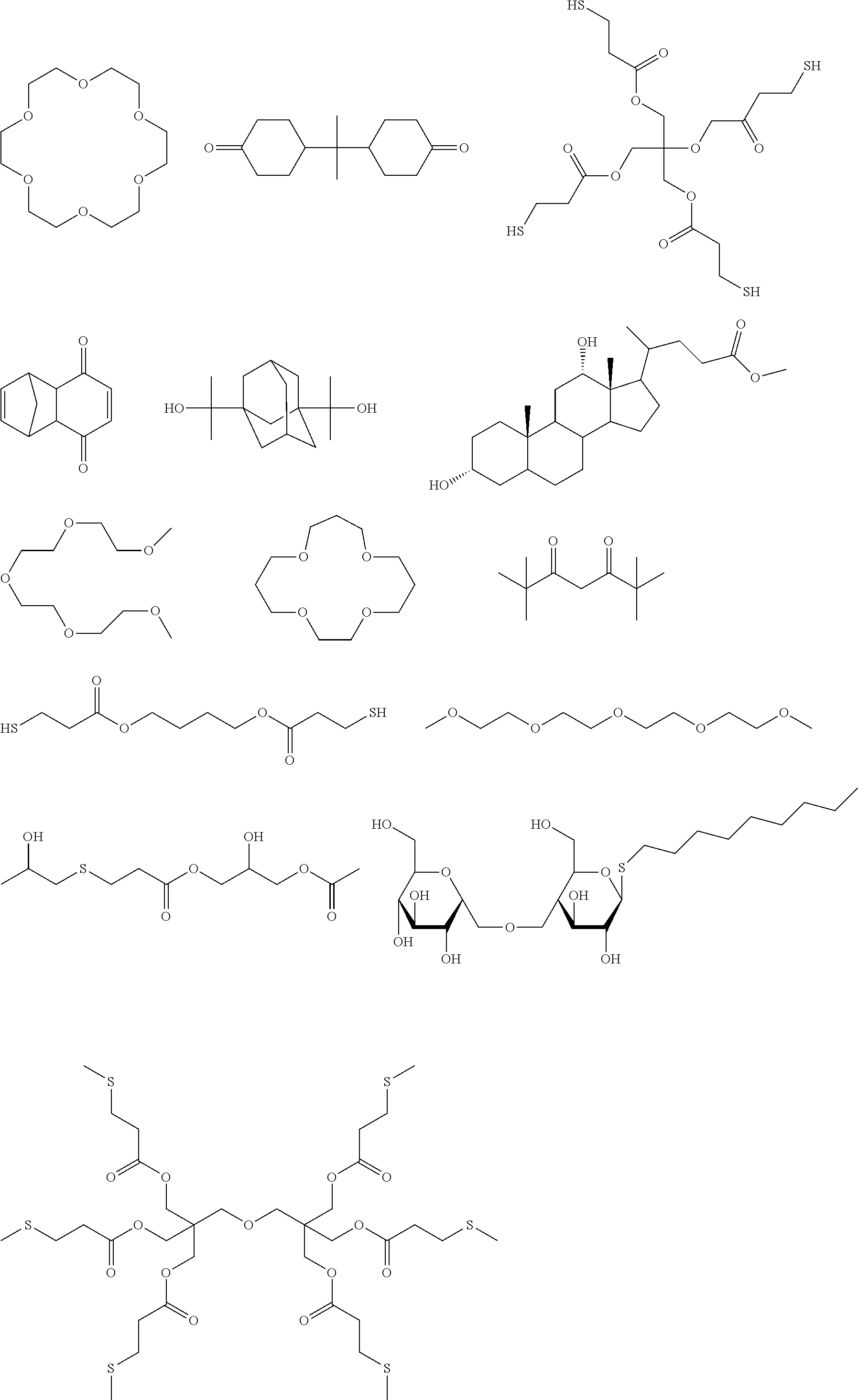

The content of the compound (A2) in the topcoat composition is preferably 0.1% to 30% by mass, more preferably 1% to 25% by mass, still more preferably 2% to 20% by mass, and particularly preferably 3% to 18% by mass, with respect to the total solid contents of the topcoat composition.

<Surfactant>

The topcoat composition of the present invention may further include a surfactant.

The surfactant is not particularly limited, and any of an anionic surfactant, a cationic surfactant, and a nonionic surfactant can be used as long as it can uniformly form a film of the topcoat composition, and also be dissolved in the solvent of the topcoat composition.

The amount of surfactant to be added is preferably 0.001% to 20% by mass, and more preferably 0.01% to 10% by mass.

The surfactant may be used singly or in combination of two or more kinds thereof.

As the surfactant, for example, one selected from an alkyl cation-based surfactant, an amide-type quaternary cation-based surfactant, an ester type quaternary cation-based surfactant, an amine oxide-based surfactant, a betaine-based surfactant, an alkoxylate-based surfactant, a fatty acid ester-based surfactant, an amide-based surfactant, an alcohol-based surfactant, an ethylenediamine-based surfactant, and a fluorine- and/or silicon-based surfactant (a fluorine-based surfactant, a silicon-based surfactant, or a surfactant having both of a fluorine atom and a silicon atom) can be appropriately used.

Specific examples of the surfactant include polyoxyethylene alkyl ethers such as polyoxyethylene lauryl ether, polyoxyethylene stearyl ether, polyoxyethylene cetyl ether, and polyoxyethylene oleyl ether; polyoxyethylene alkylallyl ethers such as polyoxyethylene octylphenol ether and polyoxyethylene nonylphenol ether, polyoxyethylene/polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; and surfactants such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; and commercially available surfactants mentioned later.

Examples of the commercially available surfactants that can be used include fluorine-based surfactants or silicon-based surfactants such as EFTOP EF301 and EF303 (manufactured by Shin-Akita Kasei K. K.); FLUORAD FC430, 431, and 4430 (manufactured by Sumitomo 3M Limited); MEGAFACE FL71, F173, F176, F189, F113, F110, F177, F120, and R08 (manufactured by DIC Corp.); SURFLON S-382, SC101, 102, 103, 104, 105, and 106 (manufactured by Asahi Glass Co., Ltd.); TROYSOL S-366 (manufactured by Troy Chemical Corp.); GF-300 and GF-150 (manufactured by Toagosei Chemical Industry Co., Ltd.); SURFLON S-393 (manufactured by AGC Seimi Chemical Co., Ltd.); EFTOP EF121, EF122A, EF122B, RF122C, EF125M, EF135M, EP351, 352, EF801, EF802, and EF601 (manufactured by JEMCO Inc.); PF636, PF656, PF6320, and PF6520 (manufactured by OMNOVA Solutions Inc.); and FTX-204D, 208G, 218G, 230G, 204D, 208D, 212D, 218, and 222D (manufactured by NEOS Co., Ltd.). In addition, Polysiloxane Polymer KP-341 (manufactured by Shin-Etsu Chemical COMPANY LIMITED) can also be used as the silicon-based surfactant.

<Method for Preparing Topcoat Composition>

The topcoat composition of the present invention is preferably used by dissolving the above-mentioned respective components in a solvent, and filtering the solution through a filter. The filter is preferably a polytetrafluoroethylene-, polyethylene-, or nylon-made filter having a pore size of 0.1 μm or less, more preferably 0.05 μm or less, and still more preferably 0.03 μm or less. Further, two or more kinds of filters are connected in series or in parallel, and used. Incidentally, the composition may be filtered a plurality of times, and a step of filtering plural times may be a circulatory filtration step. Incidentally, the composition may also be subjected to a deaeration treatment or the like before and after the filtration through the filter. It is preferable that the topcoat composition of the present invention does not include impurities such as metal. The content of the metal components included in these materials is preferably 1 ppm or less, more preferably 100 ppt or less, and still more preferably 10 ppt or less, but the material substantially not having metal components (at a detection limit of a measurement device or less) is particularly preferable.

[3] Pattern Forming Method

The pattern forming method of the present invention includes a pattern forming method including a step of forming an upper layer film on a resist film, using the above-mentioned composition for forming an upper layer film according to the present invention, step of exposing the resist film, and a step of developing the exposed resist film.

The pattern forming method of the present invention may be a negative tone pattern forming method or a positive tone pattern forming method, but a negative tone pattern forming method using an organic developer as the developer as described later is preferable.

The resist film is suitably formed by a step a of applying the resist composition onto a substrate to form a resist film.

The step of forming an upper layer film on the resist film using the composition for forming an upper layer film according to the present invention is preferably a step b of applying the composition for forming an upper layer film according to the present invention onto the resist film to form an upper layer film on the resist film.

The step of exposing the resist film will be described later as a step c of exposing the resist film having the upper layer film formed thereon.

The step of developing the exposed resist film is preferably a step d of developing the exposed resist film using a developer to form a pattern.

<Step a>

In the step a, the resist composition of the present invention is applied onto a substrate to form a resist film. The coating method is not particularly limited, and a spin coating method, a spray method, a roll coating method, a dip method, or the like, which have been known in the related art, can be used, with the spin coating method being preferable.

After applying the resist composition of the present invention, the substrate may be heated (prebaked), if desired. Thus, a film in which insoluble residual solvents have been removed can be uniformly formed. The temperature for prebake is not particularly limited, but is preferably 50° C. to 160° C., and more preferably 60° C. to 140° C.

The film thickness of the resist film is preferably 20 to 200 nm, and more preferably 30 to 100 nm.

The substrate on which the resist film is formed is not particularly limited, and it is possible to use a substrate generally used in a process for manufacturing a semiconductor such as an IC, a process for manufacturing a circuit board for a liquid crystal, a thermal head, or the like, and other lithographic processes of photofabrication, and examples thereof include inorganic substrates such as silicon, SiO₂, and SiN, and coating type inorganic substrates such as SOG.

Prior to forming the resist film, an antireflection film may be applied onto the substrate in advance.

As the antireflection film, any type of an inorganic film type such as titanium, titanium dioxide, titanium nitride, chromium oxide, carbon, and amorphous silicon, and an organic film type formed of a light absorber and a polymer material can be used. In addition, as the organic antireflection film, a commercially available organic antireflection film such as DUV-30 series or DUV-40 series manufactured by Brewer Science, Inc., AR-2, AR-3, or AR-5 manufactured by Shipley Company, L.L.C., or ARC series such as ARC29A manufactured by Nissan Chemical Industries, Ltd. can also be used.

<Step b>

In the step b, a composition (topcoat composition) for forming an upper layer film is applied onto the resist film formed in the step a, and then heated (prebaked (PB)), if desired, to form an upper layer film (hereinafter also referred to as a “topcoat”) on the resist film. Thus, it is possible to form a trench pattern or hole pattern having an ultrafine width or pore diameter (for example, 60 nm or less) with high DOF performance in the resist pattern after the development, as described above.

For the reason that the effects of the present invention are more excellent, the temperature for prebaking in the step b (hereinafter also referred to as a “PB temperature”) is preferably 100° C. or higher, more preferably 105° C. or higher, still more preferably 110° C. or higher, particularly preferably 120° C. or higher, and most preferably higher than 120° C.

The upper limit value of the PB temperature is not particularly limited, but may be, for example, 200° C. or lower. It is preferably 170° C. or lower, more preferably 160° C. or lower, and still more preferably 150° C. or lower.

In a case where the exposure of the step c which will be described later is a liquid immersion exposure, the topcoat is arranged between the resist film and the immersion liquid, and the resist film functions as a layer which is not brought into direct contact with the immersion liquid. In this case, preferred characteristics required for the topcoat (topcoat composition) are coating suitability onto the resist film, radiation, transparency, particularly to light at 193 nm, and poor solubility in an immersion liquid (preferably water). Further, it is preferable that the topcoat is not mixed with the resist film, and can be uniformly applied onto the surface of the resist film.

Moreover, in order to uniformly apply the topcoat composition onto the surface of the resist film while not dissolving the resist film, it is preferable that the topcoat composition contains a solvent in which the resist film is not dissolved. It is more preferable that as the solvent in which the resist film is not dissolved, a solvent of components other than an organic developer is used, which will be described later. A method for coating the topcoat composition is not particularly limited, a spin coating method, a spray method, a roll coating method, a dip method, or the like, which has been known in the related art, can be used.

The details of the topcoat composition are the same as described above.

The film thickness of the topcoat is not particularly limited, but from the viewpoint of transparency to an exposure light source, the film is formed, which has a thickness of usually 5 nm to 300 nm, preferably 10 nm to 300 nm, more preferably 20 nm to 200 nm, and still more preferably 30 nm to 100 nm.

After forming the topcoat, the substrate is heated, if desired.

From the viewpoint of resolution, it is preferable that the refractive index of the topcoat is close to that of the resist film.

The topcoat is preferably insoluble in an immersion liquid, and more preferably insoluble in water.

With regard to a receding contact angle of the topcoat, the receding contact angle (23° C.) of an immersion liquid onto the topcoat is preferably 50 to 100 degrees, and more preferably 80 to 100 degrees, from the viewpoint of the followability of the immersion liquid.

In the liquid immersion exposure, from the viewpoint that the immersion liquid needs to move on a wafer following the movement of an exposure head that is scanning the wafer at a high speed and forming an exposure pattern, the contact angle of the immersion liquid with respect to the resist film in a dynamic state is important, and in order to obtain better resist performance, the immersion liquid preferably has a receding contact angle in the above range.

In a case where the topcoat is released, an organic developer which will be described later may be used, and another release agent may also be used. As the release agent, a solvent hardly permeating the resist film is preferable. In a view that the release of the topcoat can be carried out simultaneously with the development of the resist film, the topcoat is preferably releasable with an organic developer. The organic developer used for release is not particularly limited as long as it makes it possible to dissolve and remove a less exposed area of the resist film. The organic developer can be selected from developers including a polar solvent such as a ketone-based solvent, an ester-based solvent, an alcohol-based solvent, an amide-based solvent, and an ether-based solvent, and a hydrocarbon-based solvent, which will be described later. A developer containing a ketone-based solvent, an ester-based solvent, an alcohol-based solvent, or an ether-based solvent is preferable, a developer containing an ester-based solvent is more preferable, and a developer containing butyl acetate is still more preferable.

From the viewpoint of release using an organic developer, the dissolution rate of the topcoat in the organic developer is preferably 1 to 300 nm/sec, and more preferably 10 to 100 nm/sec.

Here, the dissolution rate of a topcoat in the organic developer refers to a film thickness decreasing rate in a case where the topcoat is exposed to a developer after film formation, and is a rate in a case of dipping a butyl acetate solution at 23° C. in the present invention.

An effect of reducing development defects after developing a resist film is accomplished by setting the dissolution rate of a topcoat in the organic developer to 1 nm/sec or more, and preferably 10 nm/sec or more. Further, an effect that the line edge roughness of a pattern after the development of the resist film becomes better is accomplished as an effect of reducing the exposure unevenness during liquid immersion exposure by setting the dissolution rate to 300 nm/sec or less, and preferably 100 nm/sec or less.

The topcoat may also be removed using other known developers, for example, an aqueous alkali solution. Specific examples of the aqueous alkali solution which can be used include an aqueous tetramethylammonium hydroxide solution.

<Step c>

The exposure in the step c can be carried out by a generally known method, and for example, a resist film having a topcoat formed thereon is irradiated with actinic ray or radiation through a predetermined mask. Here, the resist film is preferably irradiated with actinic ray or radiation through an immersion liquid, but are not limited thereto. The exposure dose can be appropriately set, but is usually 1 to 100 mJ/cm².

The wavelength of the light source used in the exposure device in the present invention is not particularly limited, but light at a wavelength of 250 nm or less is preferably used. Examples thereof include KrF excimer laser light (248 nm), ArF excimer laser light (193 nm), F₂ excimer laser light (157 nm), EUV light (13.5 nm), and electron beams. Among these, ArF excimer laser light (193 nm) is preferably used.

In a case of carrying out liquid immersion exposure, before the exposure and/or after the exposure, the surface of the film may be washed with a water-based chemical before carrying out the heating which will be described later.

The immersion liquid is preferably a liquid which is transparent at an exposure wavelength and has a minimum temperature coefficient of a refractive index so as to minimize the distortion of an optical image projected on the film. In particular, in a case where the exposure light source is an ArF excimer laser light (wavelength: 193 nm), water is preferably used in terms of easy availability and easy handling, in addition to the above-mentioned viewpoints.

In a case of using water, an additive (liquid) that decreases the surface tension of water while increasing the interfacial activity may be added in a slight proportion. It is preferable that this additive does not dissolve the resist film on a substrate, and has a negligible effect on the optical coat at the undersurface of a lens element Water to be used is preferably distilled water. Further, pure water which has been subjected to filtration through an ion exchange filter or the like may also be used. Thus, it is possible to suppress the distortion of an optical image projected on the resist film by the incorporation of impurities.

In addition, from the viewpoint of further improving the refractive index, a medium having a refractive index of 1.5 or more can also be used. This medium may be an aqueous solution or an organic solvent.

The pattern forming method of the present invention may also have the step c (exposing step) carried out plural times. In the case, exposure to be carried out plural times may use the same light source or different light sources, but for the first exposure, ArF excimer laser light (wavelength; 193 nm) is preferably used.

After the exposure, heating (baking, also referred to as PEB) is preferably carried out to carry out development (preferably including rinsing). Thus, a good pattern can be obtained. The temperature for PEB is not particularly limited as long as a good resist pattern is obtained, and is usually 40° C. to 160° C. PEB may be carried out once or plural times.

<Step d>

The developer used in the step d may be an alkali developer or a developer containing an organic solvent, but is preferably the developer containing an organic solvent. A developing step using an alkali developer and a developing step using a developer containing an organic solvent may be combined.

As the alkali developer, quaternary ammonium salts typically exemplified by tetramethylammonium hydroxide are usually used, but in addition, aqueous alkaline solutions of inorganic alkalis, primary to tertiary amines, alcohol amines, cyclic amines, or the like can also be used.

Specifically, as the alkali developer, for example, alkali aqueous solutions of inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcoholamines such as dimethyl ethanolamine and triethanolamine; quaternary ammonium salts such as tetramethylammonium hydroxide and tetraethylammonium hydroxide; and cyclic amines such as pyrrole and piperidine can be used. Among these, an aqueous tetraethylammonium hydroxide solution is preferably used.

Moreover, an appropriate amount of alcohols or a surfactant may also be added to the alkali developer. The alkali concentration of the alkali developer is usually 0.1% to 20% by mass. The pH of the alkali developer is usually 10.0 to 15.0.

The time for carrying out development using an alkali developer is usually 10 to 300 seconds.

The alkali concentration (and the pH) of the alkali developer and the developing time can be appropriately adjusted depending on the patterns formed.

Washing may be carried out using a rinsing liquid after the development using an alkali developer, and as the rinsing liquid, pure water is used, or an appropriate amount of a surfactant may be added thereto before the use.

Furthermore, after the developing treatment or the rinsing treatment, a treatment for removing the developer or rinsing liquid adhering on the pattern by a supercritical fluid may be carried out.

In addition, after the rinsing treatment or the treatment using the supercritical fluid, a heating treatment can also be carried out so as to remove the moisture remaining in the pattern.

Examples of the developer containing an organic solvent (hereinafter also referred to as an organic developer) include developers containing a polar solvent such as a ketone-based solvent, an ester-based solvent, an alcohol-based solvent, an amide-based solvent, and an ether-based solvent, and a hydrocarbon-based solvent.

Examples of the ketone-based solvent include 1-octanone, 2-octanone, 1-nonanone, 2-nonanone, acetone, 2-heptanone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, and propylene carbonate.

Examples of the ester-based solvent include methyl acetate, ethyl acetate, isopropyl acetate, butyl acetate (n-butyl acetate), pentyl acetate, hexyl acetate, isoamyl acetate, butyl propionate (n-butyl propionate), butyl butyrate, isobutyl butyrate, butyl butanoate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, methyl 2-hydroxyisobutyrate, isobutyl isobutyrate, and butyl propionate.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol; glycol-based solvents such as ethylene glycol, propylene glycol, diethylene glycol, and triethylene glycol; and glycol ether-based solvents such as ethylene glycol monomethyl ether, propylene glycol monomethyl ether, diethylene glycol monomethyl ether, triethylene glycol monoethyl ether, and methoxymethylbutanol.

Examples of the ether-based solvent include, in addition to the glycol ether-based solvents above, dioxane, and tetrahydrofuran.

Examples of the amide-based solvent which can be used include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include aromatic hydrocarbon-based solvents such as toluene and xylene, and aliphatic hydrocarbon-based solvents such as pentane, hexane, octane, and decane.

A plurality of these solvents may be mixed, or the solvent may be used after being mixed with a solvent other than those described above or with water. However, in order to exhibit the effects of the present invention sufficiently, the moisture content in the entire developer is preferably less than 10% by mass, and it is more preferable that the developer contains substantially no water.

That is, the amount of the organic solvent to be used in the organic developer is preferably from 90% by mass to 100% by mass, and more preferably from 95% by mass to 100% by mass, with respect to the total amount of the developer.

Among these, as the organic developer, a developer containing at least one organic solvent selected from the group consisting of a ketone-based solvent, an ester-based solvent, an alcohol-based solvent, an amide-based solvent, and an ether-based solvent is preferable, a developer containing a ketone-based solvent or an ester-based solvent is more preferable, and a developer containing butyl acetate, butyl propionate, or 2-heptanone is still more preferable.

The vapor pressure of the organic developer is preferably 5 kPa or less, more preferably 3 kPa or less, and still more preferably 2 kPa or less, at 20° C. By setting the vapor pressure of the organic developer to 5 kPa or less, the evaporation of the developer on a substrate or in a development cup is suppressed, and the temperature evenness within a wafer plane is improved, whereby the dimensional evenness within a wafer plane is enhanced.

Specific examples of the solvent having a vapor pressure of 5 kPa or less (2 kPa or less) include the solvents described in paragraph [0165] of JP2014-71304A.

An appropriate amount of a surfactant may be added to the organic developer, if desired.

The surfactant is not particularly limited, and for example, an ionic or nonionic, fluorine- and/or silicon-based surfactant can be used. Examples of such a fluorine- and/or silicon-based surfactant include surfactants described in JP1987-36663A (JP-S62-36663A), JP1986-226746A (JP-S61-226746A), JP1986-226745A (JP-S61-226745A), JP1987-170950A (JP-S62-170950A), JP988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), and U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, with the nonionic surfactant being preferable. The nonionic surfactant is not particularly limited, but the fluorine-based surfactant or the silicon-based surfactant is more preferably used.

The amount of the surfactant to be used is usually 0.001% to 5% by mass, preferably 0.005% to 2% by mass, and more preferably 0.01% to 0.5% by mass, with respect to the total amount of the developer.

The organic developer may also include a basic compound. Specific and preferred examples of the basic compound which can be included in the organic developer used in the present invention include those which will be described later as the basic compounds which can be included in the resist composition.

Examples of the developing method include a method in which a substrate is immersed in a tank filled with a developer for a certain period of time (a dip method), a method in which a developer is heaped up to the surface of a substrate by surface tension and developed by stopping for a certain period of time (a paddle method), a method in which a developer is sprayed on the surface of a substrate (a spray method), and a method in which a developer is continuously discharged on a substrate spun at a constant rate while scanning a developer discharging nozzle at a constant rate (a dynamic dispense method).

In addition, after the step of carrying out development using a developer containing an organic solvent, a step of stopping the development while replacing the solvent with another solvent may also be included.

A washing step using a rinsing liquid may be included after the step of carrying out development using a developer containing an organic solvent.

The rinsing liquid is not particularly limited as long as it does not dissolve the resist pattern, and a solution including a general organic solvent can be used. As the rinsing liquid, for example, a rinsing liquid containing at least one organic solvent selected from a hydrocarbon-based solvent, a ketone-based solvent, an ester-based solvent, an alcohol-based solvent, an amide-based solvent, and an ether-based solvent, described above as the organic solvent included in the organic developer is preferably used. More preferably, a step of carrying out washing using a rinsing liquid containing at least one organic solvent selected from a hydrocarbon-based solvent, a ketone-based solvent, an ester-based solvent, an alcohol-based solvent, and an amide-based solvent is carried out. Still more preferably, a step of carrying out washing using a rinsing liquid containing a hydrocarbon-based solvent, an alcohol-based solvent, or an ester-based solvent is carried out. Particularly preferably, a step of carrying out washing using a rinsing liquid containing a monohydric alcohol is carried out.

Here, examples of the monohydric alcohol used in the rinsing step include linear, branched, or cyclic monohydric alcohols, and specifically, 1-butanol, 2-butanol, 3-methyl-1-butanol, 3-methyl-2-butanol, tert-butyl alcohol, 1-pentanol, 2-pentanol, 3-methyl-2-pentanol, 4-methyl-2-pentanol, 1-hexanol, 2-hexanol, 3-hexanol, 4-methyl-2-hexanol, 5-methyl-2-hexanol, 1-heptanol, 2-heptanol, 3-heptanol, 4-methyl-2-heptanol, 5-methyl-2-heptanol, 1-octanol, 2-octanol, 3-octanol, 4-octanol, 4-methyl-2-octanol, 5-methyl-2-octanol, 6-methyl-2-octanol, 2-nonanol, 4-methyl-2-nonanol, 5-methyl-2-nonanol, 6-methyl-2-nonanol, 7-methyl-2-nonanol, 2-decanol, or the like can be used, with 1-hexanol, 2-hexanol, 1-pentanol, 3-methyl-1-butanol, or 4-methyl-2-heptanol being preferable.

Furthermore, examples of the hydrocarbon-based solvent used in the rinsing step include aromatic hydrocarbon-based solvents such as toluene and xylene; and aliphatic hydrocarbon-based solvents such as pentane, hexane, octane, decane (n-decane), and undecane.

In a case where an ester-based solvent is used as the rinsing liquid, a glycol ether-based solvent may be used, in addition to the ester-based solvent (one kind, or two or more kinds). As a specific example thereof in this case, an ester-based solvent (preferably butyl acetate) may be used as a main component, and a glycol ether-based solvent (preferably propylene glycol monomethyl ether (PGME)) may be used as a side component. Thus, residue defects are suppressed.

A plurality of the respective components may be mixed, or the components may be mixed with an organic solvents other than the above solvents before use.

The moisture content of the rinsing liquid is preferably 10% by mass or less, more preferably 5% by mass or less, and particularly preferably 3% by mass or less. By setting the moisture content to 10% by mass or less, good development characteristics can be obtained.

The vapor pressure of the rinsing liquid is preferably 0.05 to 5 kPa, more preferably 0.1 to 5 kPa, and still more preferably 0.12 to 3 kPa, at 20° C. By setting the vapor pressure of the rinsing liquid to a range from 0.05 to 5 kPa, the temperature evenness within a wafer plane is improved, and further, the dimensional evenness within a wafer plane is enhanced by inhibition of swelling due to the permeation of the rinsing liquid.

The rinsing liquid can also be used after adding an appropriate amount of a surfactant thereto.

In the rinsing step, the wafer which has been subjected to development using a developer containing an organic solvent is subjected to a washing treatment using the rinsing liquid including the organic solvent. A method for the washing treatment is not particularly limited, and for example, a method in which rinsing liquid is continuously discharged on a substrate rotated at a constant rate (a spin coating method), a method in which a substrate is immersed in a tank filled with rinsing liquid for a certain period of time (a dip method), a method in which rinsing liquid is sprayed onto a substrate surface (a spray method), or the like, can be applied. Among these, a method in which a washing treatment is carried out using the spin coating method, and a substrate is rotated at a rotation speed of 2,000 rpm to 4,000 rpm after washing, and then the rinsing liquid is removed from the substrate, is preferable. Further, it is preferable that a heating step (Post Bake) is included after the rinsing step. The residual developer and the rinsing liquid between and inside the patterns are removed by baking. The heating step after the rinsing step is carried out typically at 40° C. to 160° C., and preferably at 70° C. to 95° C., and typically for 10 seconds to 3 minutes, and preferably for 30 seconds to 90 seconds.

Moreover, the pattern forming method of the present invention may include a developing step using an organic developer and a developing step using an alkali developer. A portion having weak exposure intensity is removed by development using an organic developer, and a portion having strong exposure intensity is also removed by carrying out development using an alkali developer. Since pattern formation is carried out without only dissolving the region having intermediate exposure intensity by a multiple development process in which such development is carried out plural times in this manner, a finer pattern than usual can be formed (the same mechanism as that in paragraph [0077] of JP2008-292975A).

It is preferable that various materials (for example, the resist solvent, a developer, a rinsing liquid, a composition for forming an antireflection film, and the composition for forming a topcoat) used in the actinic ray-sensitive or radiation-sensitive resin composition of the present invention and the pattern forming method of the present invention include no impurities such as metal. The content of the impurities included in these materials is preferably 1 ppm or less, more preferably 100 ppt or less, and still more preferably 10 ppt or less, and particularly preferably, the impurities are not contained (no higher than the detection limit of a measurement device).

Examples of a method for removing impurities such as metals from the various materials include filtration using a filter. As for the filter pore diameter, the pore size is preferably 10 nm or less, more preferably 5 nm or less, and still more preferably 3 nm or less. With regard to the materials of a filter, a polytetrafluoroethylene-made filter, a polyethylene-made filter, and a nylon-made filter are preferable. As the filter, a filter which has been washed with an organic solvent in advance may also be used. In the step of filtration using a filter, plural kinds of filters may be connected in series or in parallel, and used. In the case of using plural kinds of filters, a combination of filters having different pore diameters and/or materials may be used. In addition, various materials may be filtered plural times, and a step of filtering plural times may be a circulatory filtration step.

Moreover, examples of the method for reducing the impurities such as metals included in the various materials include a method of selecting raw materials having a small content of metals as raw materials constituting various materials, a method of subjecting raw materials constituting various materials to filtration using a filter, and a method of carrying out distillation under the condition for suppressing the contamination as much as possible by, for example, lining the inside of a device with TEFLON (registered trademark). The preferred conditions for filtration using a filter, which is carried out for raw materials constituting various materials, are the same as described above.

In addition to filtration using a filter removal of impurities by an adsorbing material may be carried out, or a combination of filtration using a filter and an adsorbing material may be used. As the adsorbing material, known adsorbing materials may be used, and for example, inorganic adsorbing materials such as silica gel and zeolite, and organic adsorbing materials such as activated carbon can be used.

Furthermore, a mold for imprints may also be manufactured using the resist composition of the present invention, and with regard to the details thereof, reference can be made to, for example, JP4109085B. and JP2008-162101 A.

The pattern forming method of the present invention can also be used in formation of a guide pattern (see, for example, ACS Nano Vol. 4 No. 8 Pages 4815-4823) in Directed Self-Assembly (DSA).

In addition, the resist pattern formed by the method can be used as a core material (core) in the spacer process disclosed in, for example, JP991-270227A (JP-H03-270227A) and JP2013-164509A.

A method for improving the surface roughness of the pattern may also be applied to the pattern formed by the method of the present invention. Examples of the method for improving the surface roughness of the pattern include a method for treating a resist pattern by plasma of a hydrogen-containing gas disclosed in WO2014/002808A1. In addition, known methods as described in JP2004-235468A, US2010/0020297A, JP2009-19969A, Proc. of SPIE Vol. 8328 83280N-1 “EUV Resist Curing Technique for LWR Reduction and Etch Selectivity Enhancement” may also be applied.

[4] Resist Composition

Next, the resist composition of the present invention used in the pattern forming method of the present invention will be described.

(A) Resin

The resist composition in the present invention may be either a negative tone resist composition or a positive tone resist composition, and typically contains a resin whose solubility in a developer containing an organic solvent is decreased due to an increase in the polarity by the action of an acid.

The resin whose solubility in a developer containing an organic solvent is decreased due to an increase in the polarity by the action of an acid (hereinafter also referred to as a “resin (A)”) is preferably a resin (hereinafter also referred to as an “acid-decomposable resin” or an “acid-decomposable resin (A)”) having a group (hereinafter also referred to as an “acid-decomposable group”) that decomposes by the action of an acid to generate a polar group at either the main chain or the side chain of the resin, or at both the main chain and the side chain.

Furthermore, the resin (A) is more preferably a resin having an alicyclic hydrocarbon structure which is monocyclic or polycyclic (hereinafter also referred to as an “alicyclic hydrocarbon-based acid-decomposable resin”). It is thought that the resin having an alicyclic hydrocarbon structure which is monocyclic or polycyclic has high hydrophobicity and has improved developability in a case of developing an area of the resist film having a weak light irradiation intensity by an organic developer.

The resist composition of the present invention, containing the resin (A), can be suitably used in a case of irradiation with ArF excimer laser light.

Typical examples of the polar group in the acid-decomposable group include an acid group, and specifically, groups having a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, or a tris(alkylsulfonyl)methylene group.

Preferred examples of the polar group include a carboxylic acid group, a fluorinated alcohol group (preferably hexafluoroisopropanol), and a sulfonic acid group.

A preferred group that decomposes by an acid (acid-decomposable group) is a group obtained by substituting a hydrogen atom of these polar groups with a group that leaves by an acid.

Examples of the group that leaves by an acid include —C(R₃₆)(R₃₇)(R₃₈), —C(R₃₆)(R₃₇)(R₃₉), and —C(R₀₁)(R₀₂)(R₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

As the acid-decomposable group, a cumyl ester group, an enol ester group, an acetal ester group, a tertiary alkyl ester group, and the like are preferable, and a tertiary alkyl ester group is more preferable.

The resin (A) is preferably a resin containing at least one selected from the group consisting of repeating units having partial structures represented by General Formulae (pI) to (pV), and a repeating unit represented by General Formula (II-AB).

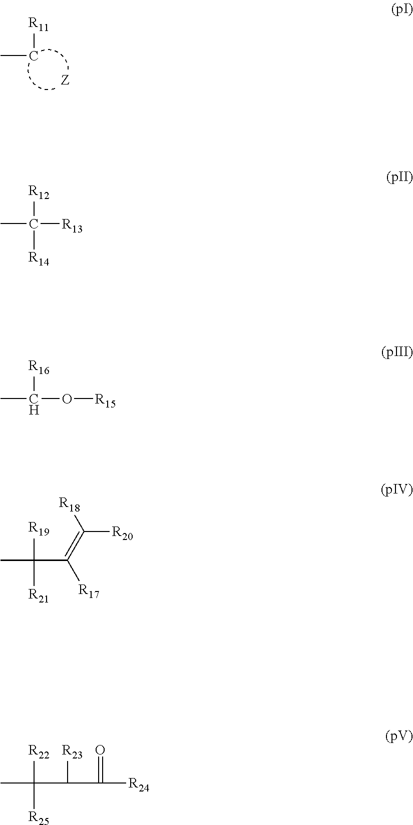

In General Formulae (pI) to (pV),

R₁₁ represents a methyl group, an ethyl group, an n-propyl group, an isopropyl group, an n-butyl group, an isobutyl group, or a sec-butyl group, and Z represents an atomic group which is necessary for forming a cycloalkyl group together with carbon atoms.

R₁₂ to R₁₆ each independently represent a linear or branched alkyl group or cycloalkyl group, having 1 to 4 carbon atoms, provided that at least one of R₁₂, . . . , or R₁₄, or any one of R₁₅ and R₁₆ is a cycloalkyl group.

R₁₇ to R₂₁ each independently represent a hydrogen atom, or a linear or branched alkyl group or cycloalkyl group, having 1 to 4 carbon atoms, provided that at least one of R₁₇, . . . , or R₂₁ is a cycloalkyl group. Further, any one of R₁₉ and R₂₁ is a linear or branched alkyl group or cycloalkyl group, having 1 to 4 carbon atoms.

R₂₂ to R₂₅ each independently represent a hydrogen atom, or a linear or branched alkyl group or cycloalkyl group, having 1 to 4 carbon atoms, provided that at least one of R₂₂, . . . , or R₂₅ is a cycloalkyl group. Further, R₂₃ and R₂₄ may be bonded to each other to form a ring.

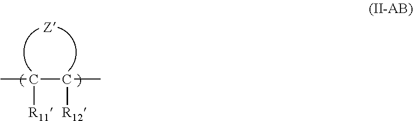

In General Formula (II-AB),

R₁₁′ and R₁₂′ each independently represent a hydrogen atom, a cyano group, a halogen atom, or an alkyl group.

Z′ represents an atomic group for forming an alicyclic structure, which contains two carbon atoms bonded to each other (C—C).

Furthermore, it is more preferable that General Formula (II-AB) is General Formula

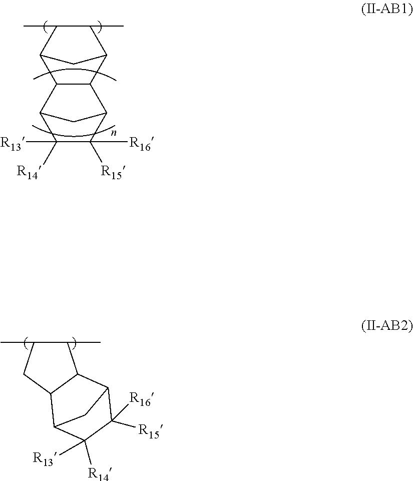

in Formulae (II-AB1) and (II-AB2),

R₁₃′ to R₁₆′ each independently represent a hydrogen atom, a halogen atom, a cyano group, —COOH, —COOR₅, a group that decomposes by the action of an acid, —C(═O)—X-A′-R₁₇′, an alkyl group, or a cycloalkyl group, provided that at least two of R₁₃′, . . . , or R₁₆′ may be bonded to each other to form a ring.

Here, R₅ represents an alkyl group, a cycloalkyl group, or a group having a lactone structure.

X represents an oxygen atom, a sulfur atom, —NH—, —NHSO₂—, or —NHSO₂NH—.

A′ represents a single bond or a divalent linking group.

R₁₇′ represents —COOH, —COOR₅, —CN, a hydroxyl group, an alkoxy group, —CO—NH—R₆, —CO—NH—SO₂—R₆, or a group having a lactone structure.

R₆ represents an alkyl group or a cycloalkyl group.

n represents 0 or 1.

In General Formulae (pI) to (pV), the alkyl group in each of R₁₂ to R₂₅ is a linear or branched alkyl group having 1 to 4 carbon atoms.

The cycloalkyl group in each of R₁₁ to R₂₅ or the cycloalkyl group formed by Z together with carbon atoms may be monocyclic or polycyclic. Specific examples thereof include a group having 5 or more carbon atoms and having a monocyclo, bicyclo, tricyclo, or tetracyclo structure. These cycloalkyl groups preferably have 6 to 30 carbon atoms, and particularly preferably has 7 to 25 carbon atoms. These cycloalkyl groups may have a substituent.

Preferred examples of the cycloalkyl group include an adamantyl group, a noradamantyl group, a decalin residue, a tricyclodecanyl group, a tetracyclododecanyl group, a norbornyl group, cedrol group, a cyclopentyl group, a cyclohexyl group, a cycloheptyl group, a cyclooctyl group, a cyclodecanyl group, and a cyclododecanyl group. More preferred examples thereof include an adamantyl group, a norbornyl group, a cyclohexyl group, a cyclopentyl group, a tetracyclododecanyl group, and a tricyclodecanyl group.

Examples of a substituent which may further be included in these alkyl groups and cycloalkyl groups include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). Examples of the substituent which may further be included in the alkyl group, the alkoxy group, the alkoxycarbonyl group, or the like include a hydroxyl group, a halogen atom, and an alkoxy group.

The structures represented by General Formulae (pI) to (pV) in the resin can be used in the protection of the polar group. Examples of the polar group include various groups that have been known in the technical field.

Specific examples of the structure include a structure in which a hydrogen atom in a carboxylic acid group, a sulfonic acid group, a phenol group, or a thiol group is substituted with a structure represented by any one of General Formulae (pI) to (pV), with a structure in which a hydrogen atom in a carboxylic acid group or a sulfonic acid group is substituted with a structure represented by any one of General Formulae (pI) to (pV) being preferable.

As the repeating unit having a polar group protected by the structure represented by any one of General Formulae (pI) to (pV), a repeating unit represented by General Formula (pA) is preferable.

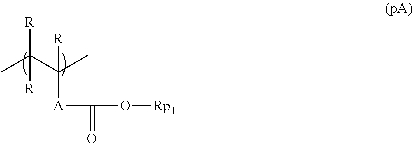

Here, R represents a hydrogen atom, a halogen atom, or a linear or branched alkyl group having 1 to 4 carbon atoms, and a plurality of R's may be the same as or different from each other.

A is a single bond, or one group or a combination of two or more groups selected from the group consisting of an alkylene group, an ether group, a thioether group, a carbonyl group, an ester group, an amido group, a sulfonamido group, a urethane group, or a urea group, with a single bond being preferable.

Rp₁ is a group of any one of Formulae (pI) to (pV).

The repeating unit represented by General Formula (pA) is particularly preferably a repeating unit derived from 2-alkyl-2-adamantyl (meth)acrylate or dialkyl(l-adamantyl)methyl (meth)acrylate.

Specific examples of the repeating unit represented by General Formula (pA) are shown below, but the present invention is not limited thereto.

(In the following formulae, Rx represents H, CH₃, or CH₂OH; and Rxa and Rxb each represent an alkyl group having 1 to 4 carbon atoms)

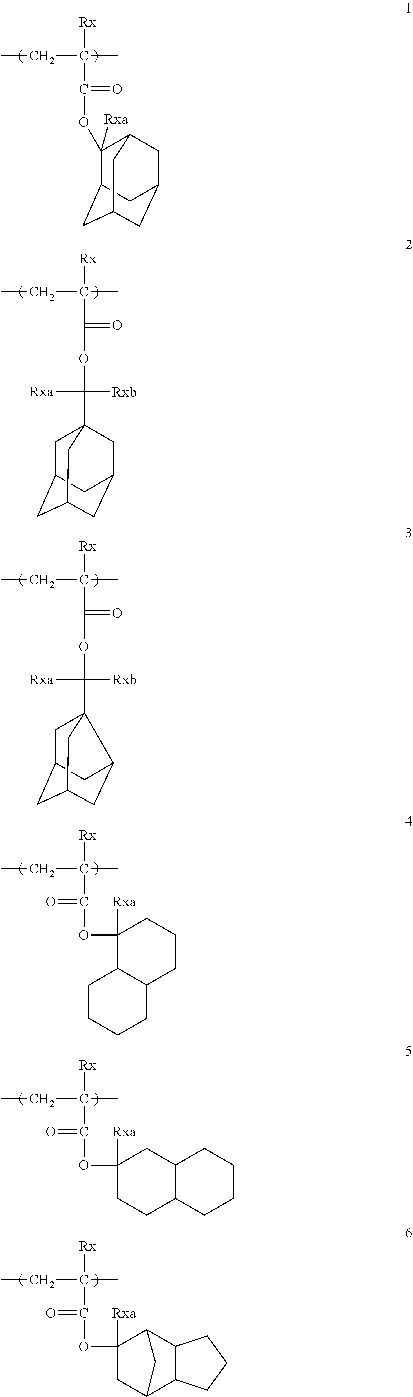

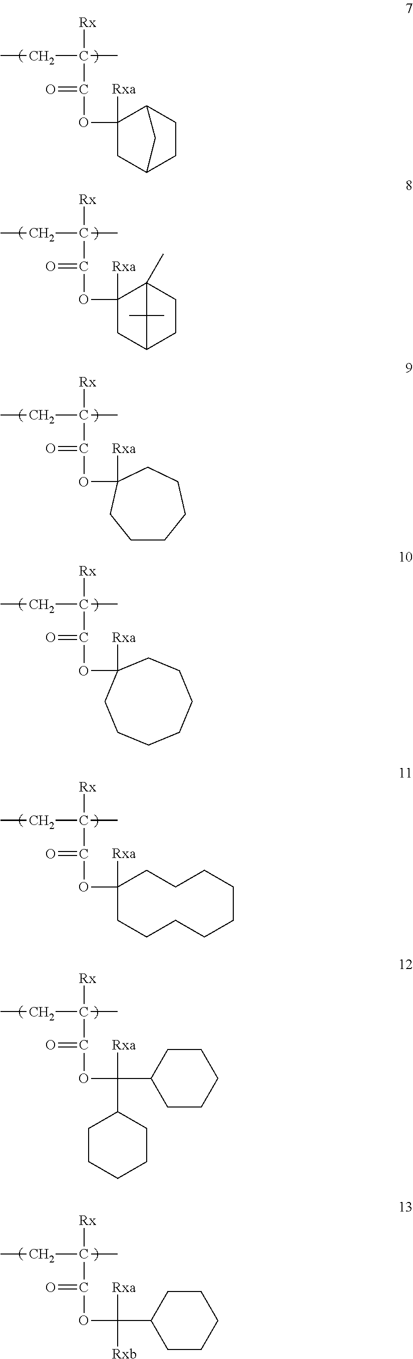

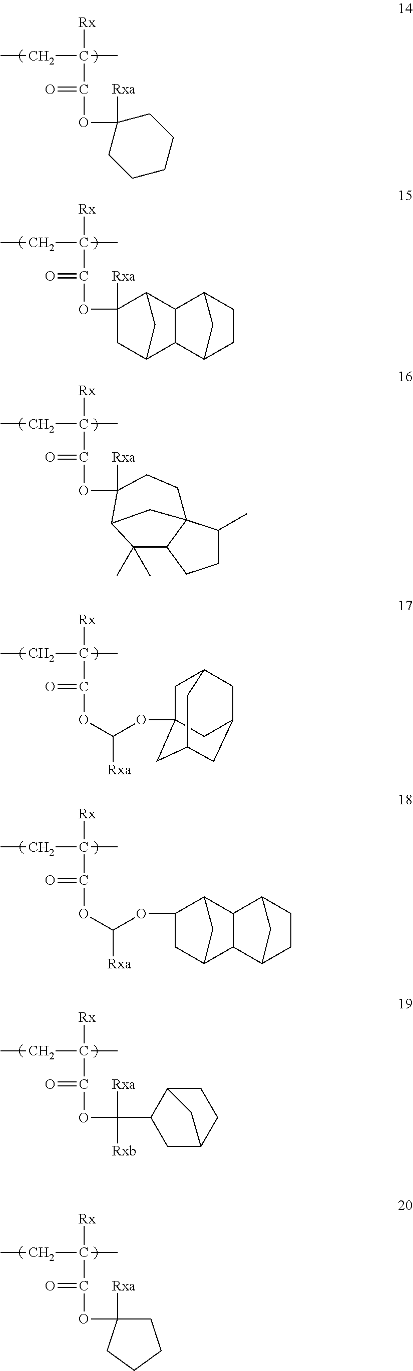

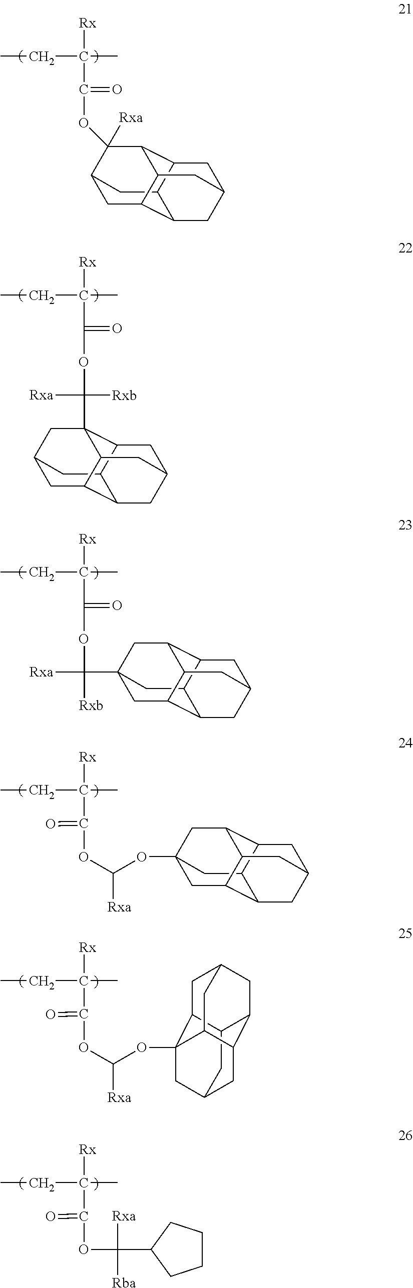

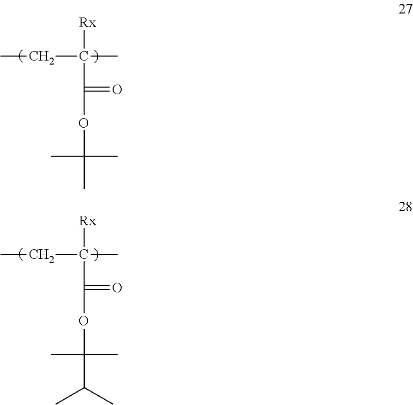

In General Formula (II-AB), examples of the halogen atoms in R₁₁′ and R₁₂′ include a chlorine atom, a bromine atom, a fluorine atom, and an iodine atom.

Examples of the alkyl group in each of R₁₁′ and R₁₂′ include a linear or branched alkyl group having 1 to 10 carbon atoms.

The atomic group for forming the alicyclic structure of Z′ is an atomic group that forms a repeating unit of an alicyclic hydrocarbon, which may have a substituent, in the resin. Above all, an atomic group for forming a crosslinked alicyclic structure that forms a crosslinked alicyclic hydrocarbon repeating unit is preferable.

Examples of the skeleton of the alicyclic hydrocarbon thus formed include the same ones as the alicyclic hydrocarbon groups represented by each of R₁₂ to R₂₅ in General Formulae (pI) to (pV).

The skeleton of the alicyclic hydrocarbon may have a substituent. Examples of the substituent include R₁₃′ to R₁₆′ in General Formula (II-AB1) or (II-AB2).

The resin (A) is preferably a resin having a repeating unit having an acid-decomposable group, and the acid-decomposable group is included in at least one repeating unit of a repeating unit having a partial structure represented by any one of General Formulae (pI) to (pV), a repeating unit represented by General Formula (II-AB), or a repeating unit of the following copolymerizable component. It is preferable that the acid-decomposable group is included in a repeating unit having a partial structure represented by any one of General Formulae (pI) to (pV).

The repeating unit having an acid-decomposable group contained in the resin (A) may be used singly or in combination of two or more kinds thereof.

It is preferable that the resin (A) contains a repeating unit having a lactone structure or a sultone (cyclic sulfonic acid ester) structure.

As the lactone group or the sultone group, any group may be used as long as it has a lactone structure or a sultone structure, but the structure is preferably a 5- to 7-membered ring lactone structure or sultone structure, and more preferably a 5- to 7-membered ring lactone structure or sultone structure to which another ring structure is fused in the form of forming a bicyclo structure or a spiro structure. The resin (A) still more preferably has a repeating unit having a lactone structure or a sultone structure represented by any one of General Formulae (LC1-1) to (LC1-17), (SL1-1), and (SL1-2). Further, the lactone structure or the sultone structure may be bonded directly to the main chain. The lactone structures or the sultone structures are preferably (LC1-1), (LC1-4), (LC1-5), and (LC1-8), and more preferably (LC1-4). By using such a specific lactone structure or sultone structure, LWR and development defects are relieved.

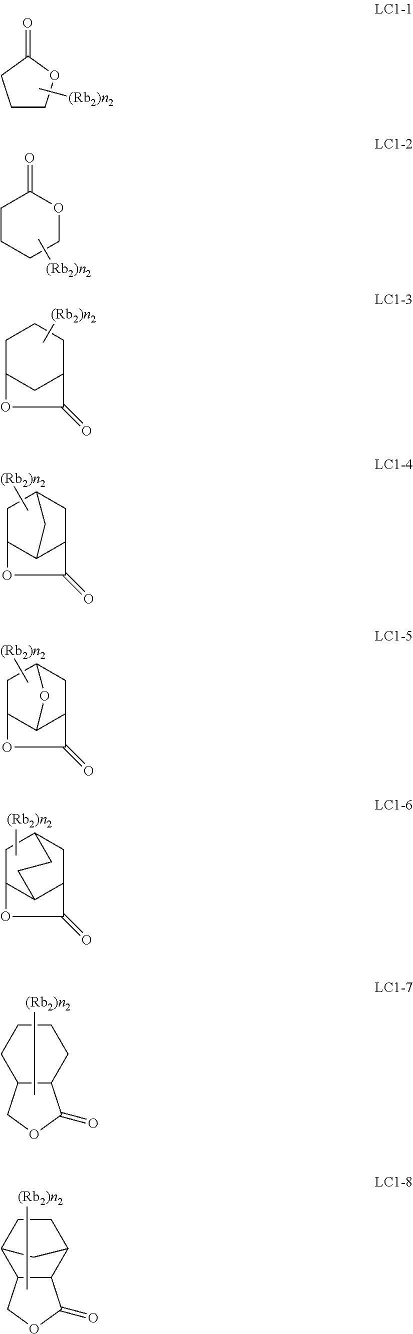

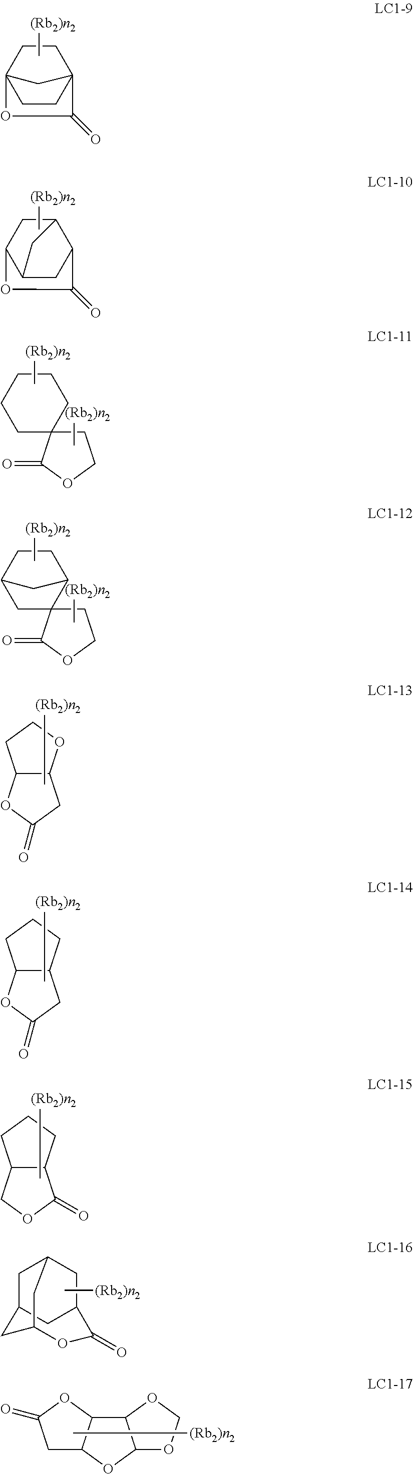

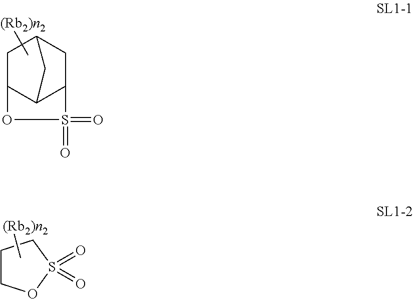

The lactone structure moiety or the sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. Among these, an alkyl group having 1 to 4 carbon atoms, a cyano group, and an acid-decomposable group are more preferable. n₂ represents an integer of 0 to 4. When n₂ is 2 or more, the substituents (Rb₂) which are present in plural numbers may be the same as or different from each other, and further, the substituents (Rb₂) which are present in plural numbers may be bonded to each other to form a ring.

The resin (A) preferably has a repeating unit containing an organic group having a polar group, in particular, a repeating unit having an alicyclic hydrocarbon structure substituted with a polar group. Thus, the substrate adhesiveness and the developer affinity are improved. As the alicyclic hydrocarbon structure of the alicyclic hydrocarbon structure substituted with a polar group, an adamantyl group, a diamantyl group, or a norbornane group is preferable. As the polar group, a hydroxyl group or a cyano group is preferable.

Preferred examples of the alicyclic hydrocarbon structure substituted with a polar group include partial structures represented by General Formulae (VIIa) to (VIId).

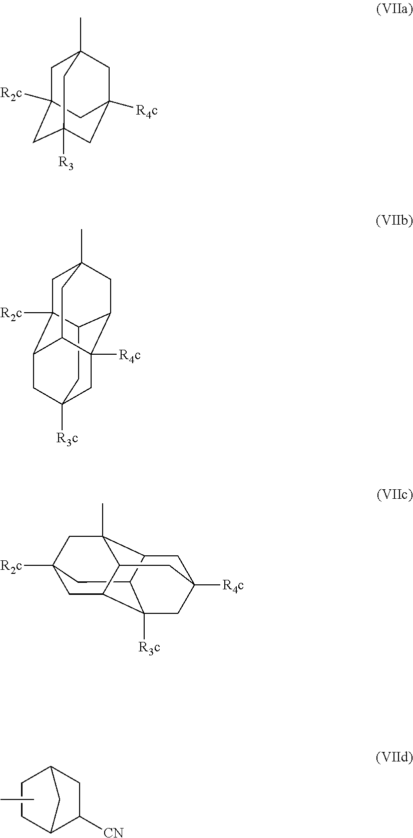

In General Formulae (VIIa) to (VIIc),

R_{2c} to R_{4c} each independently represent a hydrogen atom, a hydroxyl group, or a cyano group, provided that at least one of R_{2c}, . . . , or R_{4c} represents a hydroxyl group or a cyano group. It is preferable that one or two of R_{2c} to R_{4c} are hydroxyl group(s) and the remainders are hydrogen atoms.

In General Formula (VIIa), it is more preferable that two of R_{2c} to R_{4c} are hydroxyl groups and the remainders are hydrogen atoms.

Examples of the repeating unit having a group represented by any one of General Formulae (VIIa) to (VIId) include those in which at least one of R₁₃′, . . . , or R₁₆′ in General Formula (II-AB1) or (II-AB2) has a group represented by General Formula (VIIa) to (VIId) (for example, —COOR₅ in which R₅ is a group represented by any one of General Formulae (VIIa) to (VIId)), and repeating units represented by General Formulae (AIIa) to (AIId).

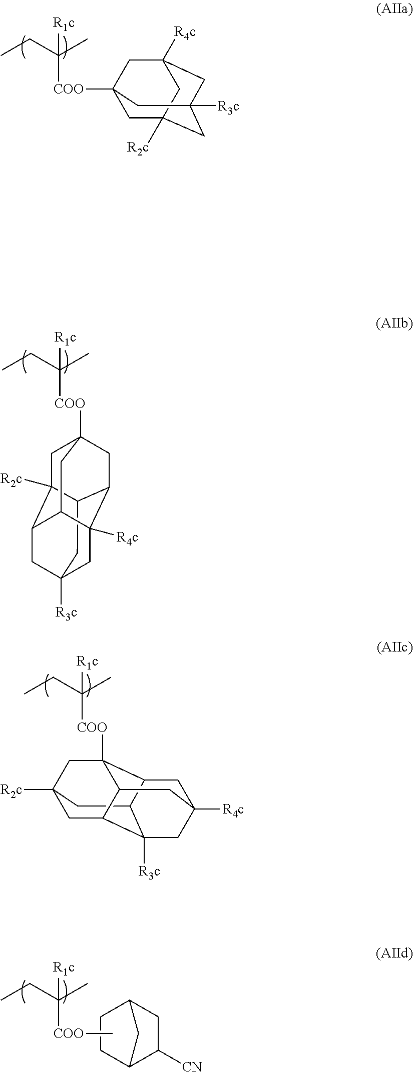

In General Formulae (AIIa) to (AIId),

R_{1c} represents a hydrogen atom, a methyl group, a trifluoromethyl group, or a hydroxymethyl group.

R_{2c} to R_{4c} have the same definitions as R_{2c} to R_{4c} in General Formulae (VIIa) to (VIIc).

Specific examples of the repeating units having the structures represented by General Formulae (AIIa) to (AIId) will be shown below, but the present invention is not limited thereto.

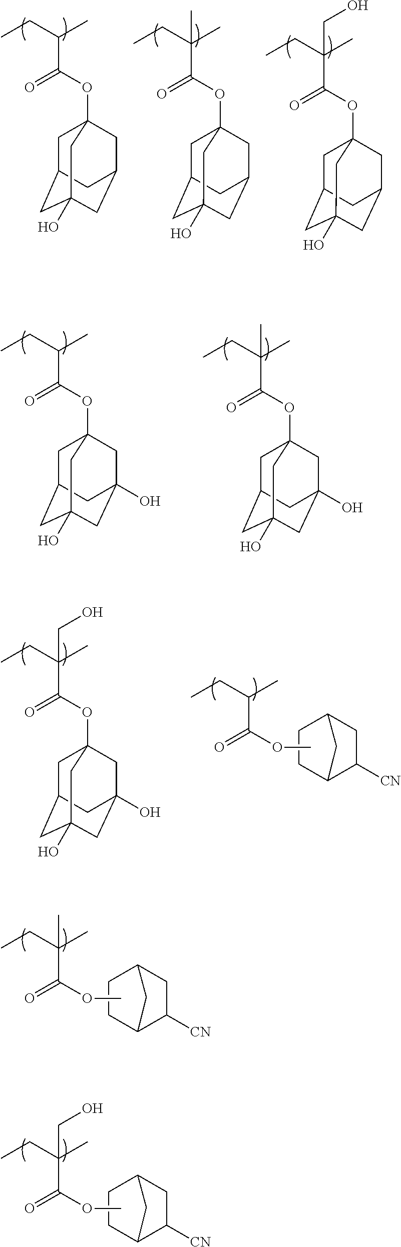

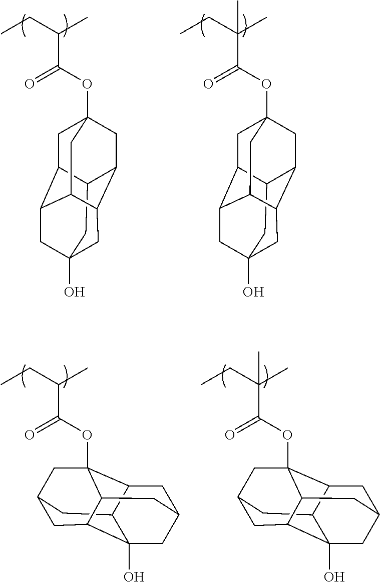

The weight-average molecular weight of the resin (A) is preferably 1,000 to 200,000, more preferably 1,000 to 20,000, and still more preferably 1,000 to 15,000 as a value in terms of polystyrene, measured by a GPC method. By setting the weight-average molecular weight to 1,000 to 200,000, the heat resistance and the dry etching resistance can be prevented from being deteriorated, and the film forming properties can be prevented from being deteriorated due to deteriorated developability or increased viscosity.

The resin (A) having a dispersity (molecular weight distribution) in a range of usually 1 to 5, preferably 1 to 3, more preferably 1.2 to 3.0, and particularly preferably 1.2 to 2.0 is used. As the dispersity is smaller, the resolution and the resist shape are excellent, the side wall of the resist pattern is smooth, and the roughness is excellent.

The content of the resin (A) is preferably 50% to 99.9% by mass, and more preferably 60% to 99.0% by mass, with respect to the total solid contents of the resist composition.

Incidentally, in the present invention, the resin (A) may be used singly or in combination of plural kinds thereof.

It is preferable that the resin (A), preferably the resist composition of the present invention, contains neither a fluorine atom nor a silicon atom from the viewpoint of the compatibility with a topcoat composition.

(B) Compound that Generates Acid Upon Irradiation with Actinic Ray or Radiation

The resist composition in the present invention typically contains a compound that generates an acid upon irradiation with actinic ray or radiation (also referred to as a “photoacid generator” or a “compound (B)”).

The compound (B) may be in a form of a low molecular compound or in a form introduced into a part of a polymer. Further, a combination of the form of a low molecular compound and the form introduced into a part of a polymer may also be used.

In a case where the compound (B) is in the form of a low molecular compound, the molecular weight is preferably 3,000 or less, more preferably 2,000 or less, and still more preferably 1,000 or less.

In a case where the compound (B) is in the form introduced into a part of a polymer, it may be introduced into a part of the above-mentioned acid-decomposable resin or into a resin other than the acid-decomposable resin.

In the present invention, it is preferable that the compound (B) is in the form of a low molecular compound.

As such a compound (B), a compound may be appropriately selected from known compounds capable of generating an acid upon irradiation with actinic ray or radiation, which are used in a photoinitiator for cationic photopolymerization, a photoinitiator for radical photopolymerization, a photodecoloring agent for coloring agents, a photodiscoloring agent, a microresist, or the like, and a mixture thereof, and used.

Examples of the compound include a diazonium salt, a phosphonium salt, a sulfonium salt, an iodonium salt, imidosulfonate, oxime sulfonate, diazodisulfone, disulfone, and o-nitrobenzyl sulfonate.

In addition, as a compound in which a group or compound that generates an acid upon irradiation with actinic ray or radiation is introduced into the main or side chain of the polymer, for example, the compounds described in U.S. Pat. No. 3,849,137A, GE3914407A, JP1988-26653A (JP-S63-26653A), JP1980-164824A (JP-S55-164824A), JP1987-69263A (JP-S62-69263A), JP1988-146038A (JP-S63-146038A), JP1988-163452A (JP-S63-163452A), JP1987-153853A (JP-S62-153853A), JP1988-46029A (JP-S63-146029A), and the like can be used.

In addition, the compounds that generate an acid by light described in U.S. Pat. No. 3,779,778A, EP126712B, and the like can also be used.

The compound (B) is preferably a compound that generates an acid having a cyclic structure upon irradiation with actinic ray or radiation. As the cyclic structure, a monocyclic or polycyclic alicyclic group is preferable, and a polycyclic alicyclic group is more preferable. It is preferable that carbonyl carbon is not included as a carbon atom constituting the ring skeleton of the alicyclic group.

Suitable examples of the compound (B) include a compound (a specific acid generator) that generates an acid upon irradiation with actinic ray or radiation represented by General Formula (3).

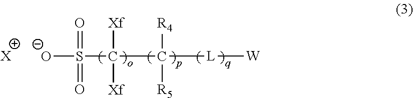

(Anion)

In General Formula (3),

Xf's each independently represent a fluorine atom or an alkyl group substituted with at least one fluorine atom.

R₄ and R₅ each independently represent a hydrogen atom, a fluorine atom, an alkyl group, or an alkyl group substituted with at least one fluorine atom, and in a case where R₄ and R₅ are present in plural numbers, they may be the same as or different from each other.

L represents a divalent linking group, and in a case where L's are present in plural numbers, they may be the same as or different from each other.

W represents an organic group including a cyclic structure.

o represents an integer of 1 to 3. p represents an integer of 0 to 10. q represents an integer of 0 to 10.

Xf represents a fluorine atom or an alkyl group substituted with at least one fluorine atom. The number of carbon atoms of the alkyl group is preferably 1 to 10, and more preferably 1 to 4. Further, the alkyl group substituted with at least one fluorine atom is preferably a perfluoroalkyl group.

Xf is preferably a fluorine atom or a perfluoroalkyl group having 1 to 4 carbon atoms. Xf is more preferably a fluorine atom or CF₃. It is particularly preferable that both Xf's are fluorine atoms.

R₄ and R₅ each independently represent a hydrogen atom, a fluorine atom, an alkyl group, or an alkyl group substituted with at least one fluorine atom, and in a case where R₄ and R₅ are present in plural numbers, they may be the same as or different from each other.

The alkyl group as R₄ and R₅ may have a substituent, and preferably has 1 to 4 carbon atoms. R₄ and R₅ are each preferably a hydrogen atom.

Specific examples and suitable aspects of the alkyl group substituted with at least one fluorine atom are the same as the specific examples and suitable aspects of Xf in General Formula (3).

L represents a divalent linking group, and in a case where L's are present in plural numbers, they may be the same as or different from each other.

Examples of the divalent linking group include —COO—(—C(═O)—O—), —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), or a divalent linking group formed by combination of these plurality of groups. Among these, —COO—, —OCO—, —CONH—, —NHCO—, —CO—, —O—, —SO₂—, —COO-alkylene group-, —OCO-alkylene group-, —CONH-alkylene group-, or —NHCO-alkylene group- is preferable, and —COO—, —OCO—, —CONH—, —SO₂—, —COO-alkylene group-, or —OCO-alkylene group- is more preferable.

W represents an organic group including a cyclic structure. Above all, it is preferably a cyclic organic group.

Examples of the cyclic organic group include an alicyclic group, an aryl group, and a heterocyclic group.

The alicyclic group may be monocyclic or polycyclic, and examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, a diamantyl group, and an adamantyl group. Among these, an alicyclic group having a bulky structure having 7 or more carbon atoms, such as a norbornyl group, a tricyclodecanyl group, a tetracyclodecanyl group, a tetracyclododecanyl group, a diamantyl group, and an adamantyl group is preferable from the viewpoints of inhibiting diffusivity into the film during post exposure baking (PEB) process and improving Mask Error Enhancement Factor (MEEF).

The aryl group may be monocyclic or polycyclic. Examples of the aryl group include a phenyl group, a naphthyl group, a phenanthryl group, and an anthryl group. Among these, a naphthyl group showing a relatively low light absorbance at 193 nm is preferable.

The heterocyclic group may be monocyclic or polycyclic, but the heterocyclic group which is polycyclic can further suppress acid diffusion. Further, the heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle having no aromaticity include a tetrahydropyran ring, a lactone ring, a sultone ring, and a decahydroisoquinoline ring. As a heterocycle in the heterocyclic group, a furan ring, a thiophene ring, a pyridine ring, or a decahydroisoquinoline ring is particularly preferable. Further, examples of the lactone ring and the sultone ring include the lactone structures and sultone structures exemplified in the above-mentioned resin.

The cyclic organic group may have a substituent. Examples of the substituent include, an alkyl group (which may be linear or branched, and preferably has 1 to 12 carbon atoms), a cycloalkyl group (which may be any one of monocyclic, polycyclic, and spiro rings, and preferably has 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic acid ester group. Incidentally, the carbon constituting the cyclic organic group (the carbon contributing to ring formation) may be carbonyl carbon.

o represents an integer of 1 to 3. p represents an integer of 0 to 10. q represents an integer of 0 to 10.

In one aspect, it is preferable that in General Formula (3), o is an integer of 1 to 3, p is an integer of 1 to 10, and q is 0. Xf is preferably a fluorine atom, R₄ and R₅ are preferably both hydrogen atoms, and W is preferably a polycyclic hydrocarbon group. o is more preferably 1 or 2, and still more preferably 1. p is more preferably an integer of 1 to 3, still more preferably 1 or 2, and particularly preferably 1. W is more preferably a polycyclic cycloalkyl group, and still more preferably an adamantyl group or a diamantyl group.

(Cation)

In General Formula (3), X⁺ represents a cation.

X⁺ is not particularly limited as long as it is a cation, but suitable aspects thereof include cations (moieties other than Z⁻) in General Formula (ZI), (ZII), or (ZIII) which will be described later.

(Suitable Aspects)

Suitable aspects of the specific acid generator include a compound represented by General Formula (ZI), (ZII), or (ZIII).

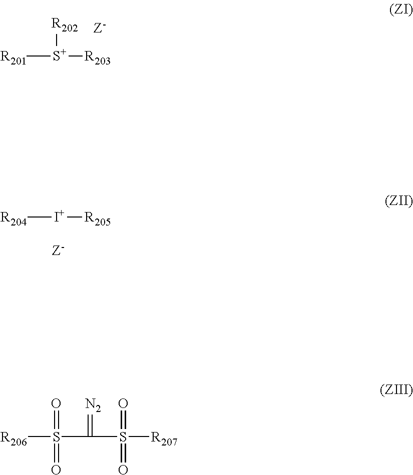

In General Formula (ZI),

R₂₀₁, R₂₀₂, and R₂₀₃ each independently represent an organic group.

The number of carbon atoms of the organic group as R₂₀₁, R₂₀₂, and R₂₀₃ is generally 1 to 30, and preferably 1 to 20.

Furthermore, two of R₂₀₁ to R₂₀₃ may be bonded to each other to form a ring structure, and the ring may include an oxygen atom, a sulfur atom, an ester bond, an amide bond, or a carbonyl group, and examples of the group formed by the bonding of two of R₂₀₁ to R₂₀₃ include an alkylene group (for example, a butylene group and a pentylene group).

Z⁻ represents an anion in General Formula (3), and specifically represents the following anion.

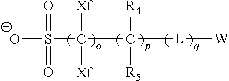

Incidentally, the acid generator may be a compound having a plurality of structures represented by General Formula (ZI). For example, it may be a compound having a structure in which at least one of R₂₀₁, . . . , or R₂₀₃ in the compound represented by General Formula (ZI) is bonded to at least one of R₂₀₁, . . . , or R₂₀₃ of another compound represented by General Formula (ZI) through a single bond or a linking group.

The compound (B) may be used singly or in combination of two or more kinds thereof.

The content of the compound (B) (a total sum of contents in a case where the compound (B) is present in plural kinds) in the composition is preferably 0.1% to 30% by mass, more preferably 0.5% to 25% by mass, still more preferably 3% to 20% by mass, and particularly preferably 3% to 15% by mass, with respect to the total solid contents of the composition.

(C) Solvent

Examples of the solvent which can be used in a case where the respective components are dissolved to prepare a resist composition include organic solvents such as alkylene glycol monoalkyl ether carboxylate, alkylene glycol monoalkyl ether, alkyl lactate ester, alkyl alkoxypropionate, a cyclic lactone having 4 to 10 carbon atoms, a monoketone compound having 4 to 10 carbon atoms, which may have a ring, alkylene carbonate, alkyl alkoxyacetate, and alkyl pyruvate.

(D) Hydrophobic Resin

The resist composition in the present invention may contain a hydrophobic resin (D). As the hydrophobic resin, the above-mentioned polymers (X) described with regard to the topcoat composition can be suitably used. A suitable aspect of the hydrophobic resin is the same as the above-mentioned polymer (X). For example, the hydrophobic resin preferably contains at least one selected from the group consisting of a fluorine atom, a silicon atom, or a CH₃ partial structure contained in a side chain moiety of a resin. Further, the hydrophobic resin includes the repeating units containing fluorine atoms in the amount of preferably 0% to 20% by mole, more preferably 0% to 10% by mole, still more preferably 0% to 5% by mole, particularly preferably 0% to 3% by mole, and ideally 0% by mole, that is, containing no fluorine atom, with respect to all the repeating units. The hydrophobic resin preferably includes a repeating unit having at least one CH₃ partial structure in the side chain moiety, more preferably includes a repeating unit having at least two CH₃ partial structures in the side chain moiety, and still more preferably includes a repeating unit having at least three CH₃ partial structures in the side chain moiety. The hydrophobic resin is preferably a solid at normal temperature (25° C.). Incidentally, the glass transition temperature (Tg) is preferably 50° C. to 250° C., more preferably 70° C. to 250° C., still more preferably 80° C. to 250° C., particularly preferably 90° C. to 250° C., and most preferably 100° C. to 250° C. The hydrophobic resin preferably has a repeating unit having a monocyclic or polycyclic cycloalkyl group. The monocyclic or polycyclic cycloalkyl group may be included in any one of the main chain and the side chain of the repeating unit. The hydrophobic resin more preferably has a repeating unit having both of a monocyclic or polycyclic cycloalkyl group and a CH₃ partial structure, and still more preferably has a repeating unit having both of a monocyclic or polycyclic cycloalkyl group and a CH₃ partial structure in the side chain.

The weight-average molecular weight of the hydrophobic resin (D) in terms of standard polystyrene is preferably 1,000 to 100,000, more preferably 1,000 to 50,000, and still more preferably 2,000 to 15,000.

The hydrophobic resin (D) may be used singly or in combination of plural kinds thereof.

The content of the hydrophobic resin (D) in the composition is generally 0.01% to 30% by mass, preferably 0.01% to 10% by mass, more preferably 0.05% to 8% by mass, and still more preferably 0.1% to 7% by mass, with respect to the total solid contents of the resist composition of the present invention.

(E) Basic Compound

The resist composition in the present invention preferably contains a basic compound (E) in order to reduce a change in performance over time from exposure to heating.

Preferred examples of the basic compound include compounds having structures represented by Formulae (A) to (E).

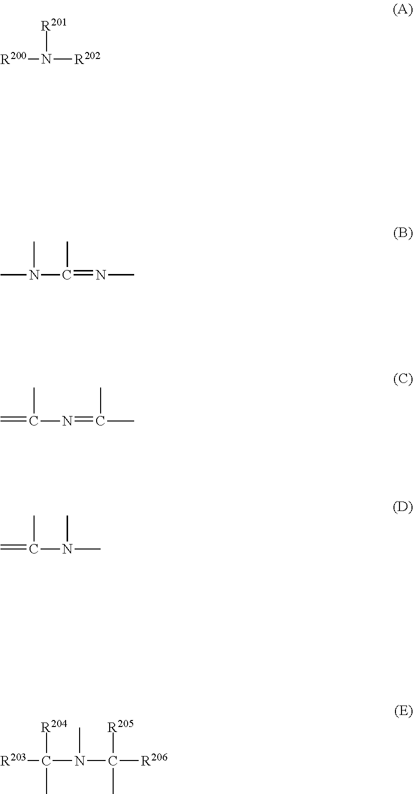

In General Formulae (A) to (E),

R²⁰⁰, R²⁰¹, and R²⁰² may be the same as or different from each other, represent a hydrogen atom, an alkyl group (preferably having 1 to 20 carbon atoms), a cycloalkyl group (preferably having 3 to 20 carbon atoms), or an aryl group (having 6 to 20 carbon atoms), in which R²⁰¹ and R²⁰² may be bonded to each other to form a ring.

With respect to the alkyl group, as the alkyl group having a substituent, an aminoalkyl group having 1 to 20 carbon atoms, a hydroxyalkyl group having 1 to 20 carbon atoms, or a cyanoalkyl group having 1 to 20 carbon atoms is preferable.

R²⁰³, R²⁰⁴, R²⁰⁵, and R²⁰⁶ may be the same as or different from each other, and each represent an alkyl group having 1 to 20 carbon atoms.

The alkyl group in General Formulae (A) to (E) is more preferably unsubstituted.

Preferred examples of the compound include guanidine, aminopyrrolidine, pyrazole, pyrazoline, piperazine, aminomorpholine, aminoalkylmorpholine and piperidine. More preferred examples of the compound include a compound having an imidazole structure, a diazabicyclo structure, an onium hydroxide structure, an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]non-5-ene, and 1,8-diazabicyclo[5,4,0]undec-7-ene. Examples of the compound having an onium hydroxide structure include triarylsulfonium hydroxide, phenacylsulfonium hydroxide, and sulfonium hydroxide having a 2-oxoalkyl group, specifically triphenylsulfonium hydroxide, tris(t-butylphenyl)sulfonium hydroxide, bis(t-butylphenyl)iodonium hydroxide, phenacylthiophenium hydroxide and 2-oxopropylthiophenium hydroxide. The compound having an onium carboxylate structure is formed by carboxylation of an anionic moiety of a compound having an onium hydroxide structure, and examples thereof include acetate, adamantane-1-carboxylate, and perfluoroalkyl carboxylate. Examples of the compound having a trialkylamine structure include tri(n-butyl)amine and tri(n-octyl)amine. Examples of the compound having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

Furthermore, as the basic compound, those described as a basic compound, which may be contained in the above-mentioned composition (topcoat composition) for forming an upper layer film can also be suitably used.

These basic compounds may be used singly or in combination of two or more kinds thereof.

The amount of the basic compound to be used is usually 0.001% to 10% by mass, and preferably 0.01% to 5% by mass, with respect to the solid contents of the resist composition of the present invention.

The ratio between the photoacid generator to the basic compound to be used in the resist composition is preferably the photoacid generator/basic compound (molar ratio)=2.5 to 300. That is, the molar ratio is preferably 2.5 or more in view of sensitivity and resolution, and is preferably 300 or less in view of suppressing the reduction in resolution due to thickening of the resist pattern with aging after exposure until the heat treatment. The photoacid generator/basic compound (molar ratio) is more preferably 5.0 to 200, and still more preferably 7.0 to 150.

(F) Surfactant

The resist composition in the present invention preferably further contains a surfactant (F), and more preferably contains either one or two or more of fluorine- and/or silicon-based surfactants (a fluorine-based surfactant, a silicon-based surfactant, or a surfactant containing both a fluorine atom and a silicon atom).

By incorporating the surfactant (F) into the resist composition of the present invention, it becomes possible to form a resist pattern which is decreased in adhesiveness and development defects with good sensitivity and resolution at the time of using an exposure light source of 250 nm or less, and particularly 220 nm or less.

Examples of the fluorine- and/or silicon-based surfactants include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP997-54432A (JP-H09-54432A), JP1997-5988A (JP-H09-5988A), JP2002-277862A, U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, and the following commercially available surfactants may be used as they are.

These surfactants may be used singly or in combination of some kinds thereof.

The amount of the surfactant (F) to be used is preferably 0.01% to 10% by mass, and more preferably 0.1% to 5% by mass, with respect to the total amount (excluding the solvent) of the resist composition.

(G) Onium Carboxylate Salt

The resist composition in the present invention may contain an onium carboxylate salt (G). Examples of the onium carboxylate salt include a sulfonium carboxylate salt, an iodonium carboxylate salt, and an ammonium carboxylate salt. In particular, as the onium carboxylate salt (G), an iodonium salt and a sulfonium salt are preferable. Further, it is preferable that the carboxylate residue of the onium carboxylate salt (G) does not contain an aromatic group and a carbon-carbon double bond. As a particularly preferred anionic moiety, a linear, branched, or cyclic (monocyclic or polycyclic) alkylcarboxylate anion having 1 to 30 carbon atoms is preferable. Further, more preferably, a carboxylate anion in which a part or all of the alkyl groups are substituted with fluorine is preferable. An oxygen atom may be contained in the alkyl chain, by which the transparency to the lights at 220 nm or less is ensured, thus, sensitivity and resolving power are enhanced, and density dependency and exposure margin are improved.

Examples of the fluorine-substituted carboxylate anion include anions of fluoroacetic acid, difluoroacetic acid, trifluoroacetic acid, pentafluoropropionic acid, heptafluorobutyric acid, nonafluoropentanoic acid, perfluorododecanoic acid, perfluorotridecanoic acid, perfluorocyclohexanecarboxylic acid, and 2,2-bistrifluoromethylpropionic acid.

These onium carboxylate salts (G) can be synthesized by reacting sulfonium hydroxide, iodonium hydroxide, or ammonium hydroxide and carboxylic acid with silver oxide in an appropriate solvent.

The content of the onium carboxylate salt (G) in the composition is generally 0.1% to 20% by mass, preferably 0.5% to 10% by mass, and more preferably 1% to 7% by mass, with respect to the total solid contents of the resist composition.

(H) Other Additives

The resist composition in the present invention can further contain a dye, a plasticizer, a light sensitizer, a light absorbent, an alkali-soluble resin, a dissolution inhibitor, a compound that promotes solubility in a developer (for example, a phenol compound with a molecular weight of 1,000 or less, an alicyclic or aliphatic compound having a carboxyl group), and the like, if desired.

Such a phenol compound having a molecular weight of 1,000 or less may be easily synthesized by those skilled in the art with reference to the method described in, for example, JP1992-122938A (JP-H04-122938A), JP1990-28531A (JP-H02-28531A), U.S. Pat. No. 4,916,210A, EP219294B, and the like.

Specific examples of the alicyclic or aliphatic compound having a carboxyl group include, but are not limited to, a carboxylic acid derivative having a steroid structure such as a cholic acid, deoxycholic acid or lithocholic acid, an adamantane carboxylic acid derivative, adamantane dicarboxylic acid, cyclohexane carboxylic acid, and cyclohexane dicarboxylic acid.

The concentration of the solid contents of the resist composition is usually 1.0% to 10% by mass, preferably 2.0% to 5.7% by mass, and more preferably 2.0% to 5.3% by mass. By setting the concentration of the solid contents to these ranges, it is possible to uniformly apply the resist solution onto a substrate and additionally, it is possible to form a resist pattern having excellent line width roughness. The reason is not clear; however, it is considered that, by setting the concentration of the solid contents to 10% by mass or less and preferably 5.7% by mass or less, the aggregation of materials, particularly the photoacid generator, in the resist solution is suppressed, and as a result, it is possible to form a uniform resist film.

The concentration of the solid contents is the weight percentage of the weight of the resist components excluding the solvent with respect to the total weight of the resist composition.

The resist composition in the present invention is used by dissolving the components in a predetermined organic solvent, preferably a mixed solvent, filtering the solution through a filter, and then applying the solution onto a predetermined support (substrate). The filter for use in the filtration is preferably a polytetrafluoroethylene-, polyethylene-, or nylon-made filter having a pore size of 0.1 μm or less, more preferably 0.05 μm or less, and still more preferably 0.03 μm or less. For the filtration with a filter, circular filtration may be carried out as in, for example, JP2002-62667A, or may be carried out by connecting a plurality of kinds of filters in series or in parallel. Further, the composition may be filtered a plurality of times. In addition, the composition may be subjected to a deaeration treatment or the like before and after filtration through a filter.

[5] Resist Pattern

The present invention also relates to a resist pattern formed by the pattern forming method of the present invention as described above.

[6] Method for Manufacturing Electronic Device, and Electronic Device

Moreover, the present invention also relates to a method for manufacturing an electronic device, including the pattern forming method of the present invention as described above, and an electronic device manufactured by this manufacturing method.

The electronic device of the present invention is suitably mounted in electrical or electronic equipments (household electronic appliance, OA-media-related equipment, optical equipment, telecommunication equipment, and the like).

### EXAMPLES

Hereinafter, the present invention will be described in more detail with reference to Examples, but the contents of the present invention are not limited thereto.

### Synthesis Example 1: Synthesis of Resin (1)

102.3 parts by mass of cyclohexanone was heated at 80° C. under a nitrogen stream. While stirring this liquid, a mixed solution of 22.2 parts by mass of a monomer represented by Structural Formula LM-1m, 22.8 parts by mass of a monomer represented by Structural Formula PM-1m, 6.6 parts by mass of a monomer represented by Structural Formula PM-4m, 189.9 parts by mass of cyclohexanone, and 2.40 parts by mass of dimethyl 2,2′-azobisisobutyrate [V-601, manufactured by Wako Pure Chemical Industries, Ltd.] was added dropwise to the liquid for 5 hours. After completion of the dropwise addition, the mixture was further stirred at 80° C. for 2 hours. After being left to be cooled, the reaction solution was reprecipitated with a large amount of hexane/ethyl acetate (mass ratio of 9:1) and filtered, and the obtained solid was dried in vacuum to obtain 41.1 parts by mass of a resin (1).

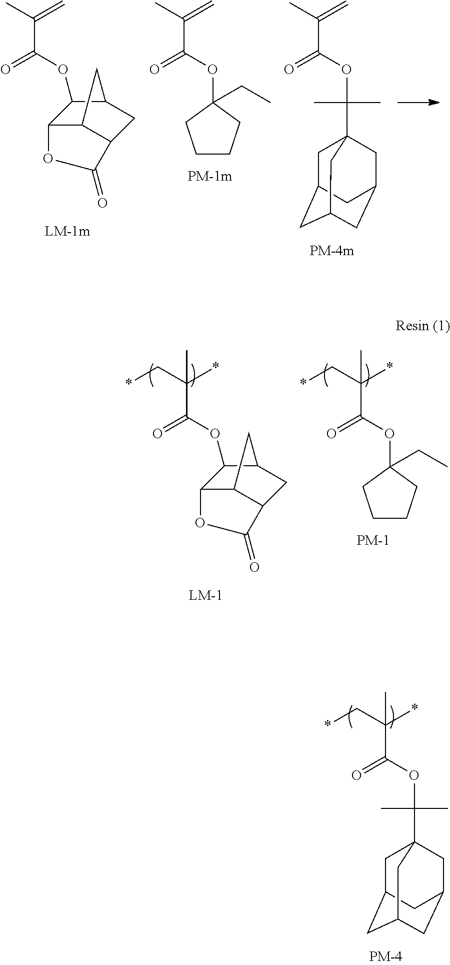

The weight-average molecular weight (Mw) of the obtained resin (1), as determined by GPC (with regard to the measurement method and the like, refer to the above description in the detailed description of the present invention), was 9,500, and the dispersity (Mw/Mn) was 1.62. The compositional ratio measured by ¹³C-NMR was 40/50/10 in terms of a molar ratio.

### Synthesis Example 2: Synthesis of Resins (2) to (12)

The same procedure as in Synthesis Example 1 was carried out to synthesize the resins (2) to (12) described below as an acid-decomposable resin. Hereinbelow, the compositional ratios (molar ratios: corresponding to the repeating units in order from the left side), the weight-average molecular weights (Mw), and the dispersities (Mw/Mn) of the respective repeating units in the resins (1) to (12) are summarized in Table 1. These were determined by the same methods as for the above-mentioned resin (1).

TABLE 1

| | | | | | | | | | Weight-average | |
|---|---|---|---|---|---|---|---|---|---|---|
| | | | | | Compositional ratio | | | | molecular | Dispersity |
| | Repeating unit | | | | (molar ratio) | | | | weight (Mw) | (Mw/Mn) |
| Resin (1) | LM-1 | PM-1 | PM-4 | — | 40 | 50 | 10 | — | 9,500 | 1.62 |
| Resin (2) | LM-2 | PM-2 | PM-5 | — | 40 | 40 | 20 | — | 17,000 | 1.70 |
| Resin (3) | LM-3 | IM-2 | PM-3 | — | 40 | 5 | 55 | — | 11,000 | 1.63 |
| Resin (4) | LM-4 | PM-10 | — | — | 40 | 60 | — | — | 15,000 | 1.66 |
| Resin (5) | LM-1 | PM-3 | PM-4 | IM-3 | 40 | 40 | 10 | 10 | 10,500 | 1.62 |
| Resin (6) | LM-1 | PM-9 | IM-4 | — | 40 | 50 | 10 | — | 15,500 | 1.68 |
| Resin (7) | LM-1 | PM-6 | — | — | 40 | 60 | — | — | 11,000 | 1.65 |
| Resin (8) | LM-1 | PM-3 | PM-4 | — | 40 | 40 | 20 | — | 10,000 | 1.64 |
| Resin (9) | LM-4 | IM-1 | PM-8 | — | 40 | 50 | 10 | — | 9,000 | 1.60 |
| Resin (10) | LM-5 | PM-8 | — | — | 40 | 60 | — | — | 10,000 | 1.61 |
| Resin (11) | LM-5 | PM-7 | PM-4 | IM-3 | 40 | 45 | 10 | 5 | 8,500 | 1.60 |
| Resin (12) | LM-1 | PM-7 | PM-4 | — | 40 | 40 | 20 | — | 17,000 | 1.61 |

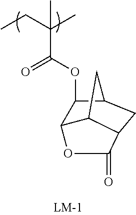

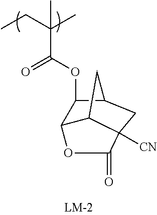

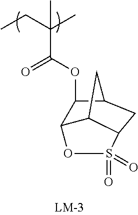

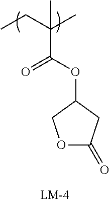

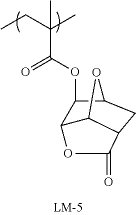

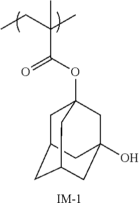

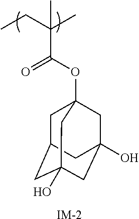

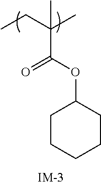

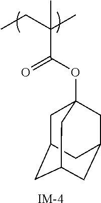

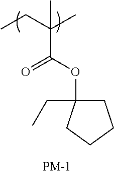

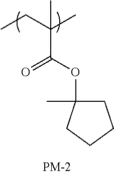

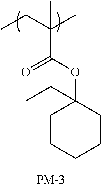

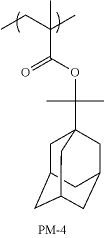

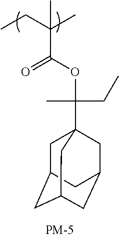

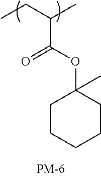

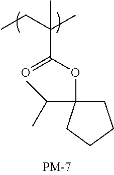

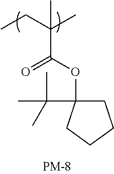

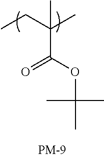

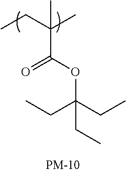

<Preparation of Resist Composition>

The components shown in Table 2 below were dissolved in the solvents shown in Table 2 below to prepare solutions having a concentration of the solid contents of 3.5% by mass, and the solutions were filtered through a polyethylene filter having a pore size of 0.03 μm to obtain resist compositions Re-1 to Re-13.

TABLE 2

| | | | Photoacid | | Hydrophobic | | Basic | | | | | | | |
|---|---|---|---|---|---|---|---|---|---|---|---|---|---|---|
| | Resin | | generator | | resin | | compound | | Solvent | | | | | |
| | | (parts by | | (parts by | | (parts by | | (parts by | | (mass | | (mass | | (mass |
| | | mass) | | mass) | | mass) | | mass) | | ratio) | | ratio) | | ratio) |
| Re-1 | Resin (1) | 85.0 | A1 | 12.0 | B-1 | 1.5 | D-1 | 1.5 | SL-1 | 70 | SL-2 | 30 | | |
| Re-2 | Resin (2) | 88.0 | A2 | 10.0 | B-2 | 0.7 | D-1 | 1.3 | SL-1 | 95 | SL-4 | 5 | | |
| Re-3 | Resin (3) | 85.0 | A3 | 9.5 | B-3 | 1.0 | D-1 | 4.5 | SL-1 | 60 | SL-2 | 40 | | |
| Re-4 | Resin (4) | 81.0 | A4 | 15.5 | B-5 | 1.7 | D-3 | 1.8 | SL-1 | 60 | SL-3 | 40 | | |
| Re-5 | Resin (5) | 86.5 | A5 | 10.0 | B-6 | 2.0 | D-4 | 1.5 | SL-1 | 90 | SL-3 | 10 | | |
| Re-6 | Resin (6) | 87.0 | A6 | 10.5 | B-7 | 1.2 | D-5 | 1.3 | SL-2 | 100 | | | | |
| Re-7 | Resin (7) | 87.0 | A7 | 11.0 | B-8 | 0.8 | D-6 | 1.2 | SL-1 | 90 | SL-2 | 5 | SL-4 | 5 |
| Re-8 | Resin (8) | 81.0 | A8 | 10.5 | B-1/B-5 | 1.0/1.5 | D-2 | 6.0 | SL-1 | 80 | SL-2 | 20 | | |
| Re-9 | Resin (9) | 87.0 | A2/A5 | 4.0/5.0 | B-4 | 0.5 | D-1 | 3.5 | SL-1 | 75 | SL-2 | 25 | | |
| Re-10 | Resin (10) | 84.0 | A1 | 14.5 | B-1 | 0.5 | D-1 | 1.0 | SL-1 | 70 | SL-2 | 20 | SL-4 | 10 |
| Re-11 | Resin (11) | 85.0 | A2 | 12.5 | B-2 | 1.1 | D-5 | 1.4 | SL-1 | 100 | | | | |
| Re-12 | Resin (1)/ | 40.0/ | A3 | 16.0 | B-1 | 3.1 | D-1 | 0.9 | SL-1 | 80 | SL-3 | 20 | | |
| | Resin (12) | 40.0 | | | | | | | | | | | | |
| Re-13 | Resin (1) | 86.5 | A1 | 12.0 | | | D-1 | 1.5 | SL-1 | 70 | SL-2 | 30 | | |

The abbreviations in Table 2 are shown below.

<Photoacid Generator>

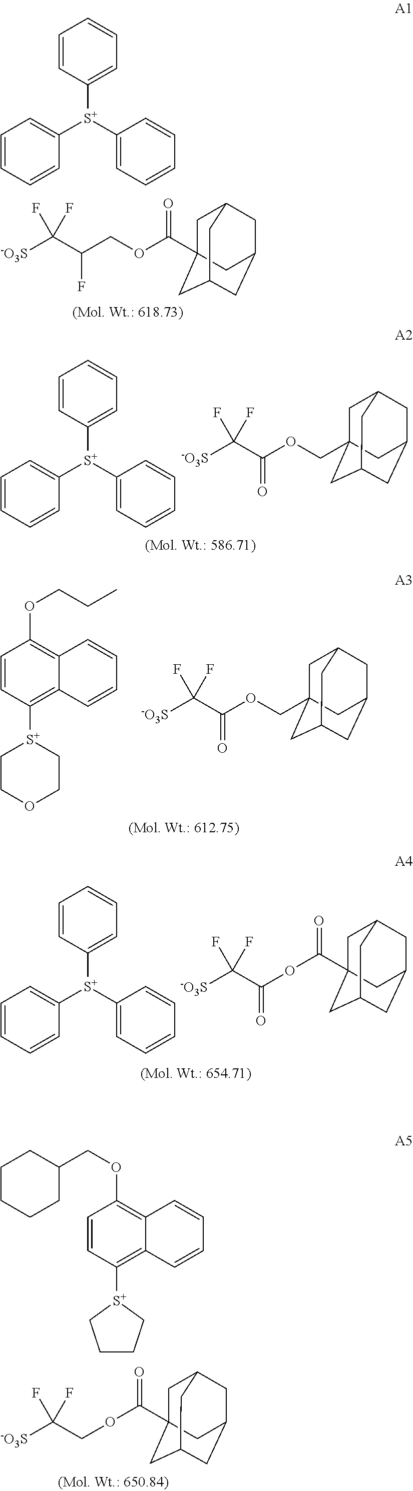

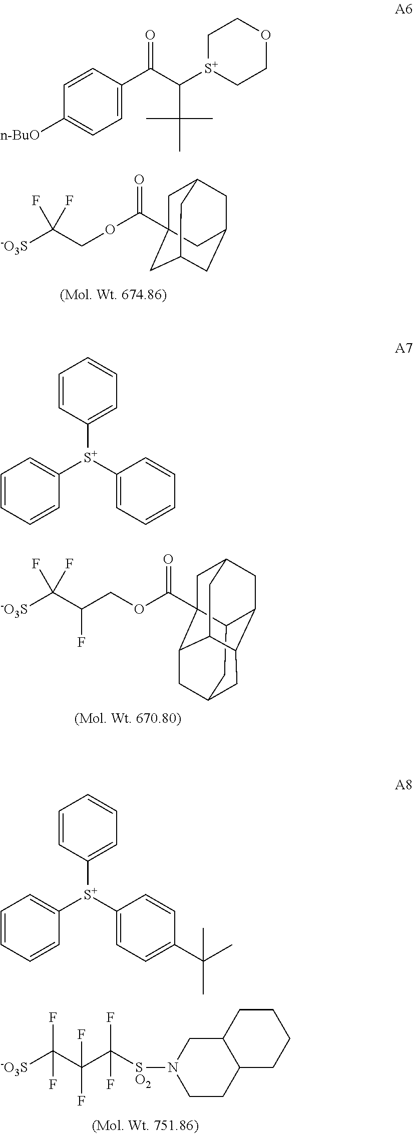

<Hydrophobic Resin>

As the hydrophobic resin, the resins (B-1) to (B-8) shown in Table 3 were used.

TABLE 3

| | | | | | | | | | Weight-average | |
|---|---|---|---|---|---|---|---|---|---|---|
| | | | | | Compositional ratio | | | | molecular | Dispersity |
| Resin | Repeating unit | | | | (molar ratio) | | | | weight (Mw) | (Mw/Mn) |
| B-1 | AM-4 | | | | 100 | | | | 12,500 | 1.58 |
| B-2 | AM-1 | AM-2 | | | 60 | 40 | | | 20,000 | 1.60 |
| B-3 | AM-2 | AM-7 | AM-8 | | 80 | 15 | 5 | | 13,000 | 1.57 |
| B-4 | AM-5 | AM-6 | BM-2 | | 70 | 20 | 10 | | 15,000 | 1.50 |
| B-5 | FM-1 | BM-1 | AM-8 | AM-3 | 40 | 50 | 5 | 5 | 8,000 | 1.52 |
| B-6 | AM-1 | AM-2 | FM-3 | | 50 | 40 | 10 | | 26,000 | 1.56 |
| B-7 | FM-4 | BM-1 | AM-3 | | 90 | 5 | 5 | | 13,000 | 1.53 |
| B-8 | FM-2 | AM-5 | BM-3 | | 50 | 25 | 25 | | 11,000 | 1.55 |

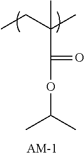

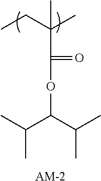

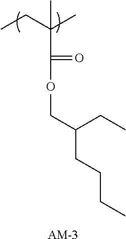

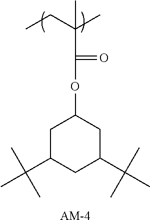

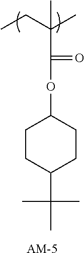

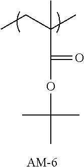

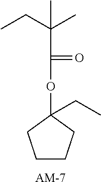

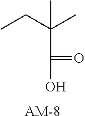

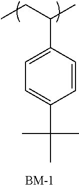

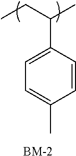

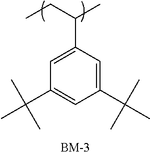

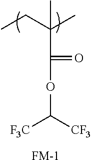

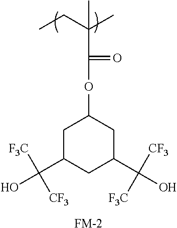

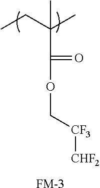

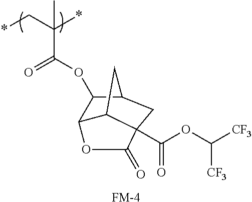

<Basic Compound>

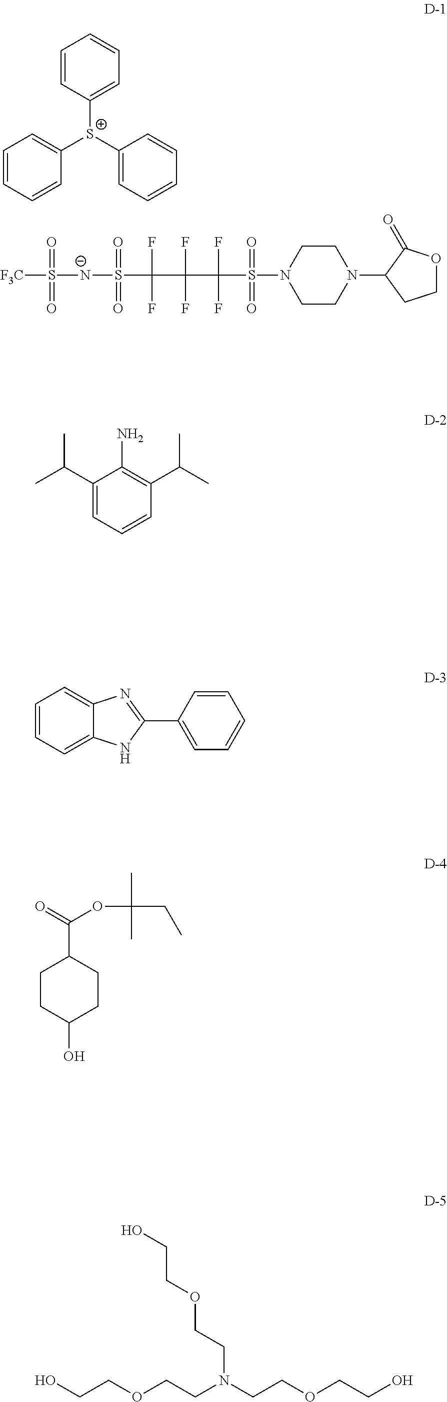 [SMILES: c1ccc([S+](c2ccccc2)c2ccccc2)cc1 ; O=C1OCCC1N1CCN(S(=O)(=O)C(F)(F)C(F)(F)C(F)(F)S(=O)(=O)[N-]S(=O)(=O)C(F)(F)F)CC1 ; CC(C)c1cccc(C(C)C)c1N ; c1ccc(-c2nc3ccccc3[nH]2)cc1 ; CCC(C)(C)OC(=O)C1CCC(O)CC1 ; OCCOCCN(CCOCCO)CCOCCO]

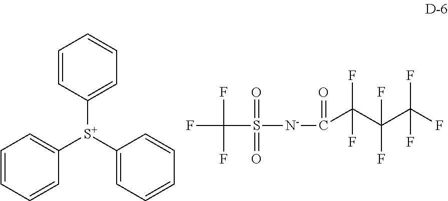 [SMILES: c1ccc([S+](c2ccccc2)c2ccccc2)cc1 ; O=C([N-]S(=O)(=O)C(F)(F)F)C(F)(F)C(F)(F)C(F)(F)F]

<Solvent>

SL-1: Propylene glycol monomethyl ether acetate (PGMEA)

SL-2: Cyclohexanone

SL-3: Propylene glycol monomethyl ether (PGME)

SL-4: γ-Butyrolactone

### Synthesis Example 3: Synthesis of Polymer (X-1)

268 g of cyclohexanone was heated at 80° C. under a nitrogen stream. While stirring this liquid, each of a mixed solution of 160 g of a monomer represented by Structural Formula M-1, 95.3 g of a monomer represented by Structural Formula M-2, 249 g of cyclohexanone, and 25.6 mg (100 ppm with respect to all the monomers) of methoxyhydroquinone (MEHQ), and a mixed solution of 5.54 g of dimethyl 2,2′-azobisisobutyrate [V-601, manufactured by Wako Pure Chemical Industries, Ltd.] and 249 g of cyclohexanone was added dropwise thereto for 6 hours. After completion of the dropwise addition, the mixture was additionally stirred at 80° C. for 2 hours. After leaving the reaction solution to be cooled, the mixture was reprecipitated with a large amount of methanol and filtered, and the obtained wet solid was re-dissolved in 4-methyl-2-propanol. While heating the solution under reduced pressure, the remaining methanol and cyclohexanone were expelled, and then the polymer solution was filtered through a polyethylene filter having a pore size of 0.05 μm to prepare 2,210 g of a 4-methyl-2-pentanol solution with 10% by mass of the polymer.

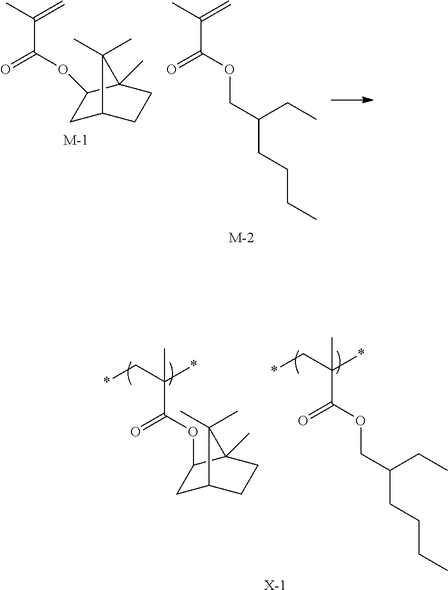

The weight-average molecular weight (Mw: in terms of polystyrene) of the obtained polymer (X-1), as determined by GPC (with regard to the detailed measurement method and the like, refer to the descriptions above in the detailed description of the present invention), was Mw=19,000, and the dispersity was Mw/Mn=1.83. The compositional ratio (molar ratio: corresponding to the polymers in order from the left side) measured by ¹³C-NMR was 60/40.

The same procedure as in Synthesis Example 3 was carried out to synthesize the polymers (X-2) to (X-15) described below, which are included in upper layer film compositions. The details of the polymers (X-1) to (X-15) are shown in Table 4.

In Table 4 below, the numeral value in the parenthesis in the section of the polymerization inhibitor used in the reaction represents the mass ratio (ppm) with respect to all the monomers. Further, the peak area (%) of the high-molecular-weight forms represents the ratio (%) of the peak area of the high-molecular-weight components having a weight-average molecular weight of 40,000 or more with respect to the entire peak area in the molecular weight distribution of the polymer (X) measured by GPC (with regard to the detailed calculation method and the like, refer to the descriptions above in the detailed description of the present invention).

TABLE 4

| | Compositional | | | | | Polymerization | Peak area (%) of |
|---|---|---|---|---|---|---|---|
| Polymer | ratio | | | | | inhibitor (ppm) | high-molecular-weight |
| (X) | (% by mole) | | | Mw | Mw/Mn | used in reaction | forms |
| X-1 | 60 | 40 | — | 19,000 | 1.83 | MEHQ (100) | <0.1 |
| X-2 | 70 | 30 | — | 11,000 | 1.63 | Phenothiazine (50) | <0.1 |
| X-3 | 90 | 10 | — | 8,000 | 1.71 | MEHQ (50) | <0.1 |
| X-4 | 70 | 30 | — | 10,000 | 1.68 | MEHQ (30) | <0.1 |
| X-5 | 60 | 40 | — | 9,500 | 1.65 | MEHQ (100) | <0.1 |
| X-6 | 100 | — | — | 12,000 | 1.68 | MEHQ (200) | <0.1 |
| X-7 | 100 | — | — | 9,000 | 1.92 | MEHQ (150) | <0.1 |
| X-8 | 50 | 50 | — | 8,000 | 1.68 | MEHQ (200) | <0.1 |
| X-9 | 90 | 10 | — | 9,500 | 1.75 | Phenothiazine (30) | <0.1 |
| X-10 | 20 | 80 | — | 8,500 | 1.63 | Catechol (30) | <0.1 |
| X-11 | 30 | 50 | 20 | 10,000 | 1.73 | MEHQ (300) | <0.1 |
| X-12 | 30 | 40 | 30 | 8,000 | 1.69 | MEHQ (50)/ | <0.1 |
| | | | | | | phenothiazine (50) | |
| X-13 | 40 | 30 | 30 | 9,000 | 1.54 | MEHQ (200) | <0.1 |
| X-14 | 75 | 25 | — | 10,000 | 1.60 | None | 0.2 |
| X-15 | 75 | 25 | — | 9,500 | 1.67 | None | 0.2 |

<Polymer (X)>

In Table 4, the chemical formulae of the polymers (X-1) to (X-15) are as follows. The % by mole of the repeating units (corresponding to the respective repeating units in order from the left side) in the respective polymers are shown in Table 4.

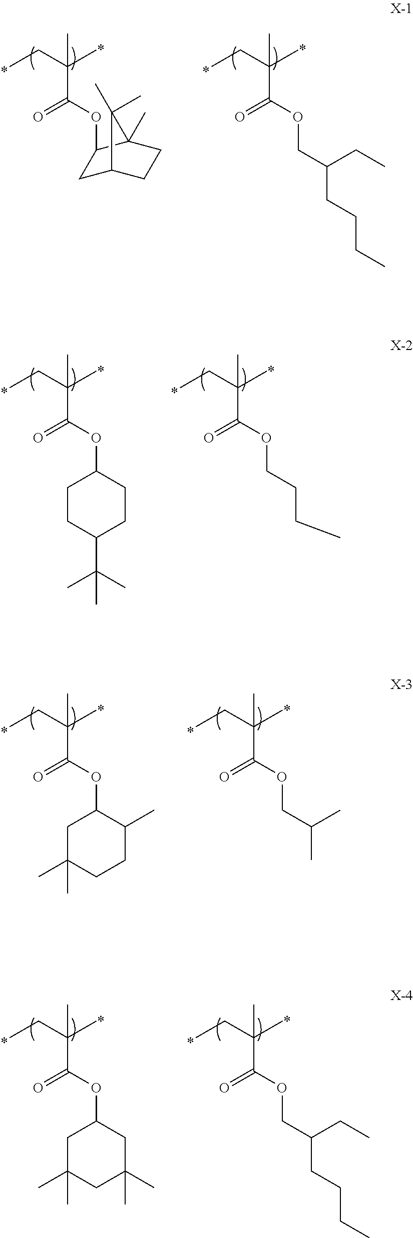

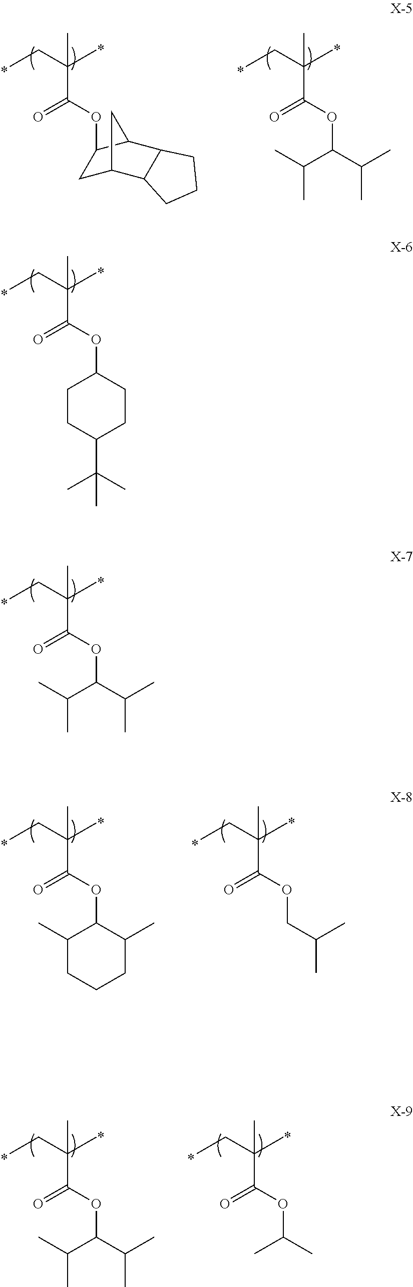

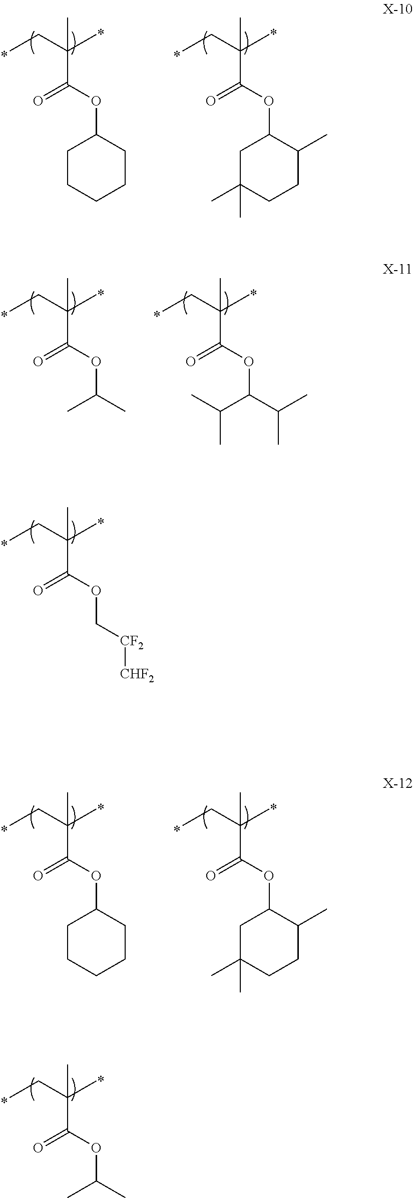

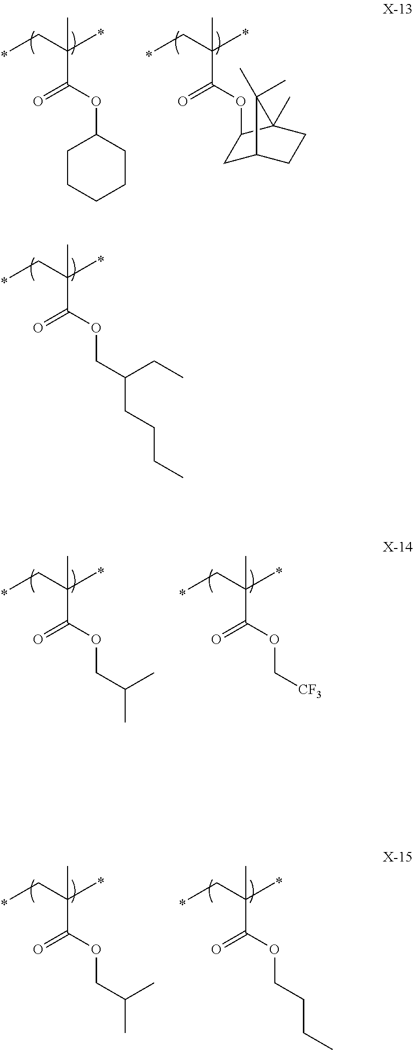

<Preparation of Upper Layer Film Composition>

The components shown in Table 5 below were dissolved in the solvents shown in Table 5 below to obtain solutions each having a concentration of the solid contents of 2.7% by mass. The solutions were filtered through a polyethylene filter having a pore size of 0.03 μm to prepare compositions (1) to (15) for forming an upper layer film. In Table 5 below, the content (% by mass) of the additive (AD) is based on the total solid contents of the composition for forming an upper layer film.

TABLE 5

| | | | Additive (AD) |
|---|---|---|---|
| Composition | Polymer (X) | Solvent (S) | (content) |
| Composition (1) | X-1 | S-1 | AD-2 |
| | | | (4% by weight) |
| Composition (2) | X-2 | S-2 | — |
| Composition (3) | X-3 | S-3 | AD-3 |
| | | | (12% by weight) |
| Composition (4) | X-4 | S-4 | — |
| Composition (5) | X-5 | S-5 | AD-2 |
| | | | (6% by weight) |
| Composition (6) | X-6 | S-6 | — |
| Composition (7) | X-7 | S-1 | AD-1 |
| | | | (4% by weight) |
| Composition (8) | X-8 | S-1 | AD-4 |
| | | | (4% by weight) |
| Composition (9) | X-9 | S-1 | — |
| Composition (10) | X-10 | S-1 | AD-4 |
| | | | (10% by weight) |
| Composition (11) | X-11 | S-1 | AD-1 |
| | | | (3% by weight) |
| Composition (12) | X-12 | S-1 | — |
| Composition (13) | X-13 | S-1 | AD-3 |
| | | | (12% by weight) |
| Composition (14) | X-14 | S-1 | — |
| Composition (15) | X-15 | S-2 | — |

The respective abbreviations in the table are as follows.

<Solvent (S)>

S-1: 4-Methyl-2-pentanol

S-2: 3-Penten-2-one

S-3: 2-Nonanone

S-4: Decane

S-5: Isoamyl ether

S-6: Isobutyl isobutyrate

<Additives (AD)>

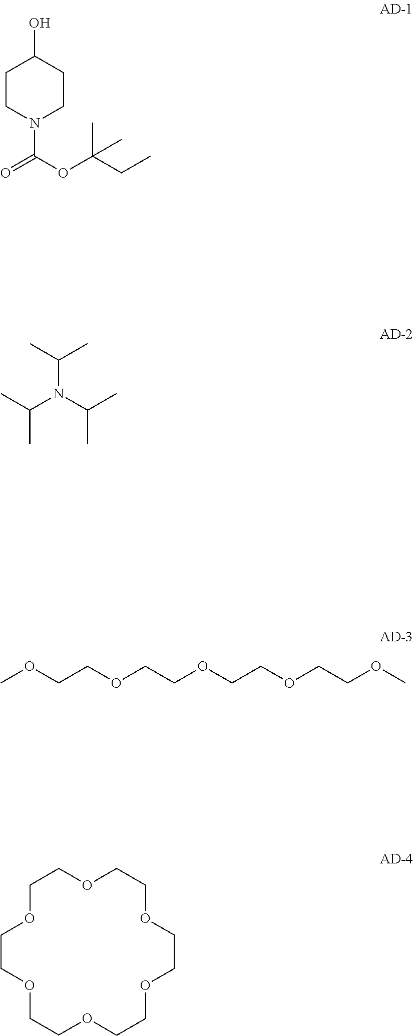

(Formation of Hole Pattern)

An organic antireflection film ARC29SR (manufactured by Brewer Science, Inc.) was applied onto a silicon wafer, and baking was carried out at 205° C. for 60 seconds to form an antireflection film having a film thickness of 86 nm. A resist composition shown in Table 6 below was applied thereon, and baking was carried out at 100° C. for 60 seconds to form a resist film having a film thickness of 90 nm.

Next, the topcoat composition shown in Table 6 below was applied onto the resist film, and then baking was carried out at the PB temperature (unit: ° C.) shown in Table 6 below for 60 seconds to form an upper layer film having a film thickness (unit: nm) shown in Table 6 below.

Subsequently, the resist film having the upper layer film formed thereon was subjected to pattern exposure through a squarely arrayed halftone mask with hole portions of 65 nm and pitches between holes of 100 nm (the hole portions were shielded), using an ArF excimer laser liquid immersion scanner (manufactured by ASML; XT1700i, NA1.20, C-Quad, outer sigma 0.730, inner sigma 0.630, and XY deflection). Ultrapure water was used as the immersion liquid. Thereafter, heating (Post Exposure Bake: PEB) was carried out at 105° C. for 60 seconds. Then, development was carried out by paddling for 30 seconds using an organic developer described in Table 6 below, and rinsing was carried out by paddling for 30 seconds using a rinsing liquid described in Table 6 below. Subsequently, a hole pattern with a hole diameter of 50 nm was obtained by rotating the wafer at a rotation speed of 2,000 rpm for 30 seconds.

(Evaluation)

<Focus Latitude (DOF: Depth of Focus)>

In the exposure dose for forming a hole pattern with a hole diameter of 50 nm under the exposure and development conditions (Formation of Hole Pattern) above, exposure and development were carried out by changing the conditions of the exposure focus at an interval of 20 nm in the focus direction. The hole diameter (CD) of each of the obtained patterns was measured using a line-width critical dimension scanning electron microscope SEM (S-9380, Hitachi, Ltd.), and a focus corresponding to the minimum value or the maximum value in a curve obtained by plotting the respective CDs was defined as the best focus. In a case where the focus was changed around the center of the best focus, a variation width of the focus tolerating a hole diameter of 50 nm±10%, that is, the focus latitude (DOF) (nm) was calculated. The evaluation results are shown in Table 6.

TABLE 6

| | | | | PB | | | |
|---|---|---|---|---|---|---|---|
| | | | Film | temperature | | | |
| | | | thickness | (° C.) after | | | |
| | Composition | | (nm) of | formation of | | | Items to be |
| | For upper | For resist | upper layer | upper layer | Organic | | evaluated |
| | layer film | film | film | film | developer | Rinsing liquid | DOF (nm) |
| Example 1 | Composition (1) | Re-1 | 80 | 90 | Butyl acetate | 4-Methyl-2-heptanol | 100 |
| Example 2 | Composition (2) | Re-2 | 60 | 110 | Butyl acetate | 4-Methyl-2-heptanol | 100 |
| Example 3 | Composition (3) | Re-3 | 30 | 90 | Butyl acetate | 4-Methyl-2-heptanol | 105 |
| Example 4 | Composition (4) | Re-4 | 50 | 120 | Butyl acetate | 4-Methyl-2-heptanol | 100 |
| Example 5 | Composition (5) | Re-5 | 70 | 90 | Butyl acetate | n-Decane | 100 |
| Example 6 | Composition (6) | Re-6 | 90 | 90 | 2-Heptanone | 4-Methyl-2-heptanol | 90 |
| Example 7 | Composition (7) | Re-7 | 60 | 120 | Butyl acetate | 4-Methyl-2-heptanol | 120 |
| Example 8 | Composition (8) | Re-8 | 80 | 90 | Butyl acetate | 4-Methyl-2-heptanol | 105 |
| Example 9 | Composition (9) | Re-9 | 90 | 90 | Butyl propionate | 4-Methyl-2-heptanol | 90 |
| Example 10 | Composition (10) | Re-10 | 60 | 90 | Butyl acetate | 4-Methyl-2-heptanol | 105 |
| Example 11 | Composition (11) | Re-11 | 50 | 90 | Butyl acetate | 4-Methyl-2-heptanol | 105 |
| Example 12 | Composition (12) | Re-12 | 30 | 90 | Butyl acetate | 4-Methyl-2-heptanol | 90 |
| Example 13 | Composition (13) | Re-13 | 60 | 120 | Butyl acetate | 4-Methyl-2-heptanol | 120 |
| Comparative | Composition (14) | Re-2 | 90 | 100 | Butyl acetate | 4-Methyl-2-heptanol | 75 |
| Example 1 | | | | | | | |
| Comparative | Composition (15) | Re-3 | 80 | 90 | Butyl acetate | 4-Methyl-2-heptanol | 75 |
| Example 2 | | | | | | | |

From Table 6 above, it could be seen that according to Examples 1 to 13, in which the composition for forming an upper layer film according to the present invention was used, a hole pattern having an ultrafine pore diameter can be formed with high focus latitude (DOF: Depth of Focus) performance, as compared with Comparative Examples 1 and 2, in which such composition was not used.

In particular, it could be seen that in Examples 1, 3, 5, 7, 8, 10, 11, and 13, in which the composition for forming an upper layer film, containing the compound selected from the group consisting of (A1) and (A2), was used, more excellent results are obtained.

In addition, it could also be seen that in Examples 2, 4, 7, and 13, in which the composition for forming an upper layer film was applied and then heated at 100° C. or higher to form an upper layer film, more excellent results are obtained.

### INDUSTRIAL APPLICABILITY

According to the present invention, it is possible to provide a composition for forming an upper layer film capable of forming a trench pattern or hole pattern having an ultrafine width or pore diameter (for example, 60 nm or less) with high focus latitude (DOF: Depth of Focus) performance, a pattern forming method using the same, and a method for manufacturing an electronic device.

While the present invention has been described in detail and with reference to specific embodiments thereof, it will be apparent to one skilled in the art that various changes and modifications can be made therein without departing from the spirit and scope of the invention.

The present application is based on Japanese Patent Application (JP2015-037290) filed on Feb. 26, 2015, the contents of which are incorporated herein by reference.

1. A composition for forming an upper layer film for a photoresist, comprising:
a polymer having a molecular weight distribution in which a peak area of a high-molecular-weight component having a weight-average molecular weight of 40,000 or more accounts for 0.1% or less with respect to the entire peak area in the molecular weight distribution, measured by the gel permeation chromatography.

2. The composition for forming an upper layer film according to claim 1, which is for use in a photoresist to be subjected to development using a developer containing an organic solvent.

3. The composition for forming an upper layer film according to claim 1,
wherein the polymer is produced by a method including a step of radically polymerizing monomers having ethylenic double bonds in the coexistence of 30 ppm or more of a polymerization inhibitor with respect to the total amount of the monomers.

4. The composition for forming an upper layer film according to claim 3,
wherein the polymerization inhibitor is one or more compounds selected from the group consisting of hydroquinone, catechol, benzoquinone, a 2,2,6,6-tetramethylpiperidin-1-oxyl free radical, an aromatic nitro compound, an N-nitroso compound, benzothiazole, dimethylaniline, phenothiazine, vinylpyrene, and derivatives thereof.

5. The composition for forming an upper layer film according to claim 1, further comprising:
at least one compound selected from the group consisting of the following (A1) and (A2):
(A1) a basic compound or base generator; and
(A2) a compound containing a bond or group selected from the group consisting of an ether bond, a thioether bond, a hydroxyl group, a thiol group, a carbonyl bond, and an ester bond.

6. A pattern forming method comprising:
a step of forming an upper layer film on a resist film using the composition for forming an upper layer film according to claim 1;
a step of exposing the resist film; and
a step of developing the exposed resist film.

7. The pattern forming method according to claim 6,
wherein the step of forming an upper layer film includes
a step of applying the composition for forming an upper layer film on the resist film, and
a step of heating the composition applied on the resist film to 100° C. or higher.

8. The pattern forming method according to claim 6,
wherein the step of developing the exposed resist film is a step of carrying out development using a developer containing an organic solvent.

9. A method for manufacturing an electronic device, using:
the pattern forming method according to claim 6.

10. A method for manufacturing an electronic device, using:
the pattern forming method according to claim 7.

11. A method for manufacturing an electronic device, using:
the pattern forming method according to claim 8.
